(19) United States
(12) Patent Application Publication
(10) Pub. No.: US 2024/0393693 A1
(43) Pub. Date: Nov. 28, 2024

(54) SILICON-CONTAINING RESIST UNDERLAYER FILM FORMING COMPOSITION, LAMINATE USING THE COMPOSITION, AND METHOD FOR MANUFACTURING SEMICONDUCTOR ELEMENT

(71) Applicant: NISSAN CHEMICAL CORPORATION, Tokyo (JP)

(72) Inventors: Wataru SHIBAYAMA, Toyama (JP); Satoshi TAKEDA, Toyama (JP); Shunsuke MORIYA, Toyama (JP); Takahiro KISHIOKA, Toyama (JP)

(73) Assignee: NISSAN CHEMICAL CORPORATION, Tokyo (JP)

(21) Appl. No.: 18/689,632

(22) PCT Filed: Sep. 2, 2022
(86) PCT No.: PCT/JP2022/033125

§ 371 Date: Mar. 6, 2024

(30) Foreign Application Priority Data
Sep. 7, 2021 (JP) 2021-145101

(51) Int. Cl. G03F 7/11; C08G 77/00; C08G 77/26; C09D 183/04; H01L 21/02; H01L 21/311; H01L 21/3213

(52) U.S. Cl. CPC G03F 7/11; C08G 77/26; C09D 183/04; H01L 21/02068; H01L 21/31116; H01L 21/32135; H01L 21/32139; C08G 77/80

(57) ABSTRACT

A silicon-containing resist underlayer film forming composition for forming a silicon-containing resist underlayer film to be used as an etching mask when a metal film containing at least one metal selected from the group consisting of Groups 6, 7, 8, and 9 of the periodic table of elements is dry-etched.

### TECHNICAL FIELD

The present invention relates to a silicon-containing resist underlayer film forming composition, a laminate using the composition, and a method for manufacturing a semiconductor element.

### BACKGROUND ART

In recent years, with miniaturization and high performance of a silicon semiconductor product, copper (Cu) wiring has been frequently used. Since dry etching of copper is extremely difficult, the Cu wiring is generally formed by a series of steps (damascene method) including a wiring groove forming step by dry etching of an inter-wiring insulating film (also referred to as an interlayer insulating film), a step of embedding copper in the formed wiring groove by electrolytic plating, a step of removing an excessive Cu film by chemical mechanical polishing (CMP), and a planarization step.

As a semiconductor substrate formed by a damascene method, a semiconductor substrate has been reported in which a barrier metal film such as a Ta film or a Ti film formed between Cu wiring formed in a groove of an interlayer insulating film and the groove of the interlayer insulating film is formed (see, for example, Patent Literature 1).

### CITATION LIST

### Patent Literature

Patent Literature 1: JP 2012-69550 A

### SUMMARY OF INVENTION

### Technical Problem

A barrier metal layer prevents Cu metal atoms from diffusing from wiring to a surrounding insulating film. A metal material having a higher resistivity than Cu is used for the barrier metal layer. Therefore, the barrier metal layer increases wiring resistance.

When a wiring pitch is reduced, the thickness of the barrier metal layer is also desirably reduced. However, when the barrier metal layer is too thin, diffusion of Cu atoms cannot be prevented. The barrier metal layer can be thinned only to some extent.

That is, when miniaturization is promoted, a ratio of the barrier metal layer in a wiring cross section increases from a certain stage. A metal of the barrier metal layer usually has a higher resistivity than Cu. Therefore, a resistance value rapidly increases due to miniaturization.

Therefore, in order to cope with this problem, in a next-generation most advanced device for semiconductors for ultrafine processing, application of a new metal such as Ru, W, or Mo instead of Cu to metal wiring is expected.

By the way, in addition to the above damascene method, for example, by a subtractive method, a semiconductor element including a semiconductor substrate and a metal wiring layer (patterned metal film) can be manufactured.

In the subtractive method, a hard mask layer is formed on a metal film, and the hard mask layer is etched to form a wiring pattern (base pattern). Next, the metal film is etched using a hard mask (a metal wiring layer is formed) to form a wiring pattern similar to the hard mask. Subsequently, the hard mask is removed, and an insulating film (dielectric film) is embedded by chemical vapor deposition (CVD). Then, a surface is scraped and flattened by CMP to expose a surface of the metal wiring layer. For example, as described above, a semiconductor element by a subtractive method can be manufactured through the series of steps described above.

In order not to cause the problem due to the barrier metal layer, it is desirable to manufacture a semiconductor element that does not require the barrier metal layer by using a new metal other than Cu for wiring, and further manufacturing the semiconductor element by a subtractive method.

Therefore, in order to manufacture a semiconductor element including a semiconductor substrate and a metal wiring layer by a subtractive method using a new metal other than Cu, such as Ru, an object of the present invention is to provide a mask material that can be preferably used as an etching mask for dry-etching a film of the new metal.

More specifically, in order to manufacture a semiconductor element by a subtractive method using a new metal other than Cu, such as Ru, an object of the present invention is to provide a resist underlayer film forming composition for forming a resist underlayer film that can be preferably used as an etching mask for dry-etching a film of a metal selected from the group consisting of Groups 6, 7, 8, and 9 of the periodic table of elements, such as Ru.

### Solution to Problem

The present inventors have found that a silicon-containing resist underlayer film formed of a silicon-containing resist underlayer film forming composition can be preferably used as an etching mask used when a metal film containing a metal selected from the group consisting of Groups 6, 7, 8, and 9 of the periodic table of elements, such as Ru, is dry-etched, and have further found that a semiconductor element not requiring a barrier metal layer, which does not cause the above-described problem of the barrier metal layer, can be preferably obtained by manufacturing the semiconductor element using the metal film and the silicon-containing resist underlayer film, thereby completing the present invention.

That is, the present invention includes the following aspects.

[1] A silicon-containing resist underlayer film forming composition for forming a silicon-containing resist underlayer film to be used as an etching mask when a metal film containing at least one metal selected from the group consisting of Groups 6, 7, 8, and 9 of the periodic table of elements is dry-etched.
[2] The silicon-containing resist underlayer film forming composition according to [1], wherein the metal is ruthenium (Ru).
[3] The silicon-containing resist underlayer film forming composition according to [1] or [2], including:
component [A]: a polysiloxane; and
component [B]: a solvent.
   [4] The silicon-containing resist underlayer film forming composition according to any one of [1] to [3], wherein the silicon-containing resist underlayer film is a film formed by application.
   [5] The silicon-containing resist underlayer film forming composition according to [3] or [4], wherein the content of Si in the polysiloxane as the component [A] is 30% by mass or more.
   [6] The silicon-containing resist underlayer film forming composition according to any one of [3] to [5], wherein the polysiloxane as the component [A] is a polysiloxane using a tetrafunctional alkoxysilane as a raw material.
   [7] The silicon-containing resist underlayer film forming composition according to any one of [3] to [6], wherein the polysiloxane as the component [A] is a polysiloxane using a trifunctional alkoxysilane as a raw material.
   [8] The silicon-containing resist underlayer film forming composition according to any one of [3] to [7], wherein the polysiloxane as the component [A] contains a polysiloxane modified product in which at least some of silanol groups are alcohol-modified or acetal-protected.
   [9] The silicon-containing resist underlayer film forming composition according to [8], wherein the polysiloxane modified product contains a dehydration reaction product of a hydrolysis condensate of a hydrolyzable silane compound and an alcohol.
   [10] The silicon-containing resist underlayer film forming composition according to any one of [3] to [9], wherein the solvent as the component [B] contains an alcohol-based solvent.
   [11] The silicon-containing resist underlayer film forming composition according to [10], wherein the solvent as the component [B] contains at least one of a propylene glycol monoalkyl ether and methyl isobutyl carbinol.
   [12] The silicon-containing resist underlayer film forming composition according to any one of [3] to [11], further including nitric acid or acetic acid.
   [13] The silicon-containing resist underlayer film forming composition according to any one of [3] to [12], wherein the solvent as the component [B] contains water.
   [14] The silicon-containing resist underlayer film forming composition according to any one of [1] to [13], wherein the silicon-containing resist underlayer film is a resist underlayer film for ArF or EUV lithography.
   [15] A laminate including: a metal film containing at least one metal selected from the group consisting of Groups 6, 7, 8, and 9 of the periodic table of elements; and a silicon-containing resist underlayer film formed on the metal film, wherein
the silicon-containing resist underlayer film is formed using the silicon-containing resist underlayer film forming composition according to any one of [1] to [14], and
the metal film is dry-etched.
   [16] A method for manufacturing a semiconductor element, including:
a step of forming a metal film containing at least one metal selected from the group consisting of Groups 6, 7, 8, and 9 of the periodic table of elements on a semiconductor substrate;
a step of forming a silicon-containing resist underlayer film on the metal film using the silicon-containing resist underlayer film forming composition according to any one of [1] to [14]; and
a step of forming a resist film on the silicon-containing resist underlayer film.
   [17] The method for manufacturing a semiconductor element according to [16], wherein a silicon-containing resist underlayer film forming composition that has been subjected to nylon filter filtration is used in the step of forming a silicon-containing resist underlayer film.
   [18] The method for manufacturing a semiconductor element according to or [17], including:
a step of applying the silicon-containing resist underlayer film forming composition according to any one of [1] to on the metal film and firing the composition to form a silicon-containing resist underlayer film; and
a step of applying a resist composition onto the silicon-containing resist underlayer film to form a resist film.
   [19] The method for manufacturing a semiconductor element according to any one of to [18], including:
a step of exposing and developing the resist film to obtain a resist pattern;
a step of etching the silicon-containing resist underlayer film using the patterned resist film as a mask; and
a step of dry-etching the metal film using the patterned silicon-containing resist underlayer film as a mask.
   [20] The method for manufacturing a semiconductor element according to [19], wherein an etching rate (etch rate) of the silicon-containing resist underlayer film in the step of dry-etching is lower than an etching rate (etch rate) of the metal film.
   [21] The method for manufacturing a semiconductor element according to or [20], further including a step of removing the silicon-containing resist underlayer film by a wet method using a chemical solution after the step of dry-etching the metal film.

### Advantageous Effects of Invention

According to the present invention, in order to manufacture a semiconductor element by a subtractive method using a new metal other than Cu, such as Ru, it is possible to provide a resist underlayer film forming composition for forming a resist underlayer film that can be preferably used as an etching mask for dry-etching a film of a metal selected from the group consisting of Groups 6, 7, 8, and 9 of the periodic table of elements, such as Ru.

### DESCRIPTION OF EMBODIMENTS

### (Silicon-Containing Resist Underlayer Film Forming Composition)

A silicon-containing resist underlayer film forming composition of the present invention is used for forming a silicon-containing resist underlayer film.

The silicon-containing resist underlayer film is used as an etching mask when a metal film containing at least one metal (hereinafter, referred to as “specific metal”) selected from the group consisting of Groups 6, 7, 8, and 9 of the periodic table of elements is dry-etched. The silicon-containing resist underlayer film is used as an etching mask, and therefore is formed on the metal film containing a specific metal.

The silicon-containing resist underlayer film is preferably a film formed by application.

The present inventors have found that a silicon-containing resist underlayer film formed of a silicon-containing resist underlayer film forming composition can be preferably used as an etching mask used when a metal film containing a metal selected from the group consisting of Groups 6, 7, 8, and 9 of the periodic table of elements, such as Ru is dry-etched.

The silicon-containing resist underlayer film forming composition of the present invention contains a polysiloxane as a component [A] and a solvent as a component [B], and further contains other components as necessary.

### <Component [A]: Polysiloxane>

The polysiloxane as the component [A] is not particularly limited as long as it is a polymer having a siloxane bond.

The polysiloxane may be a polysiloxane using a tetrafunctional alkoxysilane as a raw material.

The polysiloxane may be a polysiloxane using a trifunctional alkoxysilane as a raw material.

The polysiloxane may contain a modified polysiloxane in which at least some of silanol groups are modified, for example, a polysiloxane modified product in which at least some of silanol groups are alcohol-modified or acetal-protected.

As an example, the polysiloxane may contain, a hydrolysis condensate of a hydrolyzable silane, and may contain a dehydration reaction product of the hydrolysis condensate and an alcohol, or may contain a modified polysiloxane in which at least some of silanol groups of the hydrolysis condensate are alcohol-modified or acetal-protected. The hydrolyzable silane related to the hydrolysis condensate can contain one or more hydrolyzable silanes.

The polysiloxane can have a structure having any one of a cage type main chain, a ladder type main chain, a linear main chain, and a branched main chain. Furthermore, as the polysiloxane, a commercially available polysiloxane can be used.

Note that, in the present invention, “hydrolysis condensate” of a hydrolyzable silane, that is, a product of hydrolysis condensation includes not only a polyorganosiloxane polymer that is a condensate in which condensation is completely completed but also a polyorganosiloxane polymer that is a partial hydrolysis condensate in which condensation is not completely completed. Such a partial hydrolysis condensate is also a polymer obtained by hydrolysis and condensation of a hydrolyzable silane similarly to a condensate in which condensation is completely completed, but in the partial hydrolysis condensate, partially, hydrolysis occurs but condensation does not occur, and therefore a Si—OH group remains. In the silicon-containing resist underlayer film forming composition, in addition to the hydrolysis condensate, an uncondensed hydrolysate (a complete hydrolysate or a partial hydrolysate) or a monomer (hydrolyzable silane) may remain.

Note that, in the present specification, “hydrolyzable silane” may also be simply referred to as “silane compound”.

Examples of the polysiloxane include a hydrolysis condensate of a hydrolyzable silane containing at least one hydrolyzable silane represented by the following formula (1).

<<Formula (1)>>

[Chemical Formula 1]

R¹ₐSi(R²)₄₋ₐ (1)

In formula (1), R¹ is a group bonded to a silicon atom, and R¹s each independently represent an alkyl group optionally having a substituent, an aryl group optionally having a substituent, an aralkyl group optionally having a substituent, an halogenated alkyl group optionally having a substituent, a halogenated aryl group optionally having a substituent, a halogenated aralkyl group optionally having a substituent, an alkoxyalkyl group optionally having a substituent, an alkoxyaryl group optionally having a substituent, an alkoxyaralkyl group optionally having a substituent, an alkenyl group optionally having a substituent, an organic group having an epoxy group, an organic group having an acryloyl group, an organic group having a methacryloyl group, an organic group having a mercapto group, an organic group having an amino group, an organic group having an alkoxy group, an organic group having a sulfonyl group, an organic group having a cyano group, or a combination of two or more thereof.

R² is a group or an atom bonded to a silicon atom, and R²s each independently represent an alkoxy group, an aralkyloxy group, an acyloxy group, or a halogen atom.

a represents an integer of 0 to 3.

### <<<R¹>>>

The alkyl group may be linear, branched, or cyclic, and the number of carbon atoms thereof is not particularly limited, but is preferably 40 or less, more preferably 30 or less, still more preferably 20 or less, and further still more preferably 10 or less.

As the alkyl group, specific examples of the linear or branched alkyl group include a methyl group, an ethyl group, a n-propyl group, an i-propyl group, a n-butyl group, an i-butyl group, a s-butyl group, a t-butyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

Note that, in the present specification, “i” means “iso”, “s” means “sec”, and “t” means “tert”.

Specific examples of the cyclic alkyl group include: a cycloalkyl group such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, or a 2-ethyl-3-methyl-cyclopropyl group; and a crosslinked cyclic cycloalkyl group such as a bicyclobutyl group, a bicyclopentyl group, a bicyclohexyl group, a bicycloheptyl group, a bicyclooctyl group, a bicyclononyl group, or a bicyclodecyl group.

The aryl group may be any of a phenyl group, a monovalent group derived by removing one hydrogen atom of a condensed ring aromatic hydrocarbon compound, and a monovalent group derived by removing one hydrogen atom of a ring-linked aromatic hydrocarbon compound, and the number of carbon atoms of the aryl group is not particularly limited, but is preferably 40 or less, more preferably 30 or less, and still more preferably 20 or less.

Examples of the aryl group include an aryl group having 6 to 20 carbon atoms, and examples thereof include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, a triphenylenyl group, a biphenyl-2-yl group (o-biphenylyl group), a biphenyl-3-yl group (m-biphenylyl group), a biphenyl-4-yl group (p-biphenylyl group), a paraterphenyl-4-yl group, a metaterphenyl-4-yl group, an orthoterphenyl-4-yl group, a 1,1′-binaphthyl-2-yl group, and a 2,2′-binaphthyl-1-yl group, but are not limited thereto.

The aralkyl group is an alkyl group having a substituent of an aryl group, and as specific examples of such an aryl group and an alkyl group, those described above can be exemplified. The number of carbon atoms of the aralkyl group is not particularly limited, but is preferably 40 or less, more preferably 30 or less, and still more preferably 20 or less.

Specific examples of the aralkyl group include a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group, but are not limited thereto.

The halogenated alkyl group, the halogenated aryl group, and the halogenated aralkyl group are an alkyl group having substituents of one or more halogen atoms, an aryl group having substituents of one or more halogen atoms, and an aralkyl group having substituents of one or more halogen atoms, respectively, and as specific examples of such an alkyl group, an aryl group, and an aralkyl group, those described above can be exemplified.

Examples of the halogen atom include a fluorine atom, a chlorine atom, a bromine atom, and an iodine atom.

The number of carbon atoms of the halogenated alkyl group is not particularly limited, but is preferably 40 or less, more preferably 30 or less, still more preferably 20 or less, and further still more preferably 10 or less. Specific examples of the halogenated alkyl group include a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropan-2-yl group, a 3-bromo-2-methylpropyl group, a 4-bromobutyl group, and a perfluoropentyl group, but are not limited thereto.

The number of carbon atoms of the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7 difluoro 1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7 difluoro-2-naphthyl group, and a heptafluoro-2-naphthyl group, and also include a group in which a fluorine atom (fluoro group) in these groups is optionally replaced with a chlorine atom (chloro group), a bromine atom (bromo group), or an iodine atom (iodo group), but are not limited thereto.

The number of carbon atoms of the halogenated aralkyl group is not particularly limited, but is preferably 40 or less, more preferably 30 or less, and still more preferably 20 or less.

Specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, and a 2,3,4,5,6-pentafluorobenzyl group, and also include a group in which a fluorine atom (fluoro group) in these groups is optionally replaced with a chlorine atom (chloro group), a bromine atom (bromo group), or an iodine atom (iodo group), but are not limited thereto.

The alkoxyalkyl group, the alkoxyaryl group, and the alkoxyaralkyl group are an alkyl group having substituents of one or more alkoxy groups, an aryl group having substituents of one or more alkoxy groups, and an aralkyl group having substituents of one or more alkoxy groups, respectively, and as specific examples of such an alkyl group, an aryl group, and an aralkyl group, those described above can be exemplified.

Examples of the alkoxy group as a substituent include an alkoxy group having at least one of a linear alkyl moiety, a branched alkyl moiety, and a cyclic alkyl moiety each having 1 to 20 carbon atoms.

Examples of the linear or branched alkoxy group include a methoxy group, an ethoxy group, a n-propoxy group, an i-propoxy group, a n-butoxy group, an i-butoxy group, an s-butoxy group, a t-butoxy group, a n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

Specific examples of the alkoxyalkyl group include a lower (about 5 or less carbon atoms) alkyloxy lower (about 5 or less carbon atoms) alkyl group such as a methoxymethyl group, an ethoxymethyl group, a 1-ethoxyethyl group, a 2-ethoxyethyl group, or an ethoxymethyl group, but are not limited thereto.

Specific examples of the alkoxyaryl group include a 2-methoxyphenyl group, a 3-methoxyphenyl group, a 4-methoxyphenyl group, a 2-(1-ethoxy)phenyl group, a 3-(1-ethoxy)phenyl group, a 4-(1-ethoxy)phenyl group, a 2-(2-ethoxy)phenyl group, a 3-(2-ethoxy)phenyl group, a 4-(2-ethoxy)phenyl group, a 2-methoxynaphthalen-1-yl group, a 3-methoxynaphthalen-1-yl group, a 4-methoxynaphthalen-1-yl group, a 5-methoxynaphthalen-1-yl group, a 6-methoxynaphthalen-1-yl group, and a 7-methoxynaphthalen-1-yl group, but are not limited thereto.

Specific examples of the alkoxyaralkyl group include a 3-(methoxyphenyl)benzyl group and a 4-(methoxyphenyl)benzyl group, but are not limited thereto.

The alkenyl group may be linear or branched, and the number of carbon atoms thereof is not particularly limited, but is preferably 40 or less, more preferably 30 or less, still more preferably 20 or less, and further still more preferably 10 or less.

Specific examples of the alkenyl group include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group, and also include a crosslinked cyclic alkenyl group such as a bicycloheptenyl group (norbornyl group).

Examples of the substituent in the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group described above include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group, and as specific examples thereof and the preferred numbers of carbon atoms thereof, those described above or below can be exemplified.

The aryloxy group exemplified in the substituent is a group in which an aryl group is bonded via an oxygen atom (—O—), and as specific examples of such an aryl group, those described above can be exemplified. The number of carbon atoms of the aryloxy group is not particularly limited, but is preferably 40 or less, more preferably 30 or less, and still more preferably 20 or less, and specific examples thereof include a phenoxy group and a naphthalen-2-yloxy group, but are not limited thereto.

When there are two or more substituents, the substituents may be bonded to each other to form a ring.

Examples of the organic group having an epoxy group include a glycidoxymethyl group, a glycidoxyethyl group, a glycidoxypropyl group, a glycidoxybutyl group, and an epoxy cyclohexyl group.

Examples of the organic group having an acryloyl group include an acryloylmethyl group, an acryloylethyl group, and an acryloylpropyl group.

Examples of the organic group having a methacryloyl group include a methacryloyl methyl group, a methacryloyl ethyl group, and a methacryloyl propyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include an amino group, an aminomethyl group, an aminoethyl group, an aminophenyl group, a dimethylaminoethyl group, and a dimethylaminopropyl group, but are not limited thereto. The organic group having an amino group will be described later in more detail.

Examples of the organic group having an alkoxy group include a methoxymethyl group and a methoxyethyl group, but are not limited thereto. Note that a group in which an alkoxy group is directly bonded to a silicon atom is excluded.

Examples of the organic group having a sulfonyl group include a sulfonylalkyl group and a sulfonylaryl group, but are not limited thereto.

Examples of the organic group having a cyano group include a cyanoethyl group, a cyanopropyl group, a cyanophenyl group, and a thiocyanate group.

Examples of the organic group having an amino group include an organic group having at least one of a primary amino group, a secondary amino group, and a tertiary amino group. A hydrolysis condensate in which a hydrolyzable silane having a tertiary amino group is hydrolyzed with a strong acid to form a counter cation having a tertiary ammonium group can be preferably used. The organic group can contain a hetero atom such as an oxygen atom or a sulfur atom in addition to a nitrogen atom constituting an amino group.

Preferable examples of the organic group having an amino group include a group represented by the following formula (A1).

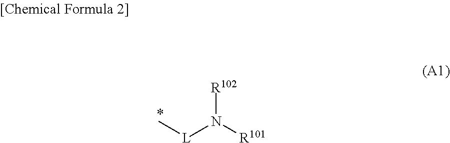

In formula (A1), R¹⁰¹ and R¹⁰² each independently represent a hydrogen atom or a hydrocarbon group, and Ls each independently represent an alkylene group optionally having a substituent. * represents a bond.

Examples of the hydrocarbon group include an alkyl group, an alkenyl group, and an aryl group, but are not limited thereto. As specific examples of the alkyl group, the alkenyl group, and the aryl group, those described above in R¹ can be exemplified.

The alkylene group may be linear or branched, and the number of carbon atoms thereof is usually 1 to 10, and preferably 1 to 5. Examples thereof include a linear alkylene group such as a methylene group, an ethylene group, a trimethylene group, a tetramethylene group, a pentamethylene group, a hexamethylene group, a heptamethylene group, an octamethylene group, a nonamethylene group, or a decamethylene group.

Examples of the organic group having an amino group include an amino group, an aminomethyl group, an aminoethyl group, an aminophenyl group, a dimethylaminoethyl group, and a dimethylaminopropyl group, but are not limited thereto.

### <<<R²>>>

Examples of the alkoxy group in R² include the alkoxy groups exemplified in the description of R¹.

Examples of the halogen atom in R² include the halogen atoms exemplified in the description of R¹.

The aralkyloxy group is a monovalent group derived by removing a hydrogen atom from a hydroxy group of an aralkyl alcohol, and as specific examples of an aralkyl group in the aralkyloxy group, those described above can be exemplified.

The number of carbon atoms of the aralkyloxy group is not particularly limited, but can be, for example, 40 or less, preferably 30 or less, and more preferably 20 or less.

Specific examples of the aralkyloxy group include a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, and a 10-phenyl-n-decyloxy group, but are not limited thereto.

The acyloxy group is a monovalent group derived by removing a hydrogen atom from a carboxyl group (—COOH) of a carboxylic acid compound, and typical examples thereof include an alkylcarbonyloxy group, an arylcarbonyloxy group, or an aralkylcarbonyloxy group derived by removing a hydrogen atom from a carboxyl group of an alkyl carboxylic acid, an aryl carboxylic acid, or an aralkyl carboxylic acid, but are not limited thereto. As specific examples of the alkyl group, the aryl group, and the aralkyl group in such an alkyl carboxylic acid, an aryl carboxylic acid, and an aralkyl carboxylic acid, those described above can be exemplified.

Specific examples of the acyloxy group include an acyloxy group having 2 to 20 carbon atoms, and examples thereof include a methylcarbonyloxy group, an ethylcarbonyloxy group, a n-propylcarbonyloxy group, an i-propylcarbonyloxy group, a n-butylcarbonyloxy group, an i-butylcarbonyloxy group, a s-butylcarbonyloxy group, a t-butylcarbonyloxy group, a n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, a n-hexylcarbonyloxy group, a 1-methyl-n-pentylcarbonyloxy group, a 2-methyl-n-pentylcarbonyloxy group, a 3-methyl-n-pentylcarbonyloxy group, a 4-methyl-n-pentylcarbonyloxy group, a 1,1-dimethyl-n-butylcarbonyloxy group, a 1,2-dimethyl-n-butylcarbonyloxy group, a 1,3-dimethyl-n-butylcarbonyloxy group, a 2,2-dimethyl-n-butylcarbonyloxy group, a 2,3-dimethyl-n-butylcarbonyloxy group, a 3,3-dimethyl-n-butylcarbonyloxy group, a 1-ethyl-n-butylcarbonyloxy group, a 2-ethyl-n-butylcarbonyloxy group, a 1,1,2-trimethyl-n-propylcarbonyloxy group, a 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

### <<<Specific Examples of Hydrolyzable Silane Represented by Formula (1)>>>

Specific examples of the hydrolyzable silane represented by formula (1) include tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl) propyltrimethoxysilane, γ-(3,4-epoxycyclohexyl) propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldidichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl)silane, triethoxy((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanate propyltriethoxysilane, chloromethyltrimethoxysilane, chloromethyltriethoxysilane, triethoxysilylpropyldiallyl isocyanurate, bicyclo[2,2,1]heptenyltriethoxysilane, benzenesulfonylpropyltriethoxysilane, benzenesulfonamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, silanes represented by the following formulas (A-1) to (A-41), and silanes represented by the following formulas (1-1) to (1-290), but are not limited thereto.

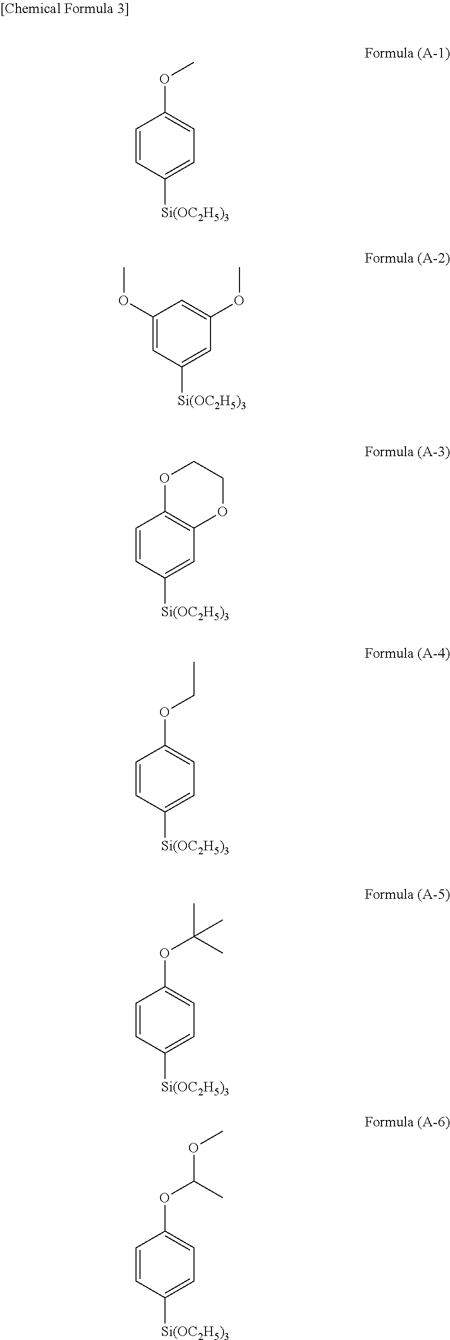

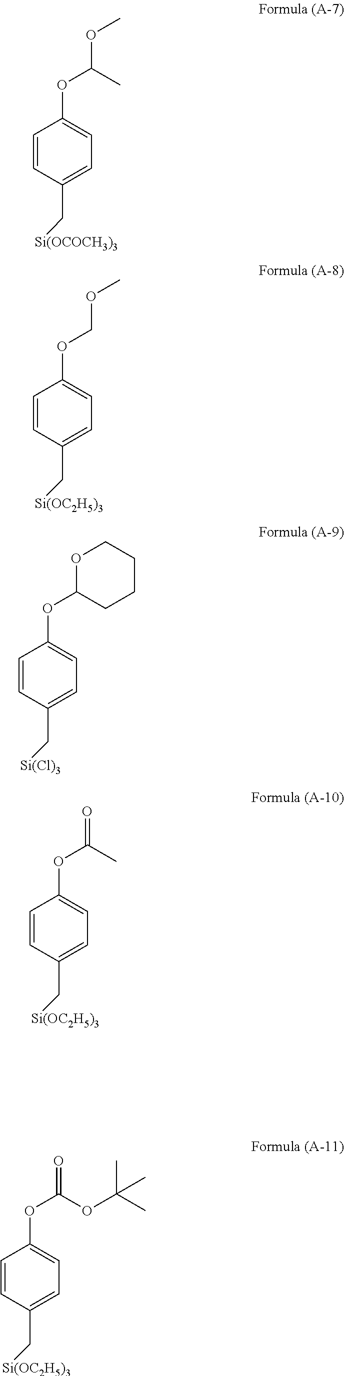

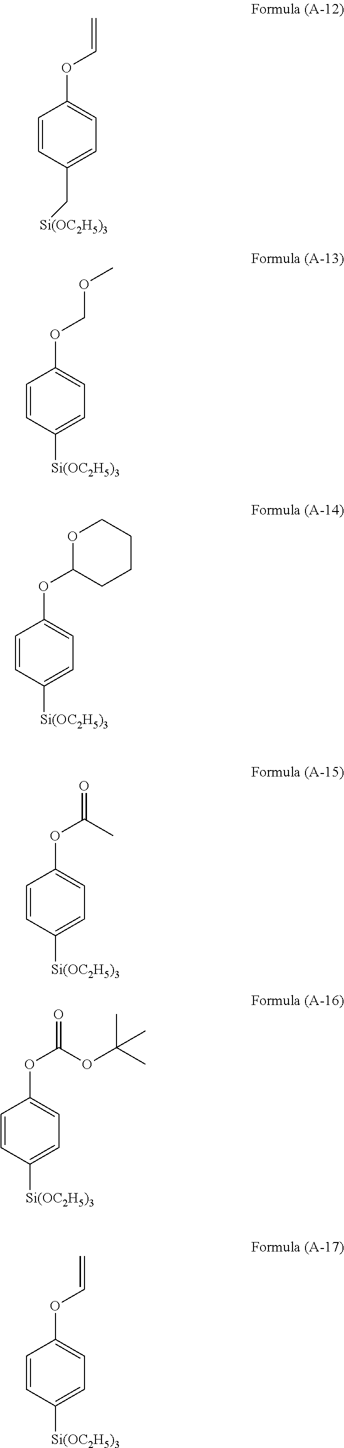

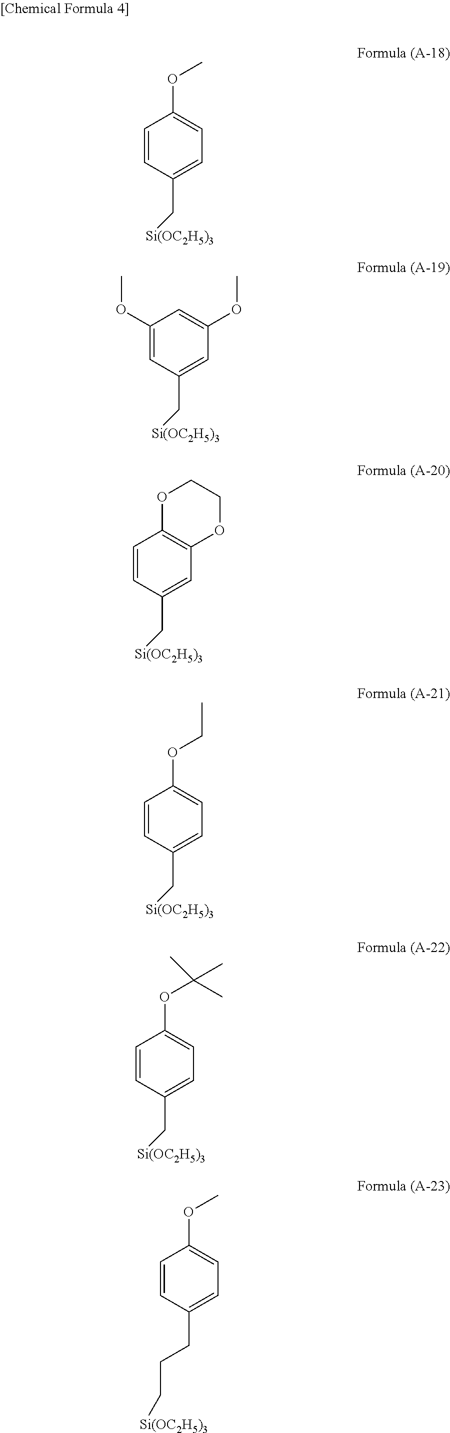

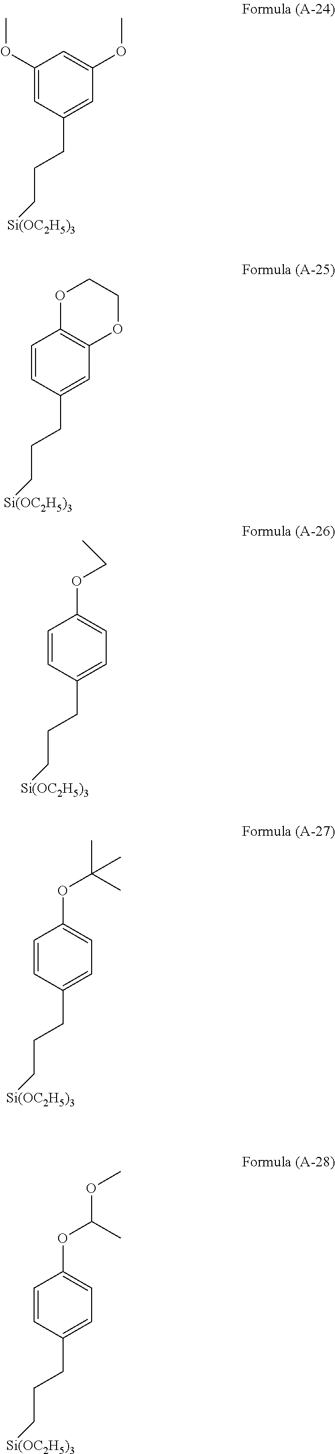

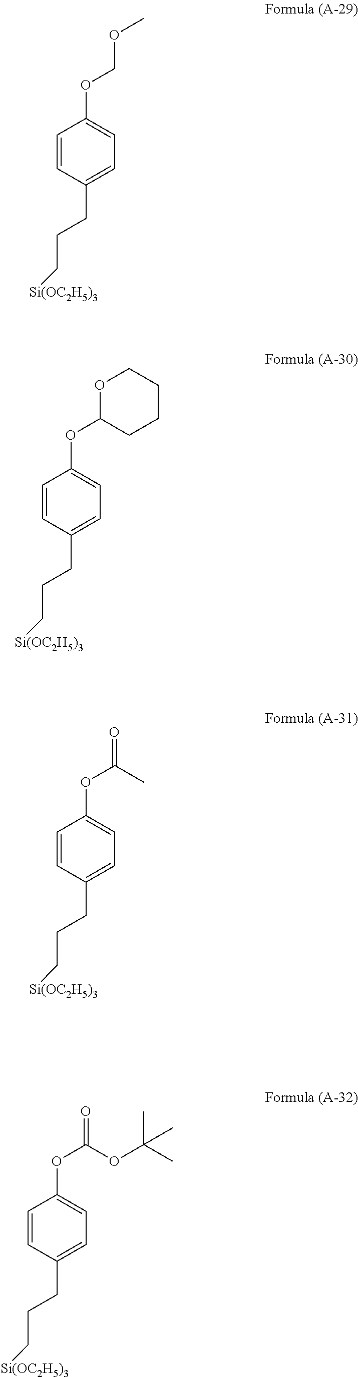

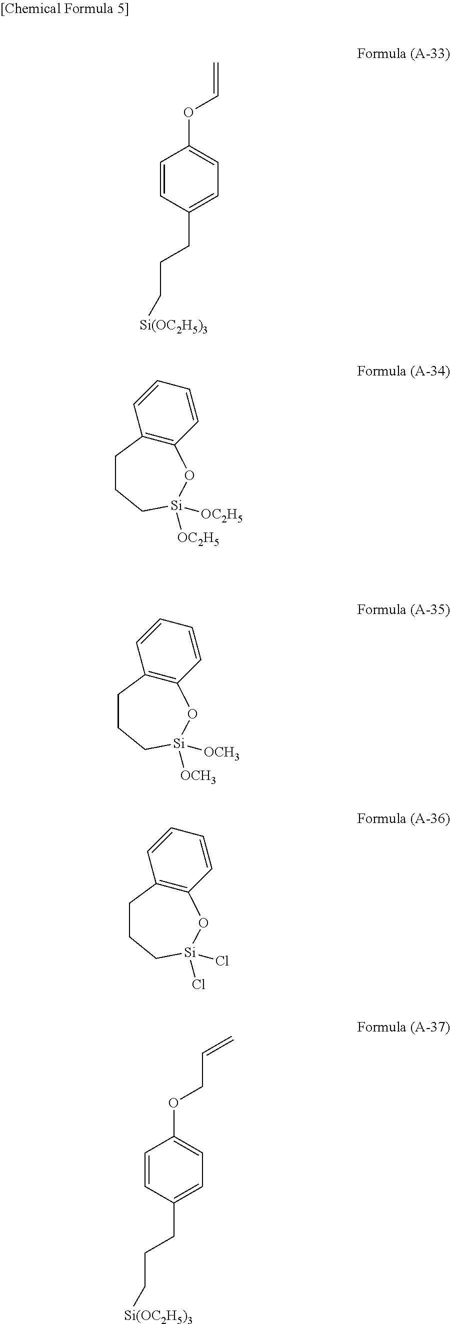

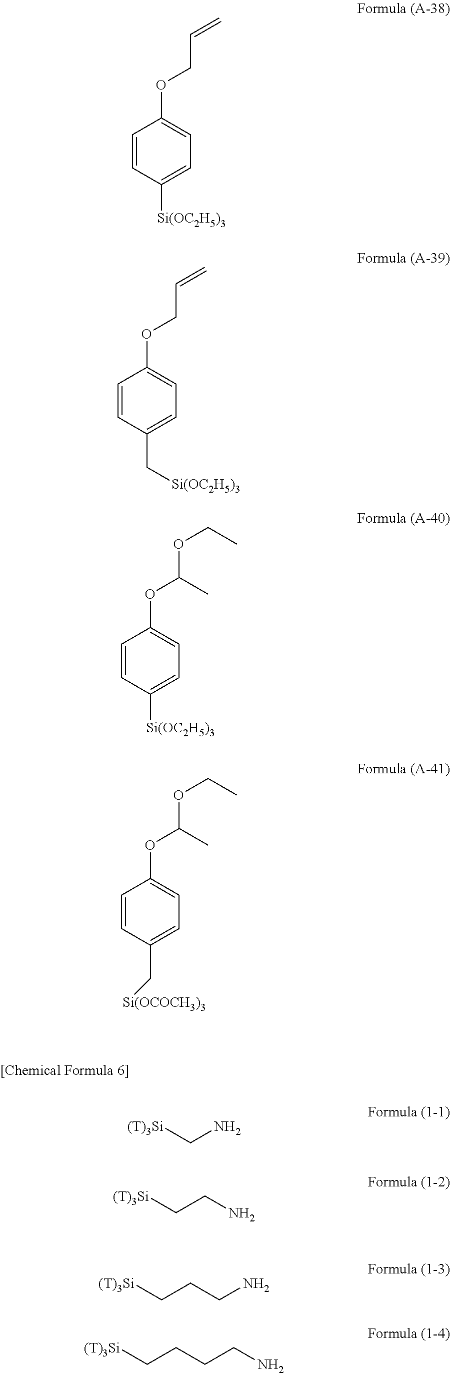

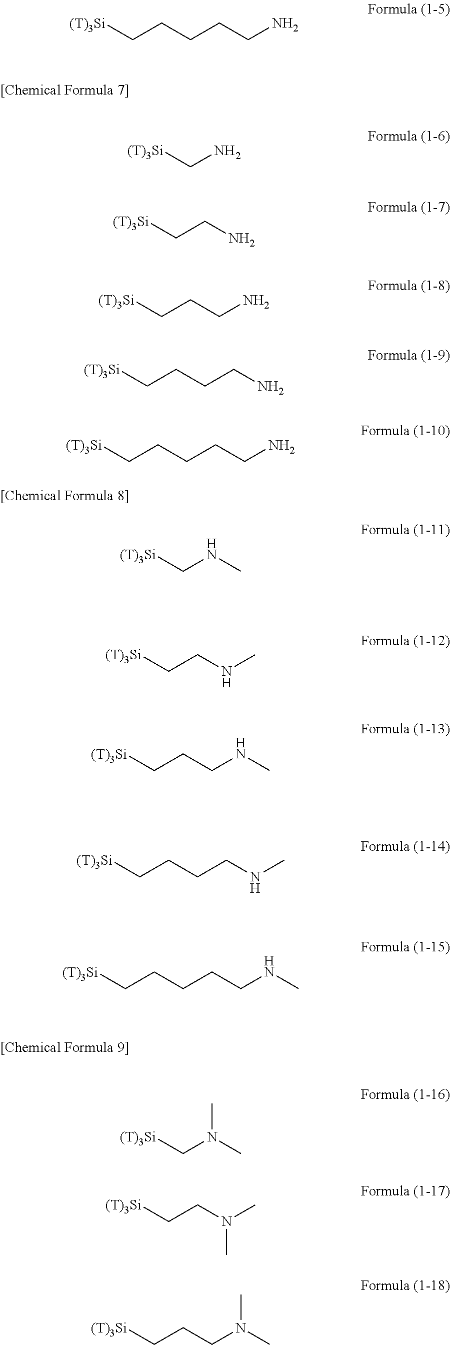

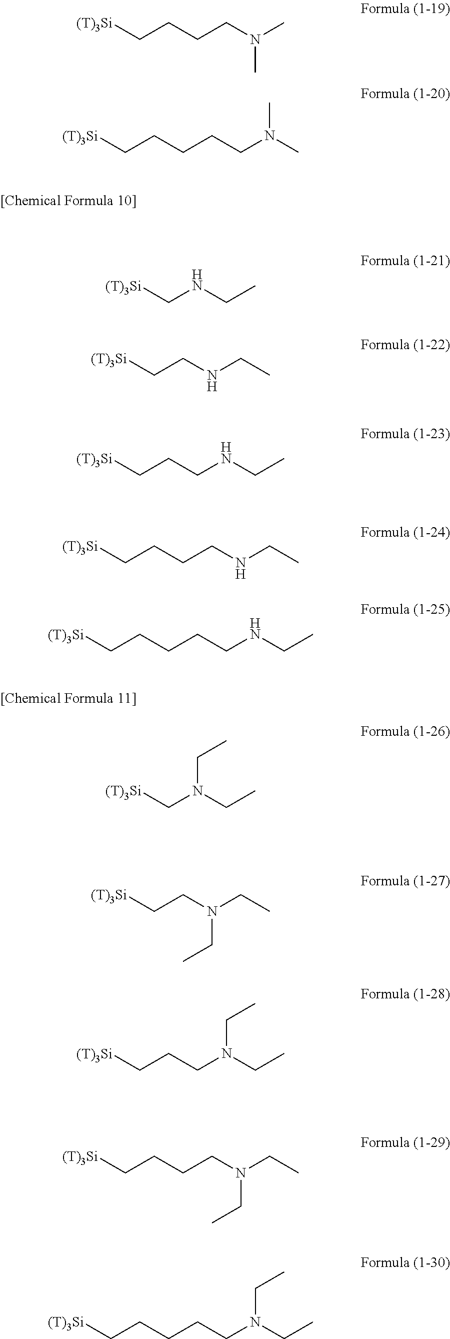

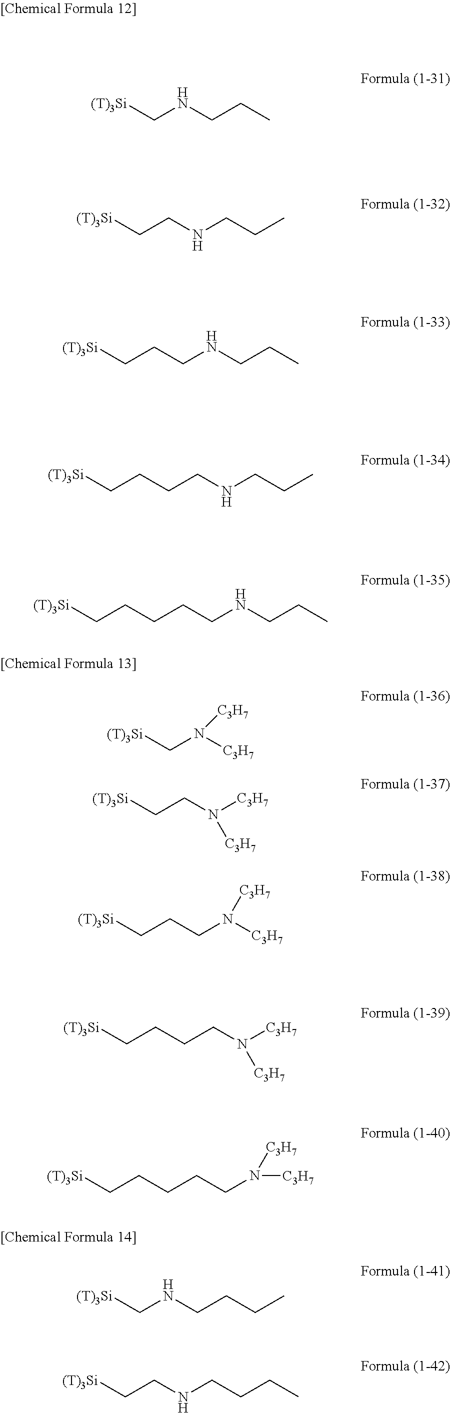

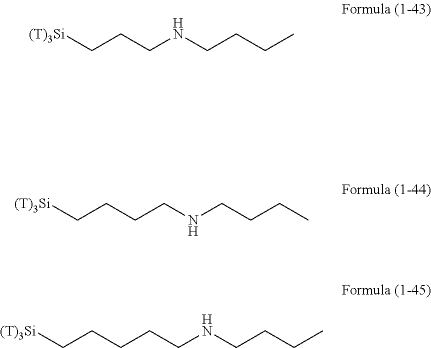

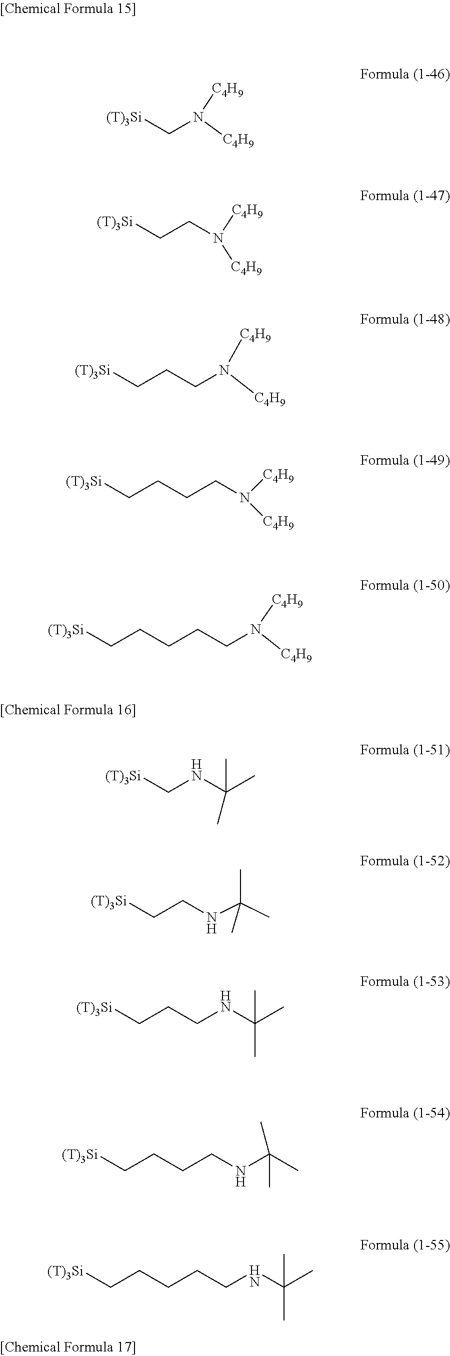

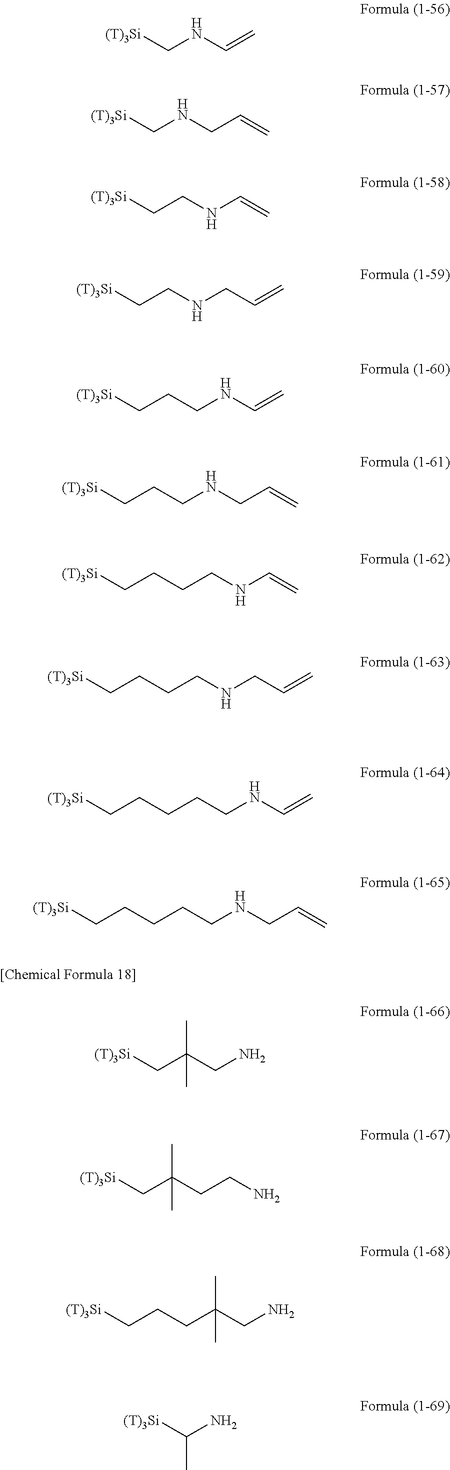

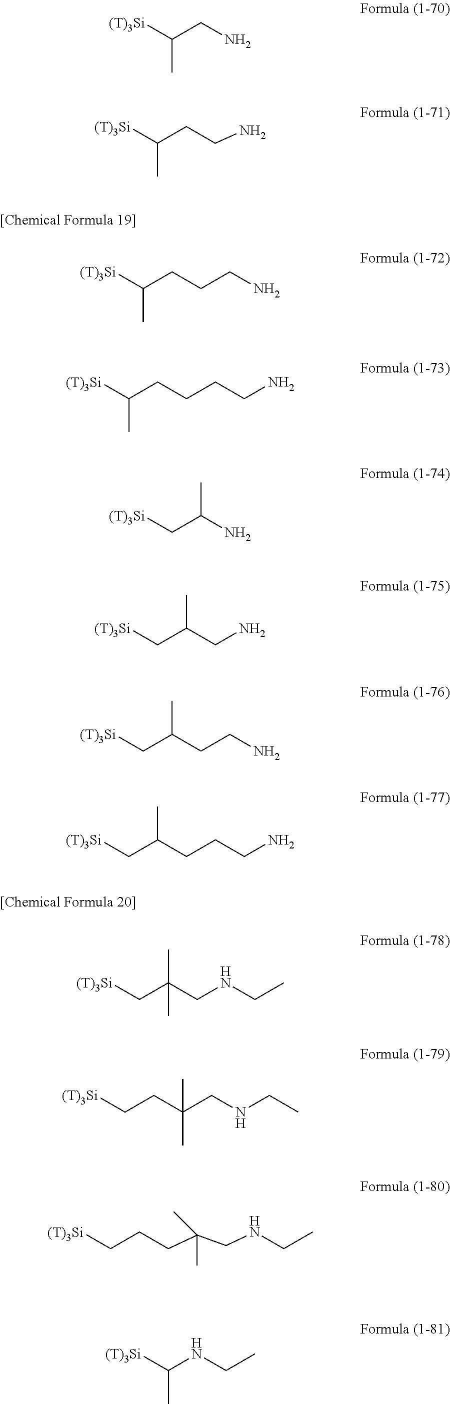

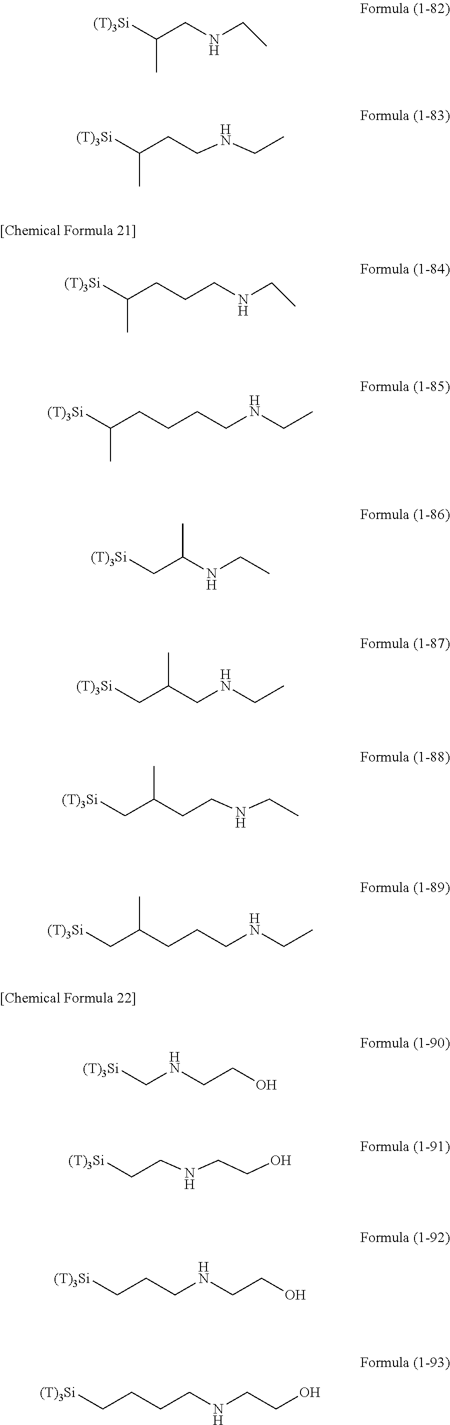

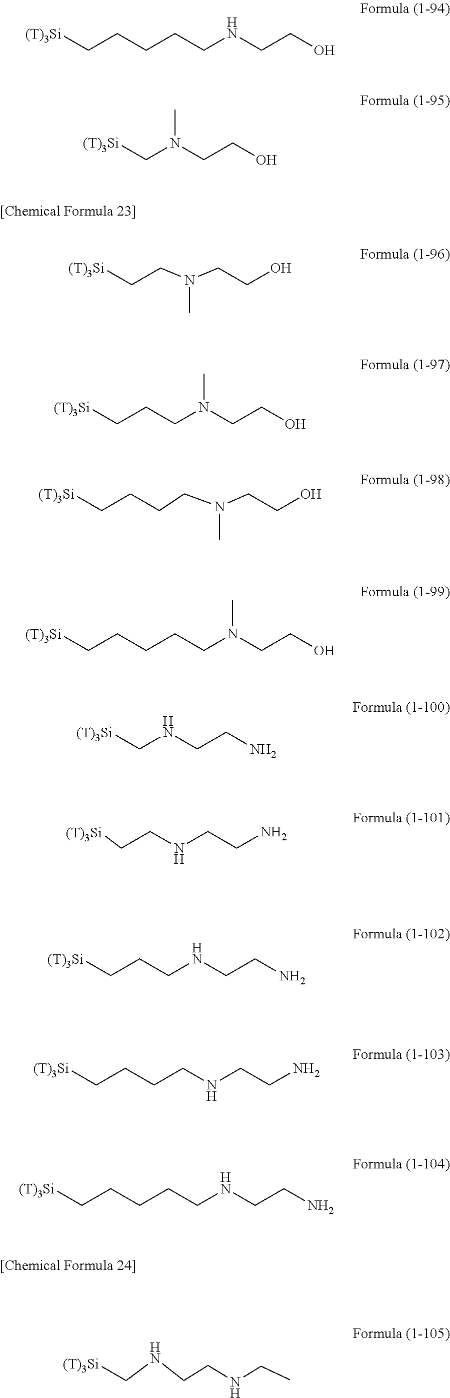

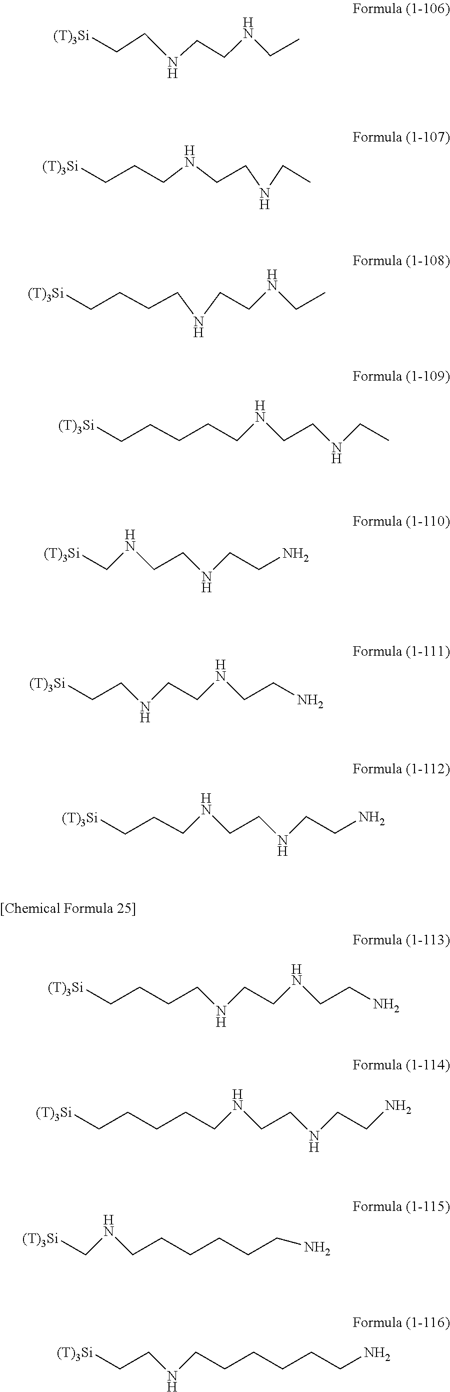

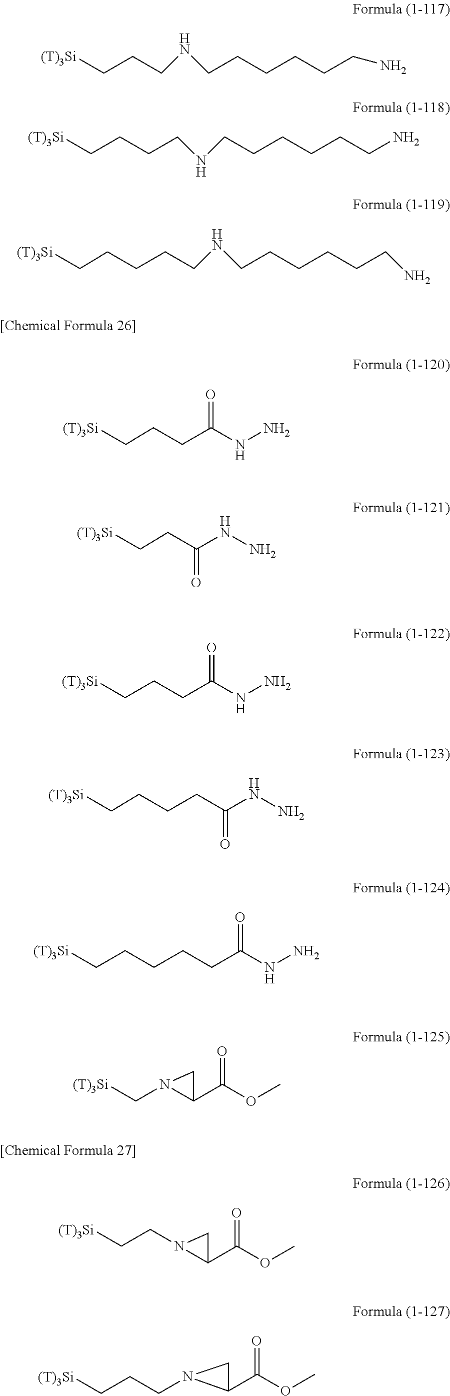

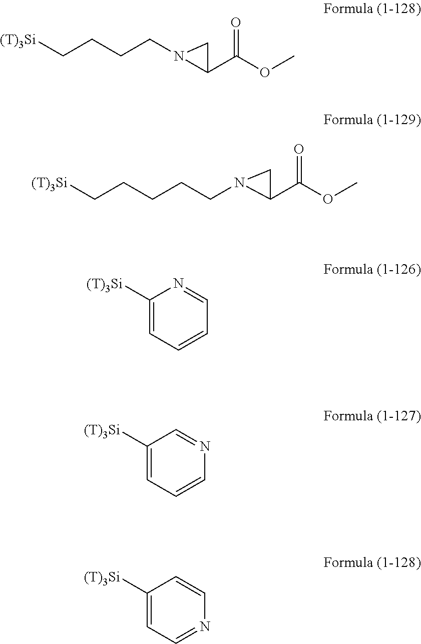

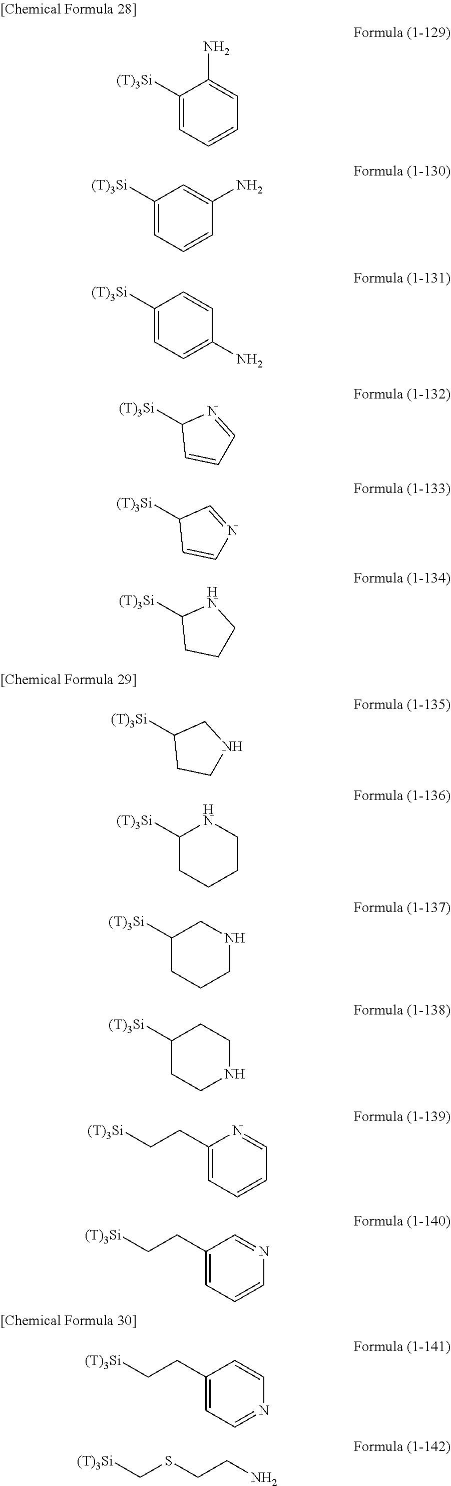

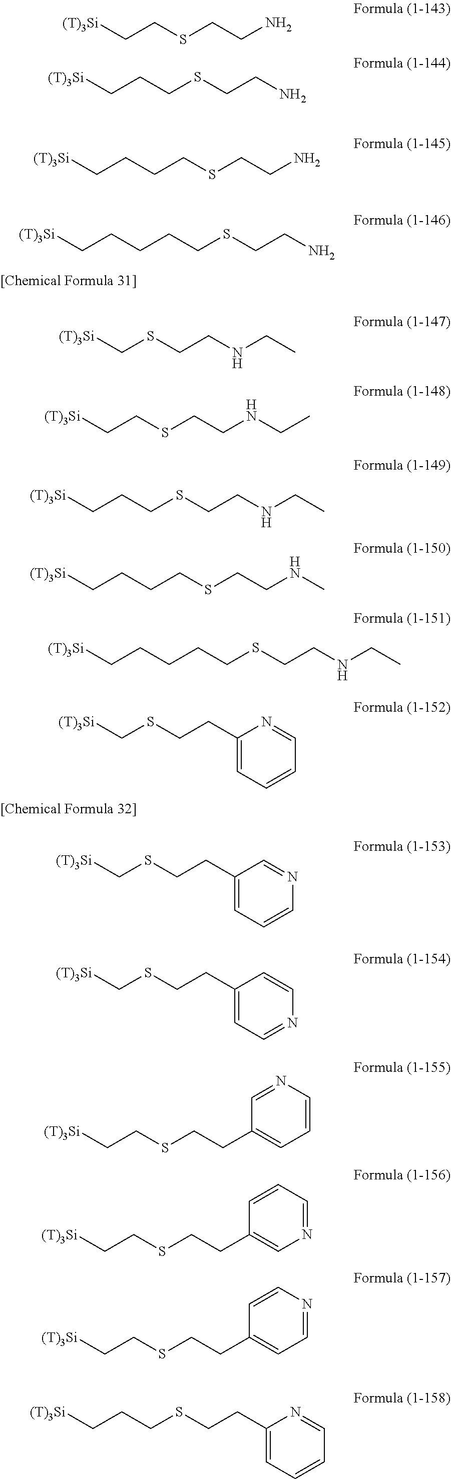

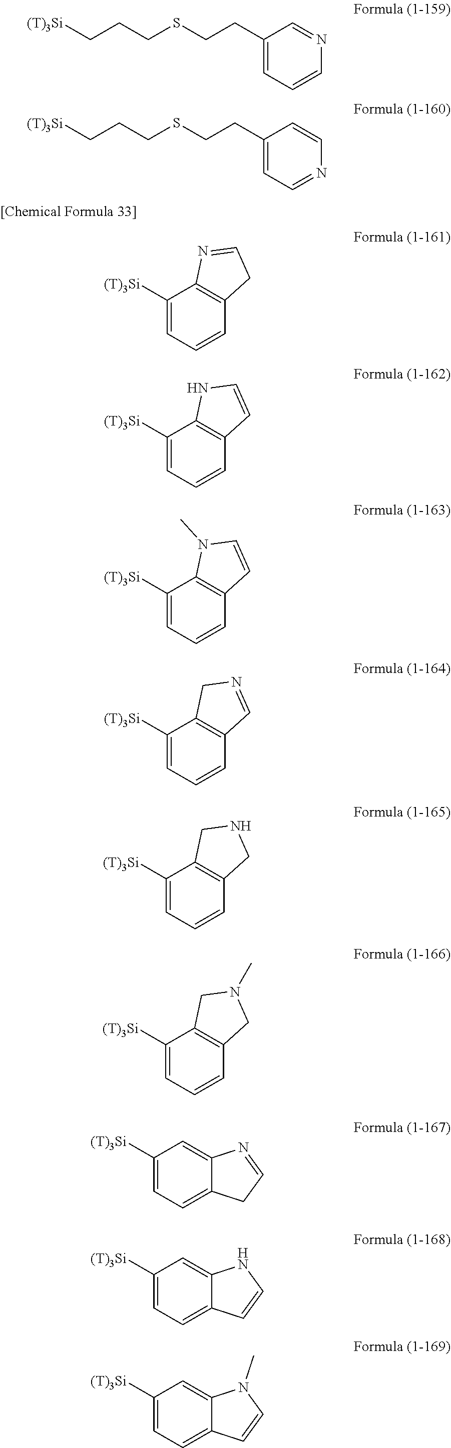

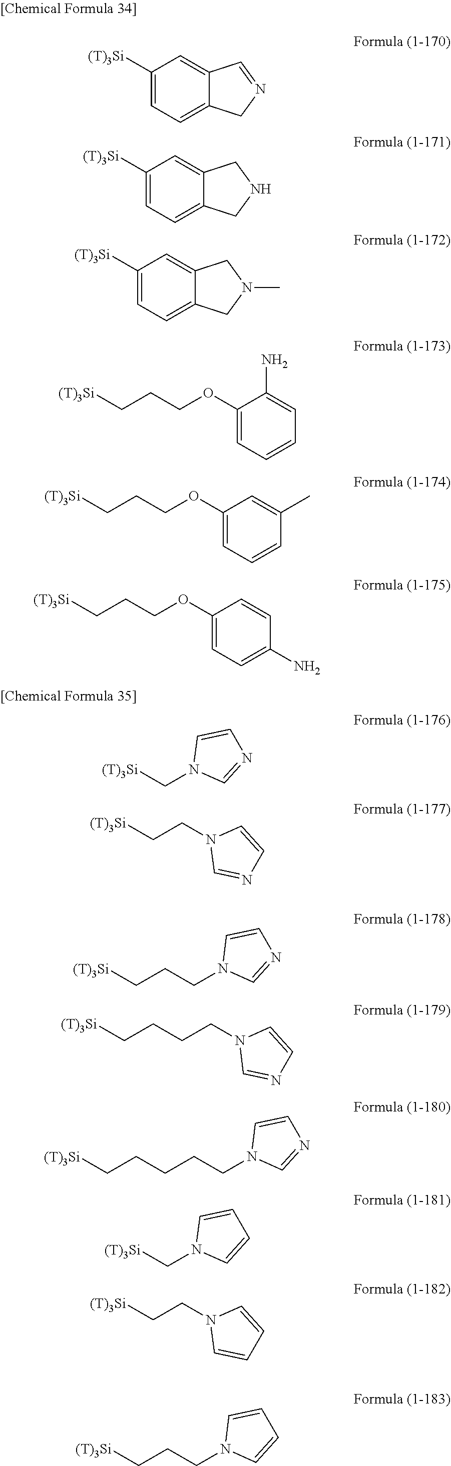

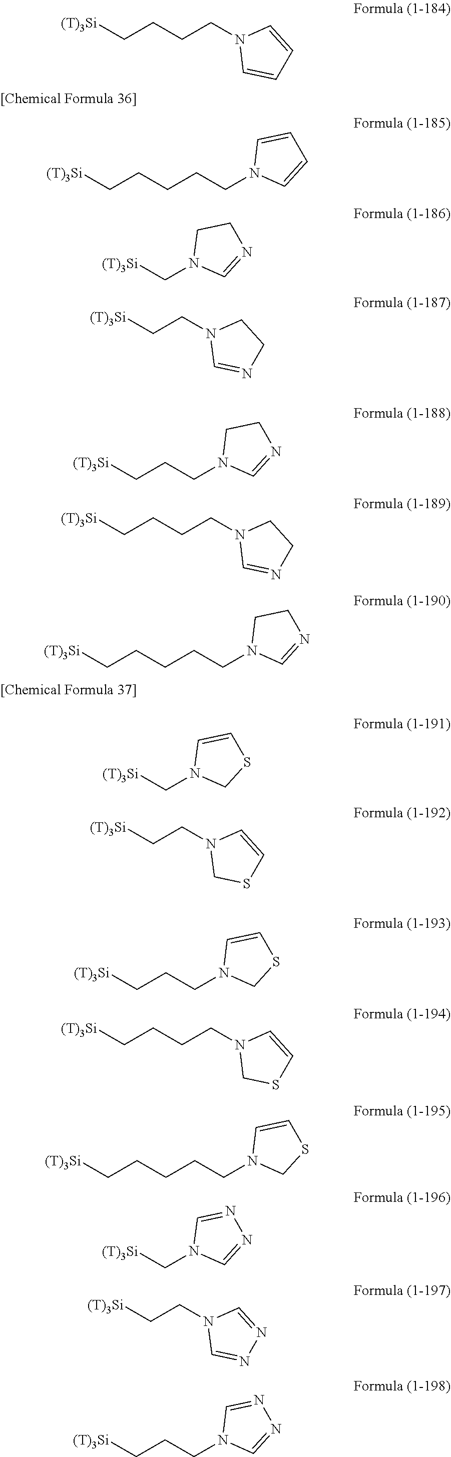

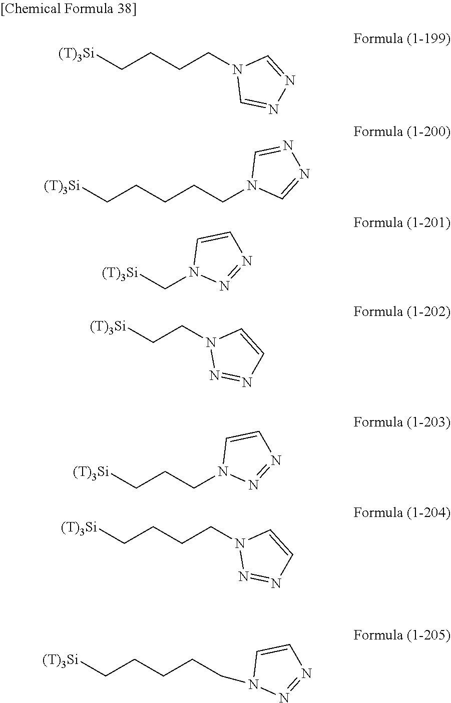

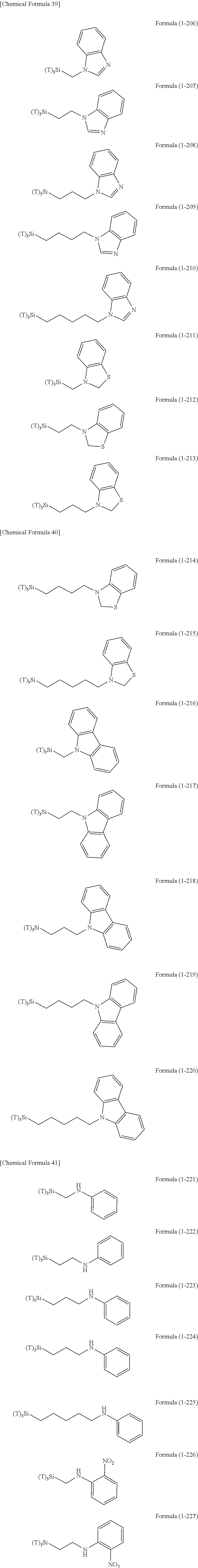

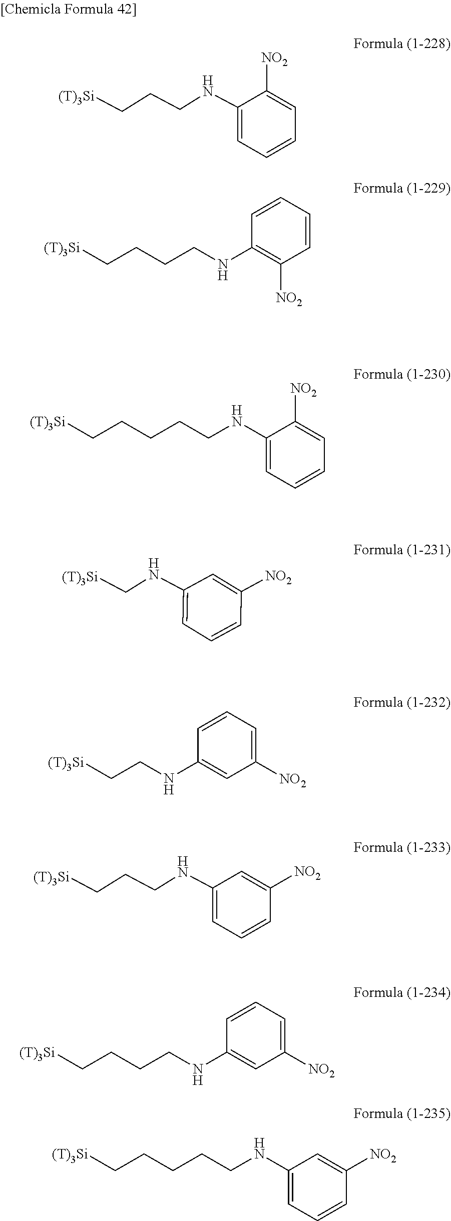

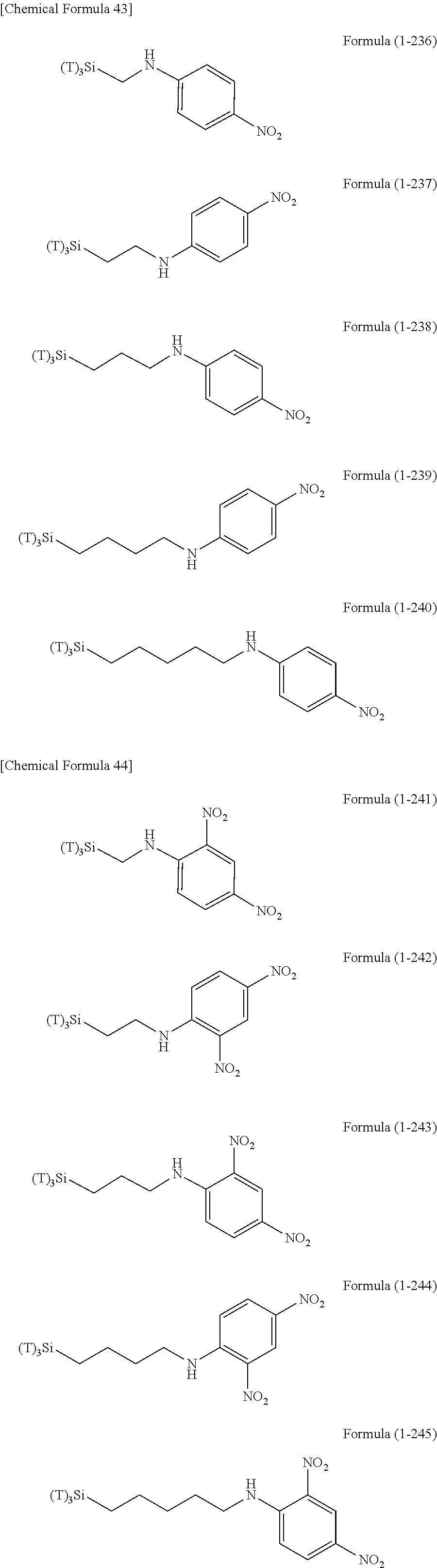

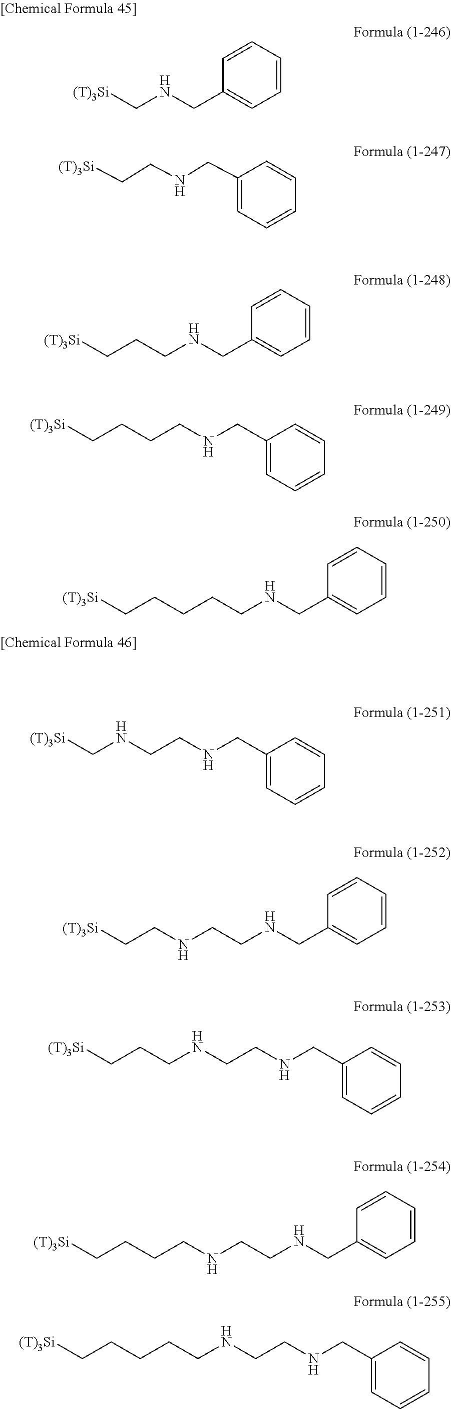

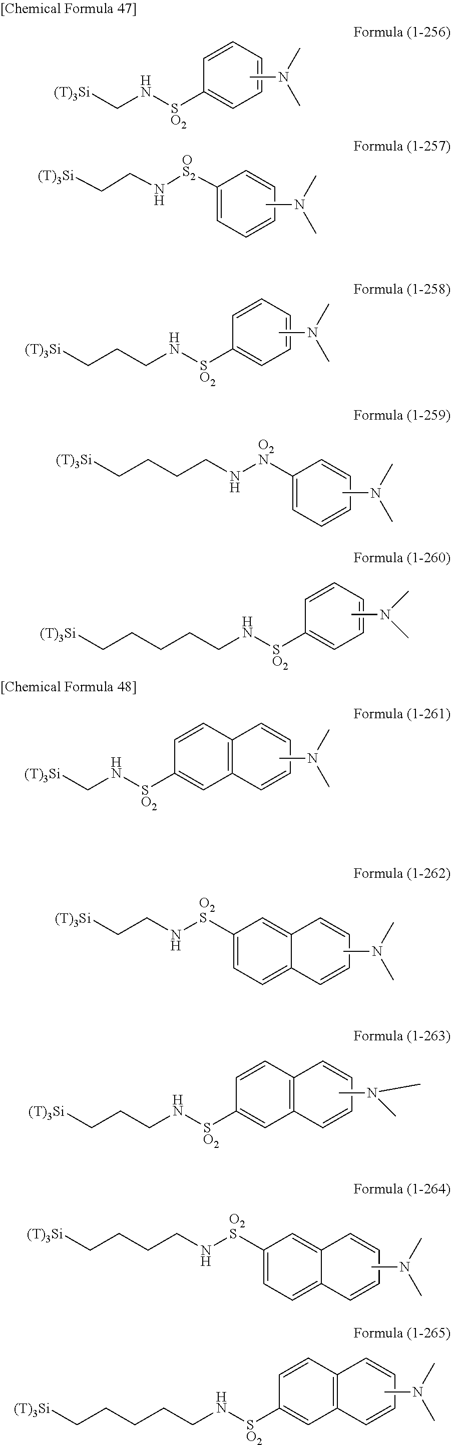

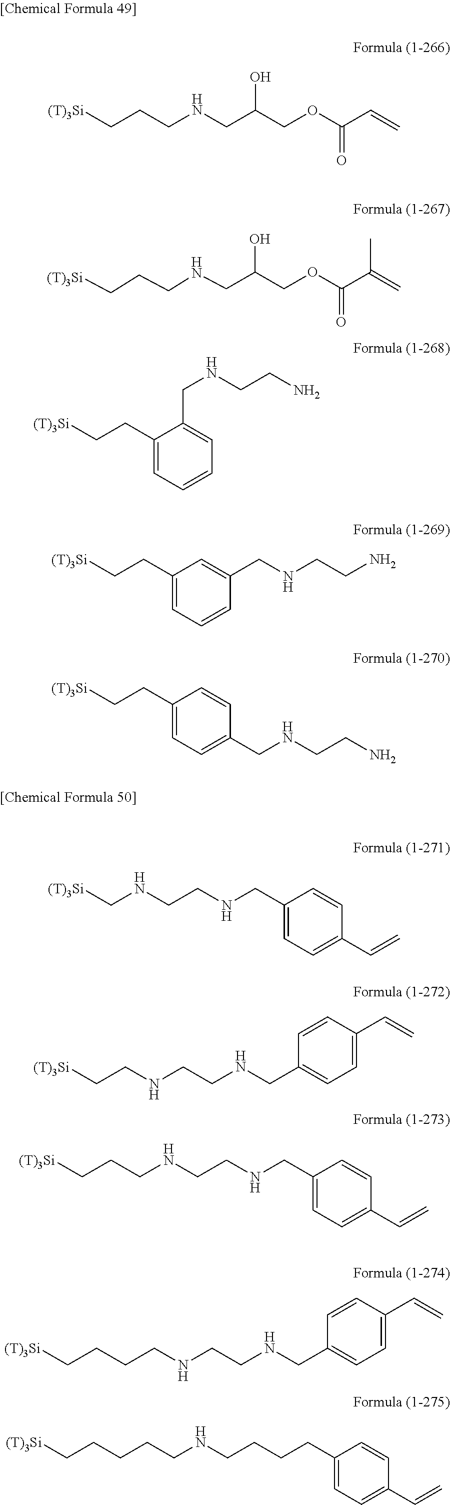

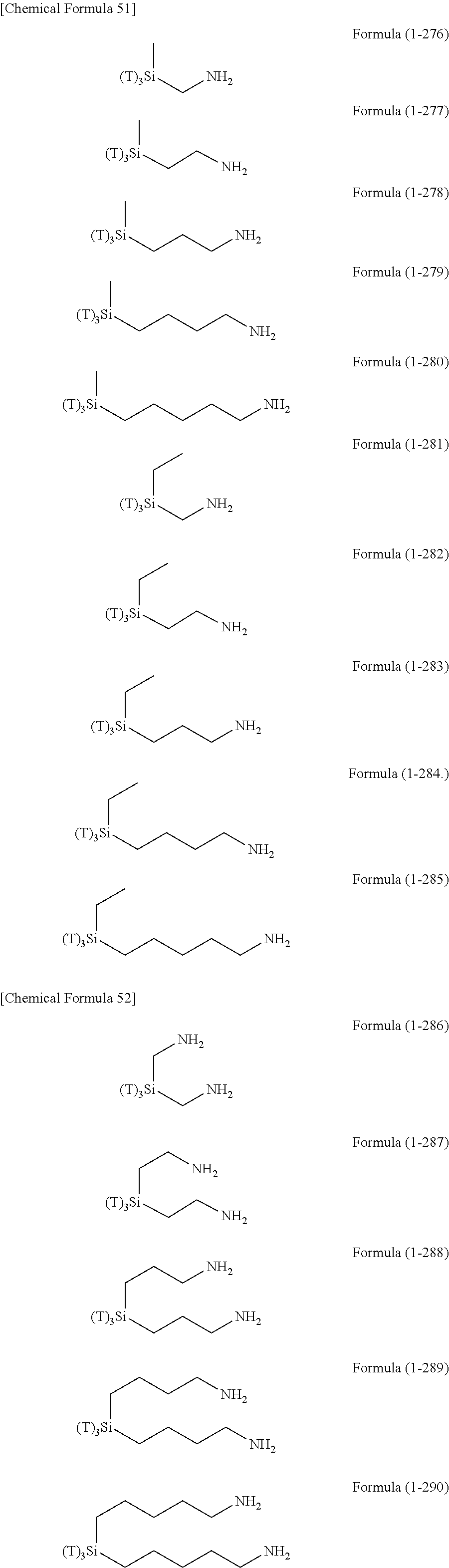

In formulas (1-1) to (1-290), Ts each independently represent an alkoxy group, an acyloxy group, or a halogen group, and for example, preferably represent a methoxy group or an ethoxy group.

Examples of [A] polysiloxane include a hydrolysis condensate of a hydrolyzable silane containing a hydrolycable silane represented by the following formula (2) together with the hydrolyzable silane represented by formula (1) or in place of the hydrolyzable silane represented by formula (1).

<<Formula (2)>>

[Chemical Formula 53]

[R³_{b}Si(R⁴)_{3-b}]₂R⁵_{c} (2)

In formula (2), R³ is a group bonded to a silicon atom, and R's each independently represent an alkyl group optionally having a substituent, an aryl group optionally having a substituent, an aralkyl group optionally having a substituent, an halogenated alkyl group optionally having a substituent, a halogenated aryl group optionally having a substituent, a halogenated aralkyl group optionally having a substituent, an alkoxyalkyl group optionally having a substituent, an alkoxyaryl group optionally having a substituent, an alkoxyaralkyl group optionally having a substituent, an alkenyl group optionally having a substituent, an organic group having an epoxy group, an organic group having an acryloyl group, an organic group having a methacryloyl group, an organic group having a mercapto group, an organic group having an amino group, an organic group having an alkoxy group, an organic group having a sulfonyl group, an organic group having a cyano group, or a combination of two or more thereof.

R⁴ is a group or an atom bonded to a silicon atom, and R⁴s each independently represent an alkoxy group, an aralkyloxy group, an acyloxy group, or a halogen atom.

R⁵ is a group bonded to a silicon atom, and R⁵s each independently represent an alkylene group or an arylene group.

b represents 0 or 1, and c represents 0 or 1.

As specific examples of the groups in R³ and the preferred numbers of carbon atoms thereof, the groups and the numbers of carbon atoms described above for R¹ can be exemplified.

As specific examples of the groups and atoms in R⁴ and the preferred numbers of carbon atoms thereof, the groups, atoms, and the numbers of carbon atoms described above for R² can be exemplified.

Specific examples of the alkylene group in R⁵ include: an alkylene group including a linear alkylene group such as a methylene group, an ethylene group, a trimethylene group, a tetramethylene group, a pentamethylene group, a hexamethylene group, a heptamethylene group, an octamethylene group, a nonamethylene group, or a decamethylene group, and a branched alkylene group such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, or a 1-ethyltrimethylene group; and an alkanetriyl group such as a methanetriyl group, an ethane-1,1,2-triyl group, an ethane-1,2,2-triyl group, an ethane-2,2,2-triyl group, a propane-1,1,1-triyl group, a propane-1,1,2-triyl group, a propane-1,2,3-triyl group, a propane 1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane 1,2,2-triyl group, a butane-2,2,3-triyl group, a 2-methylpropane-1,1,1-triyl group, a 2-methylpropane-1,1,2-triyl group, or a 2-methylpropane-1,1,3-triyl group, but are not limited thereto.

Specific examples of the arylene group in R⁵ include: a 1,2-phenylene group, a 1,3-phenylene group, and a 1,4-phenylene group; a group derived by removing two hydrogen atoms on an aromatic ring of a condensed ring aromatic hydrocarbon compound, such as a 1,5-naphthalenediyl group, a 1,8-naphthalenediyl group, a 2,6-naphthalenediyl group, a 2,7-naphthalenediyl group, a 1,2-anthracenediyl group, a 1,3-anthracenediyl group, a 1,4-anthracenediyl group, a 1,5-anthracenediyl group, a 1,6-anthracenediyl group, a 1,7-anthracenediyl group, a 1,8-anthracenediyl group, a 2,3-anthracenediyl group, a 2,6-anthracenediyl group, a 2,7-anthracenediyl group, a 2,9-anthracenediyl group, a 2,10-anthracenediyl group, or a 9,10-anthracenediyl group; and a group derived by removing two hydrogen atoms on an aromatic ring of a ring-linked aromatic hydrocarbon compound, such as a 4,4′-biphenyldiyl group or a 4,4″-paraterphenyldiyl group, but are not limited thereto.

b is preferably 0.

c is preferably 1.

Specific examples of the hydrolyzable silane represented by formula (2) include methylene bistrimethoxysilane, methylene bistrichlorosilane, methylene bistriacetoxysilane, ethylene bistriethoxysilane, ethylene bistrichlorosilane, ethylene bistriacetoxysilane, propylene bistriethoxysilane, butylene bistrimethoxysilane, phenylene bistrimethoxysilane, phenylene bistriethoxysilane, phenylene bismethyldiethoxysilane, phenylene bismethyldimethoxysilane, naphthylene bistrimethoxysilane, bistrimethoxysilane, bistriethoxysilane, bisethyldiethoxysilane, and bismethyldimethoxysilane, but are not limited thereto.

Examples of [A] polysiloxane include a hydrolysis condensate of a hydrolyzable silane containing, together with the hydrolyzable silane represented by formula (1) and/or the hydrolyzable silane represented by formula (2), another hydrolyzable silane exemplified below.

Examples of the other hydrolyzable silane include a silane compound having an onium group in a molecule, a silane compound having a sulfone group, a silane compound having a sulfonamide group, and a silane compound having a cyclic urea skeleton in a molecule, but are not limited thereto.

### <<Silane Compound Having Onium Group in Molecule (Hydrolyzable Organosilane)>>

The silane compound having an onium group in a molecule is expected to effectively and efficiently promote a crosslinking reaction of a hydrolyzable silane.

A preferred example of the silane compound having an onium group in a molecule is represented by formula (3).

[Chemical Formula 54]

R¹¹_{f}R¹²_{g}Si(R¹³)_{4-(f+g)} (3)

R¹¹ is a group bonded to a silicon atom, and represents an onium group or an organic group having the onium group.

R¹² is a group bonded to a silicon atom, and R¹²s each independently represent an alkyl group optionally having a substituent, an aryl group optionally having a substituent, an aralkyl group optionally having a substituent, an halogenated alkyl group optionally having a substituent, a halogenated aryl group optionally having a substituent, a halogenated aralkyl group optionally having a substituent, an alkoxyalkyl group optionally having a substituent, an alkoxyaryl group optionally having a substituent, an alkoxyaralkyl group optionally having a substituent, an alkenyl group optionally having a substituent, an organic group having an epoxy group, an organic group having an acryloyl group, an organic group having a methacryloyl group, an organic group having a mercapto group, an organic group having an amino group, an organic group having a cyano group, or a combination of two or more thereof.

R¹³ is a group or an atom bonded to a silicon atom, and R¹³s each independently represent an alkoxy group, an aralkyloxy group, an acyloxy group, or a halogen atom.

f represents 1 or 2, g represents 0 or 1, and 1≤f+g≤2 is satisfied.

As specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, the organic group having an amino group, the an organic group having a cyano group, the alkoxy group, the aralkyloxy group, the acyloxy group, and the halogen atom, specific examples of the substituents of the alkyl group, the aryl group, the aralkyl group, the halogenated alkyl group, the halogenated alkyl group, the alkoxyalkyl group, the alkoxyaryl group, the alkoxyaralkyl group, and the alkenyl group, and the preferred numbers of carbon atoms thereof for R¹² and R¹³, those described above for R¹ and R² can be exemplified, respectively.

More specifically, specific examples of the onium group include a cyclic ammonium group and a chain ammonium group, and a tertiary ammonium group or a quaternary ammonium group is preferable.

That is, preferred specific examples of the onium group or the organic group having the onium group include an organic group having a cyclic ammonium group, a chain ammonium group, or at least one of the cyclic ammonium group and the chain ammonium group, and an organic group having a tertiary ammonium group, a quaternary ammonium group, or at least one of the tertiary ammonium group and the quaternary ammonium group is preferable.

Note that when the onium group is a cyclic ammonium group, a nitrogen atom constituting the ammonium group also serves as an atom constituting a ring. At this time, a nitrogen atom constituting a ring and a silicon atom may be bonded to each other directly or via a divalent linking group, or a carbon atom constituting a ring and a silicon atom may be bonded to each other directly or via a divalent linking group.

In an example of a preferred aspect, R¹¹ that is a group bonded to a silicon atom is a heteroaromatic cyclic ammonium group represented by the following formula (S1).

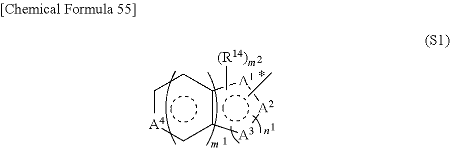

In formula (S1), A¹, A², A³, and A⁴ each independently represent a group represented by any one of the following formulas (J1) to (J3), and at least one of A¹ to A⁴ is a group represented by the following formula (J2). It is determined whether a bond between each of A¹ to A⁴ and an atom adjacent to each of A¹ to A⁴ and constituting a ring together is a single bond or a double bond such that the ring to be constituted exhibits aromaticity depending on which of A to A⁴ a silicon atom in formula (3) is bonded to. * represents a bond.

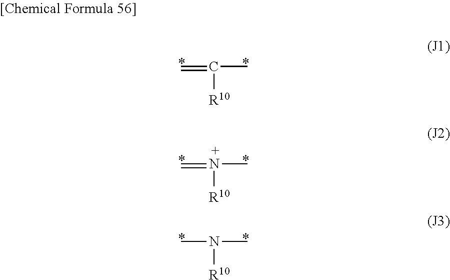

In formulas (J1) to (J3), R¹⁰s each independently represent a single bond, a hydrogen atom, an alkyl group, an aryl group, an aralkyl group, a halogenated alkyl group, a halogenated aryl group, a halogenated aralkyl group, or an alkenyl group, and as specific examples of the alkyl group, the aryl group, the aralkyl group, the halogenated alkyl group, the halogenated aryl group, the halogenated aralkyl group, and the alkenyl group, and the preferred numbers of carbon atoms thereof, those described above can be exemplified. * represents a bond.

In formula (S1), R¹⁴s each independently represent an alkyl group, an aryl group, an aralkyl group, a halogenated alkyl group, a halogenated aryl group, a halogenated aralkyl group, an alkenyl group, or a hydroxy group, and when there are two or more R¹⁴s, the two R¹⁴s may be bonded to each other to form a ring, and the ring formed by the two R¹⁴s may have a crosslinked ring structure. In such a case, the cyclic ammonium group has an adamantane ring, a norbornene ring, a spiro ring, or the like.

As specific examples of such an alkyl group, an aryl group, an aralkyl group, a halogenated alkyl group, a halogenated aryl group, a halogenated aralkyl group, and an alkenyl group, and the preferred numbers of carbon atoms thereof, those described above can be exemplified.

In formula (S1), n¹ is an integer of 1 to 8, m¹ is 0 or 1, and m² is 0 or any of positive integers from 1 to the maximum number of substituents which a monocyclic or polycyclic ring can have.

When m¹ is 0, a (4+n¹)-membered ring containing A¹ to A⁴ is formed. That is, a 5-membered ring is formed when n¹ is 1, a 6-membered ring is formed when n¹ is 2, a 7-membered ring is formed when n¹ is 3, an 8-membered ring is formed when n¹ is 4, a 9-membered ring is formed when n¹ is 5, a 10-membered ring is formed when n¹ is 6, a 11-membered ring is formed when n¹ is 7, and a 12-membered ring is formed when n¹ is 8.

When m¹ is 1, a (4+n¹)-membered ring containing A¹ to A³ and a 6-membered ring containing A⁴ are condensed to form a condensed ring.

There are a case where each of A¹ to A⁴ has a hydrogen atom on an atom constituting a ring and a case where each of A¹ to A⁴ does not have a hydrogen atom on the atom constituting the ring depending on whether each of A¹ to A⁴ is represented by any of formulas (J1) to (J3), but in a case where each of A¹ to A⁴ has a hydrogen atom on the atom constituting the ring, the hydrogen atom may be replaced with R¹⁴. A ring-constituting atom other than the ring-constituting atom in A¹ to A⁴ may be replaced with R¹⁴. Under such circumstances, as described above, m² is 0 or selected from positive integers of 1 to the maximum number of substituents which a monocyclic or polycyclic ring can have.

The bond of the heteroaromatic cyclic ammonium group represented by formula (S1) is present at any carbon atom or nitrogen atom present in such a single ring or condensed ring, and is directly bonded to a silicon atom, or is bonded to a linking group to form an organic group having a cyclic ammonium, which is bonded to the silicon atom.

Examples of such a linking group include an alkylene group, an arylene group, and an alkenylene group, but are not limited thereto.

As specific examples of the alkylene group and the arylene group, and the preferred numbers of carbon atoms thereof, those described above can be exemplified.

The alkenylene group is a divalent group derived by further removing one hydrogen atom of an alkenyl group, and as specific examples of such an alkenyl group, those described above can be exemplified. The number of carbon atoms of the alkenylene group is not particularly limited, but is preferably 40 or less, more preferably 30 or less, and still more preferably 20 or less.

Specific examples thereof include vinylene, 1-methylvinylene, propenylene, 1-butenylene, 2-butenylene, 1-pentenylene, and 2-pentenylene groups, but are not limited thereto.

Specific examples of the silane compound (hydrolyzable organosilane) represented by formula (3) and having a heteroaromatic cyclic ammonium group represented by formula (S1) include silanes represented by the following formulas (I-1) to (I-50), but are not limited thereto.

[Chemical Formula 57]

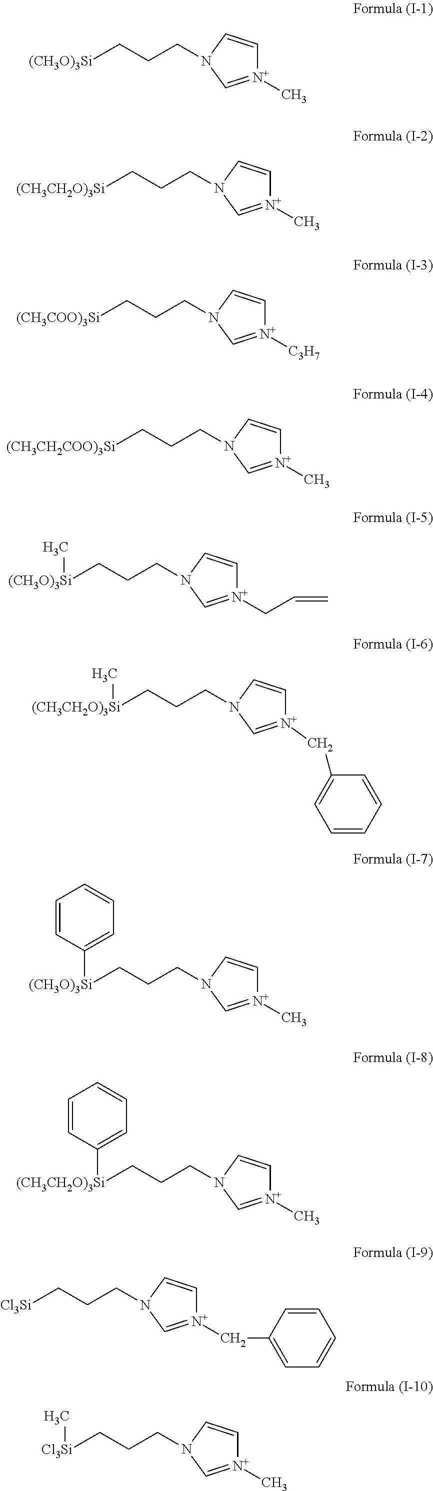

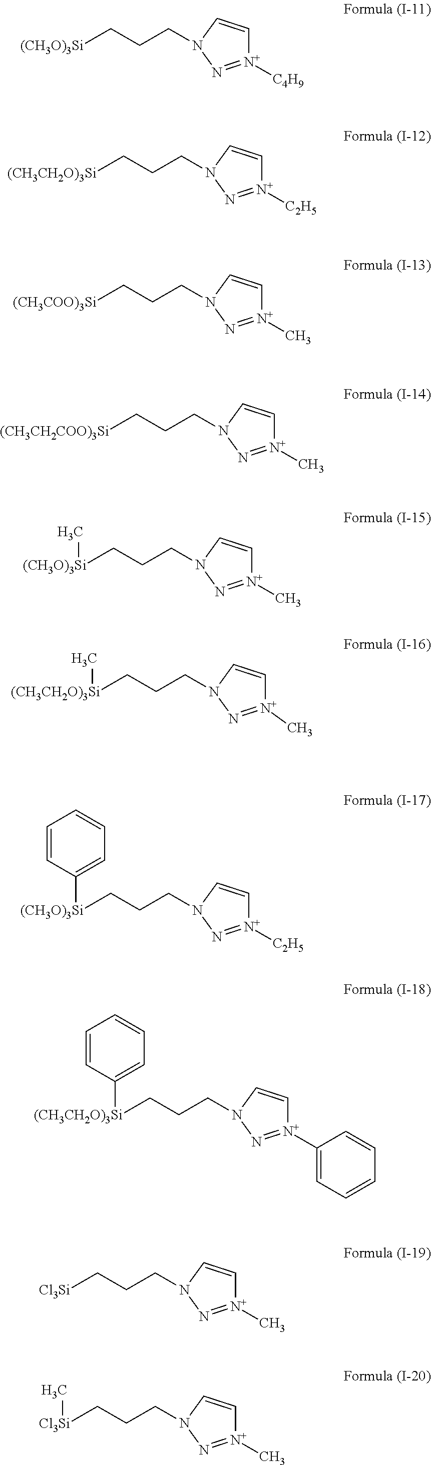

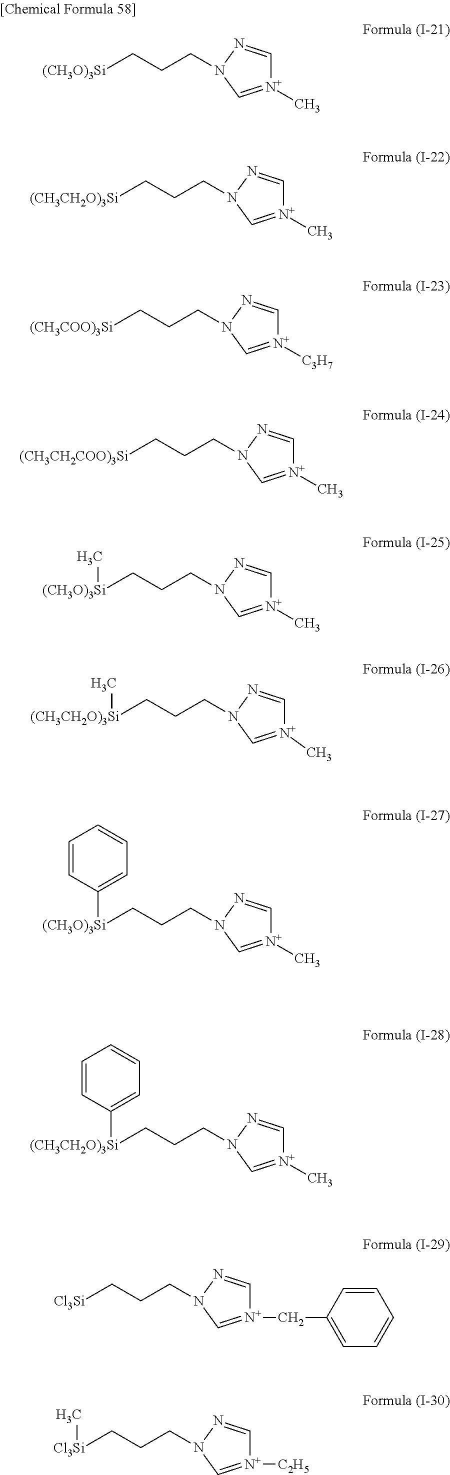

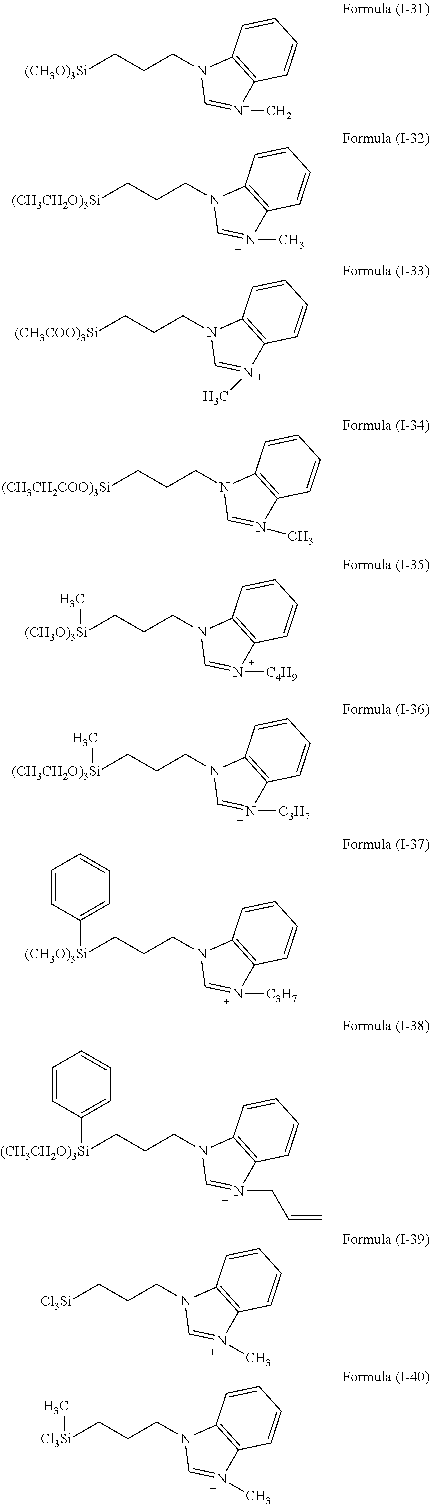

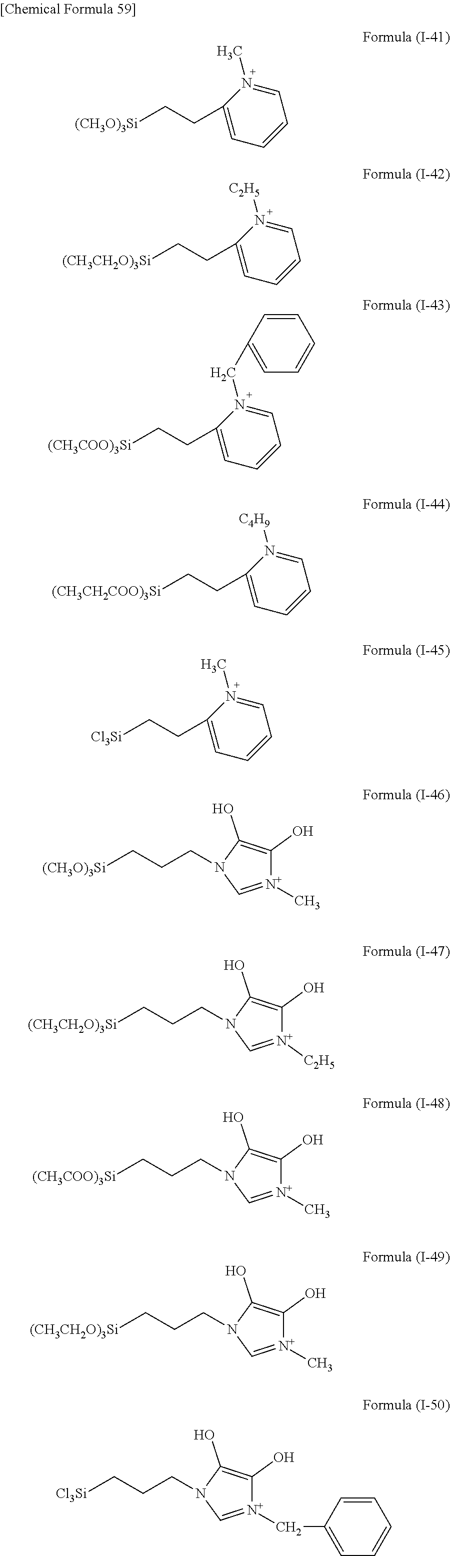

In another example, R that is a group bonded to a silicon atom in formula (3) can be a heteroaliphatic cyclic ammonium group represented by the following formula (S2).

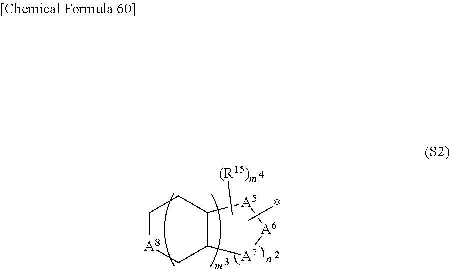

In formula (S2), A⁵, A⁶, A⁷, and A⁸ each independently represent a group represented by any one of the following formulas (J4) to (J6), and at least one of A⁵ to A⁸ is a group represented by the following formula (J5). Depending on which of A⁵ to A⁸ a silicon atom in formula (3) is bonded to, it is determined whether a bond between each of A⁵ to A⁸ and an atom adjacent to each of A⁵ to A⁸ and constituting a ring together is a single bond or a double bond such that the ring to be constituted exhibits non-aromaticity. * represents a bond.

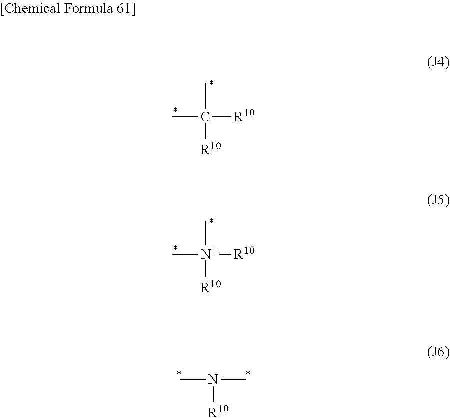

In formulas (J4) to (J6), R¹⁰s each independently represent a single bond, a hydrogen atom, an alkyl group, an aryl group, an aralkyl group, a halogenated alkyl group, a halogenated aryl group, a halogenated aralkyl group, or an alkenyl group, and as specific examples of the alkyl group, the aryl group, the aralkyl group, the halogenated alkyl group, the halogenated aryl group, the halogenated aralkyl group, and the alkenyl group and the preferred numbers of carbon atoms thereof, those described above can be exemplified. * represents a bond.

In formula (S2), R¹⁵s each independently represent an alkyl group, an aryl group, an aralkyl group, a halogenated alkyl group, a halogenated aryl group, a halogenated aralkyl group, an alkenyl group, or a hydroxy group, and when there are two or more R¹⁵s, the two R¹⁵s may be bonded to each other to form a ring, and the ring formed by the two R¹⁵s may have a crosslinked ring structure, and in such a case, the cyclic ammonium group has an adamantane ring, a norbornene ring, a spiro ring, or the like.

As specific examples of the alkyl group, the aryl group, the aralkyl group, the halogenated alkyl group, the halogenated aryl group, the halogenated aralkyl group, and the alkenyl group, and the preferred numbers of carbon atoms thereof, those described above can be exemplified.

In formula (S2), n² is an integer of 1 to 8, m³ is 0 or 1, and m⁴ is 0 or any of positive integers from 1 to the maximum number of substituents which a monocyclic or polycyclic ring can have.

When m³ is 0, a (4+n²)-membered ring containing A⁵ to A⁸ is formed. That is, a 5-membered ring is formed when n² is 1, a 6-membered ring is formed when n² is 2, a 7-membered ring is formed when n² is 3, an 8-membered ring is formed when n² is 4, a 9-membered ring is formed when n² is 5, a 10-membered ring is formed when n² is 6, a 11-membered ring is formed when n² is 7, and a 12-membered ring is formed when n² is 8.

When m³ is 1, a (4+n²)-membered ring containing A⁵ to A⁷ and a 6-membered ring containing A⁸ are condensed to form a condensed ring.

There are a case where each of A⁵ to A⁸ has a hydrogen atom on an atom constituting a ring and a case where each of A⁵ to A⁸ does not have a hydrogen atom on the atom constituting the ring depending on whether each of A⁵ to A⁸ is represented by any of formulas (J4) to (J6), but in a case where each of A⁵ to A⁸ has a hydrogen atom on the atom constituting the ring, the hydrogen atom may be replaced with R¹⁵. A ring-constituting atom other than the ring-constituting atom in A⁵ to A⁸ may be replaced with R¹⁵.

Under such circumstances, as described above, m⁴ is 0 or selected from positive integers of 1 to the maximum number of substituents which a monocyclic or polycyclic ring can have.

The bond of the heteroaliphatic cyclic ammonium group represented by formula (S2) is present at any carbon atom or nitrogen atom present in such a single ring or condensed ring, and is directly bonded to a silicon atom, or is bonded to a linking group to form an organic group having a cyclic ammonium, which is bonded to the silicon atom.

Examples of such a linking group include an alkylene group, an arylene group, and an alkenylene group, and as specific examples of the alkylene group, the arylene group, and the alkenylene group, and the preferred numbers of carbon atoms thereof, those described above can be exemplified.

Specific examples of the silane compound (hydrolyzable organosilane) represented by formula (3) and having a heteroaliphatic cyclic ammonium group represented by formula (S2) include silanes represented by the following formulas (II-1) to (II-30), but are not limited thereto.

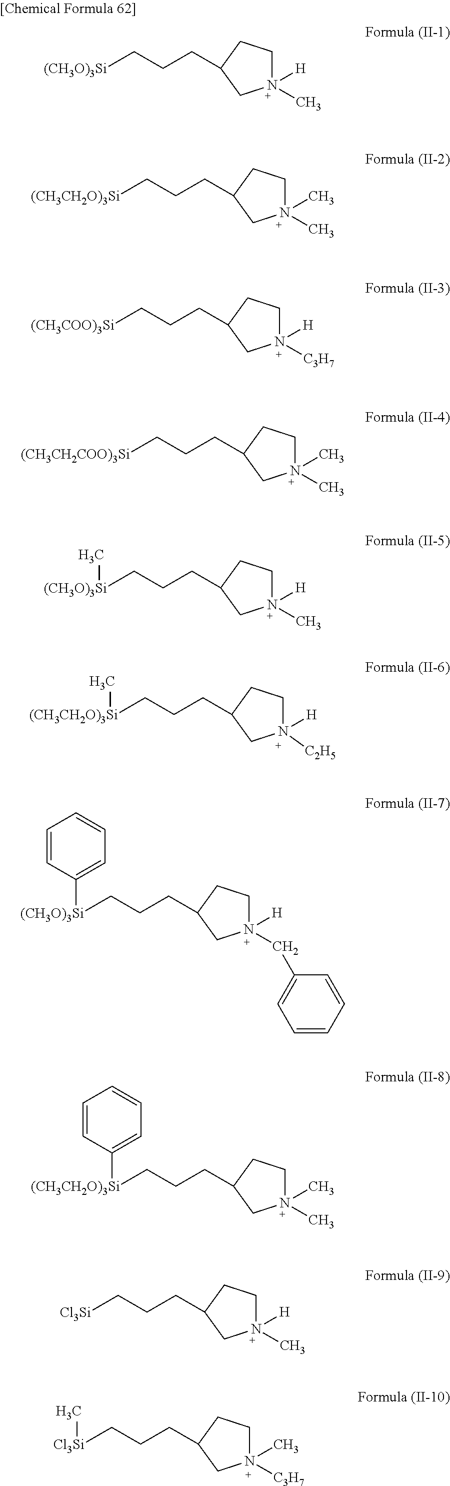

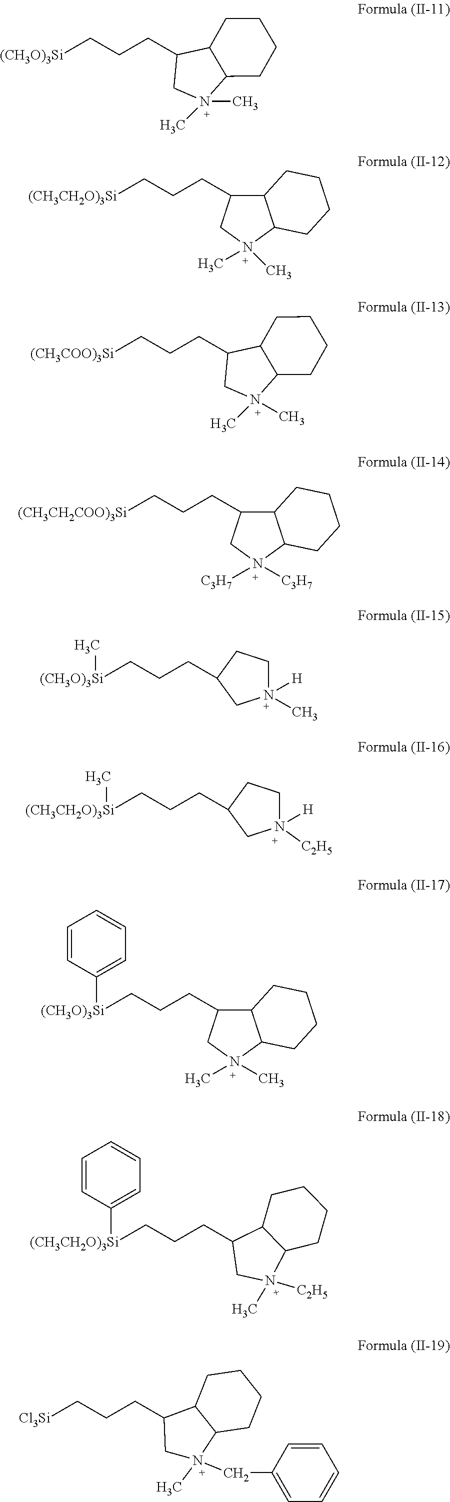

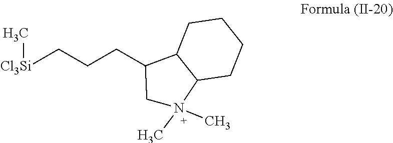

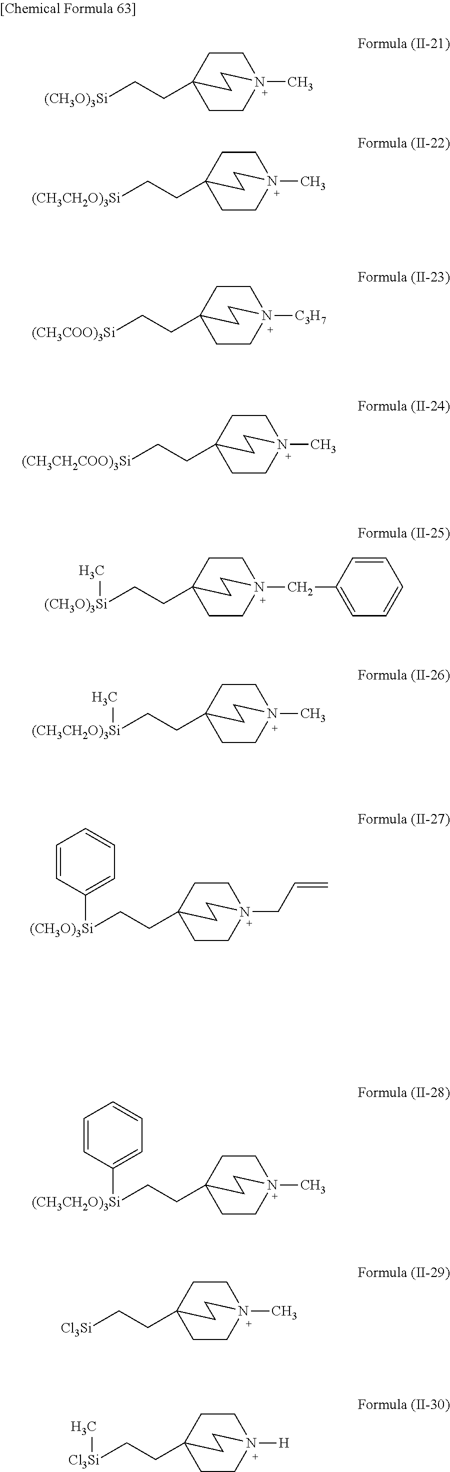

In still another example, R that is a group bonded to a silicon atom in formula (3) can be a chain ammonium group represented by the following formula (S3).

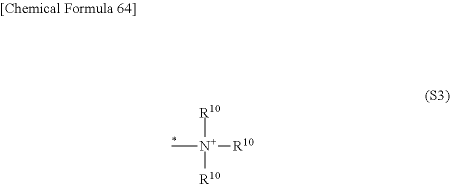

In formula (S3), R¹⁰s each independently represent a hydrogen atom, an alkyl group, an aryl group, an aralkyl group, a halogenated alkyl group, a halogenated aryl group, a halogenated aralkyl group, or an alkenyl group, and as specific examples of the alkyl group, the aryl group, the aralkyl group, the halogenated alkyl group, the halogenated aryl group, the halogenated aralkyl group, and the alkenyl group and the preferred numbers of carbon atoms thereof, those described above can be exemplified. * represents a bond.

The chain ammonium group represented by formula (S3) is directly bonded to a silicon atom, or is bonded to a linking group to form an organic group having a chain ammonium group, which is bonded to the silicon atom.

Examples of such a linking group include an alkylene group, an arylene group, and an alkenylene group, and as specific examples of the alkylene group, the arylene group, and the alkenylene group, those described above can be exemplified.

Specific examples of the silane compound (hydrolyzable organosilane) represented by formula (3) and having a chain ammonium group represented by formula (S3) include silanes represented by the following formulas (III-1) to (III-28), but are not limited thereto.

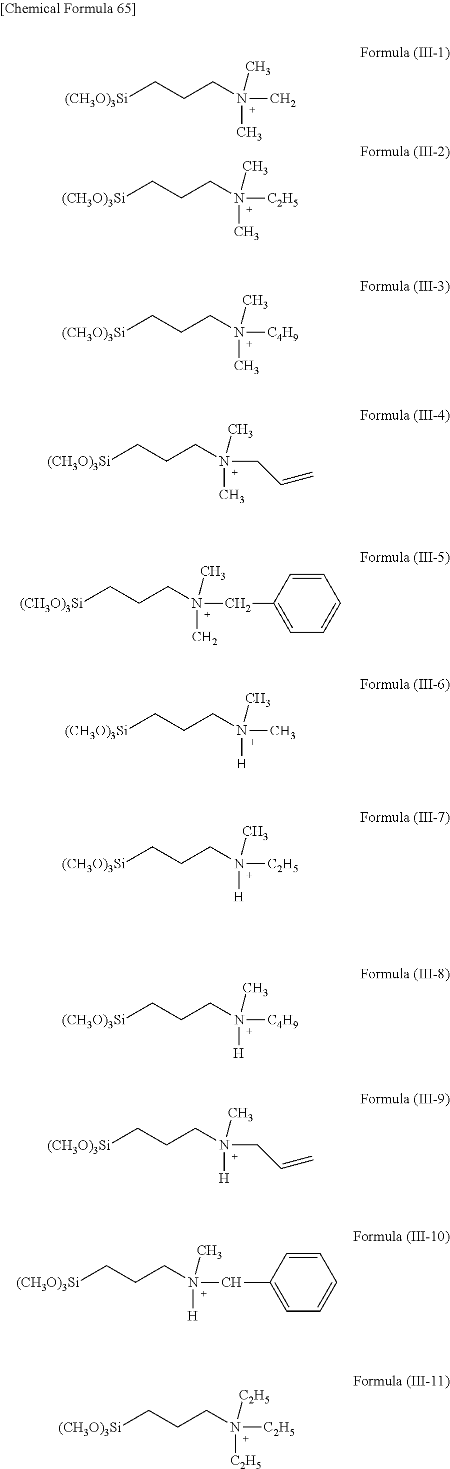

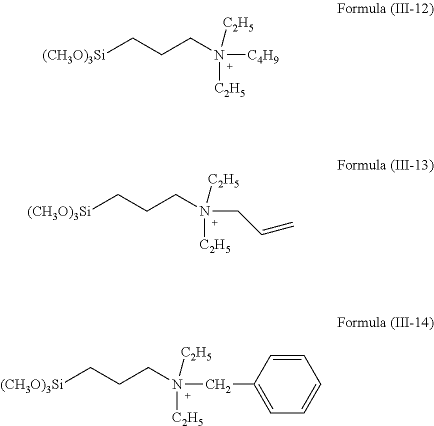

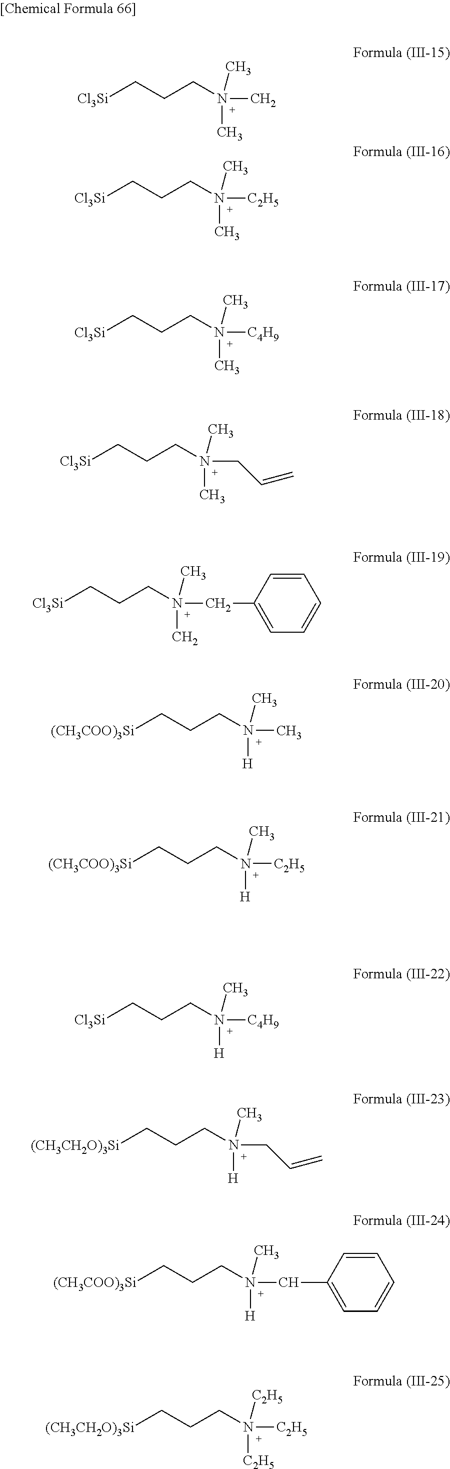

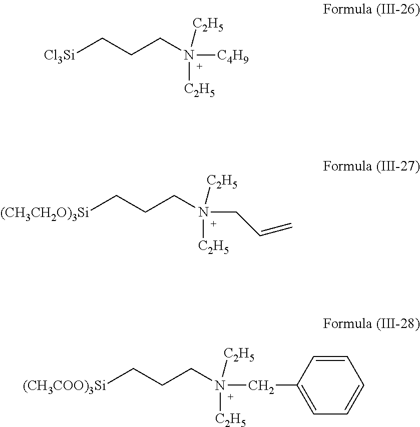

### <<Silane Compound Having Sulfone Group or Sulfonamide Group (Hydrolyzable Organosilane)>

Specific examples of the silane compound having a sulfone group and the silane compound having a sulfonamide group include compounds represented by the following formulas (B-1) to (B-36), but are not limited thereto.

In the following formulas, Me represents a methyl group, and Et represents an ethyl group.

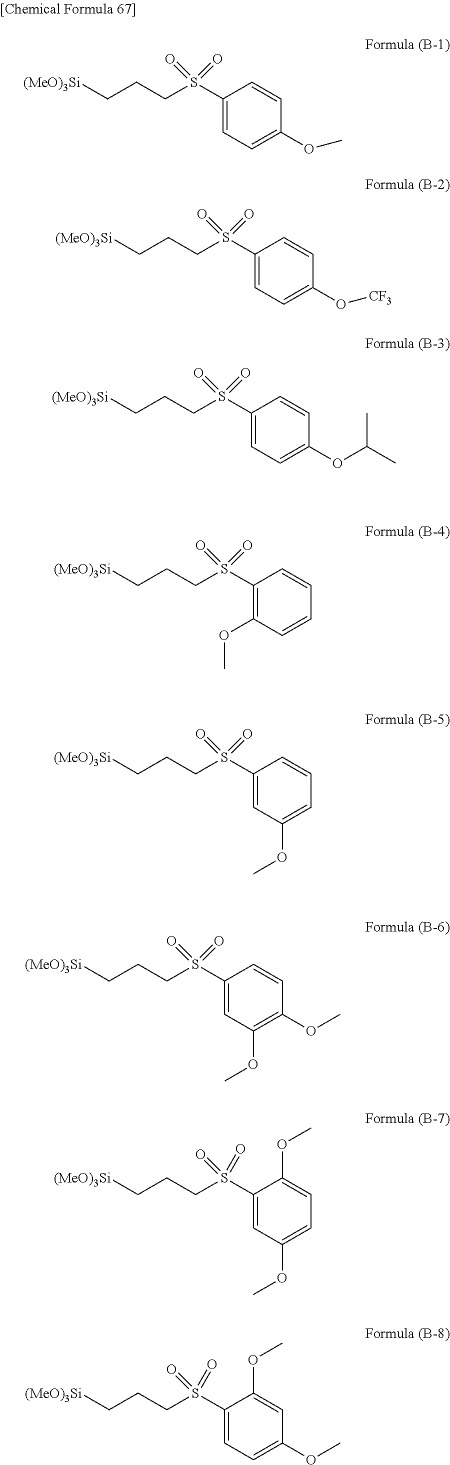

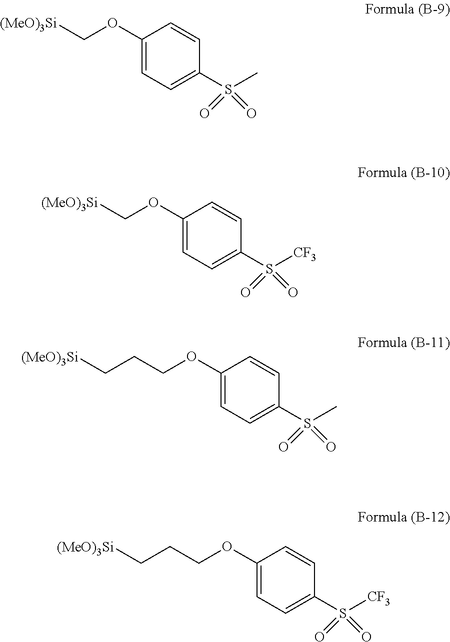

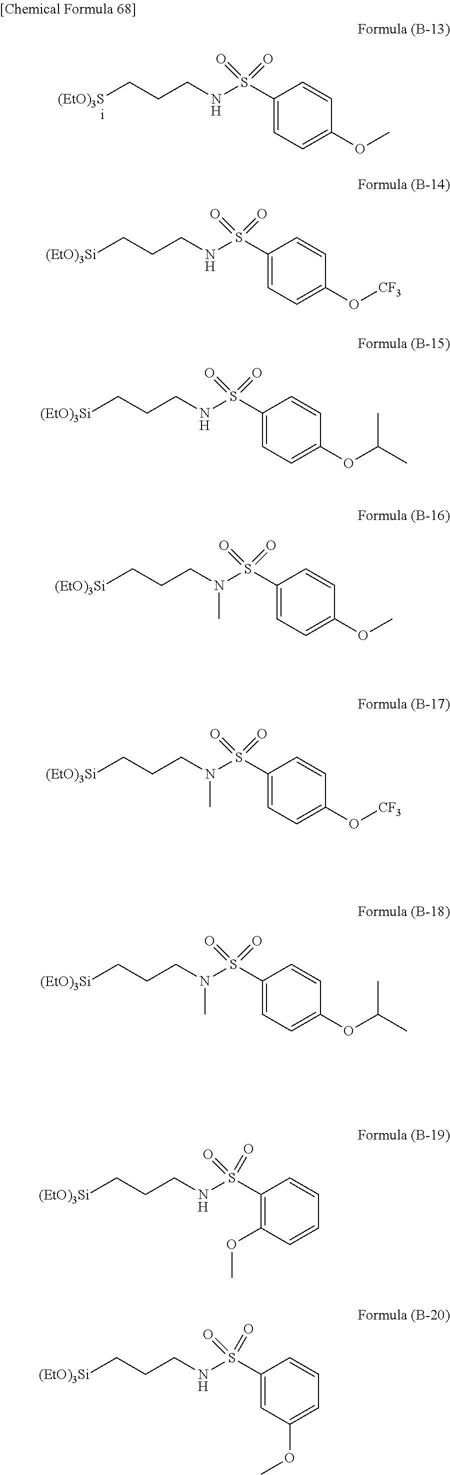

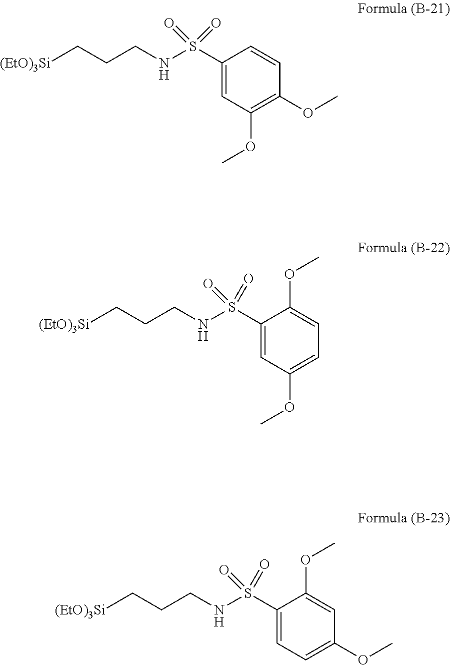

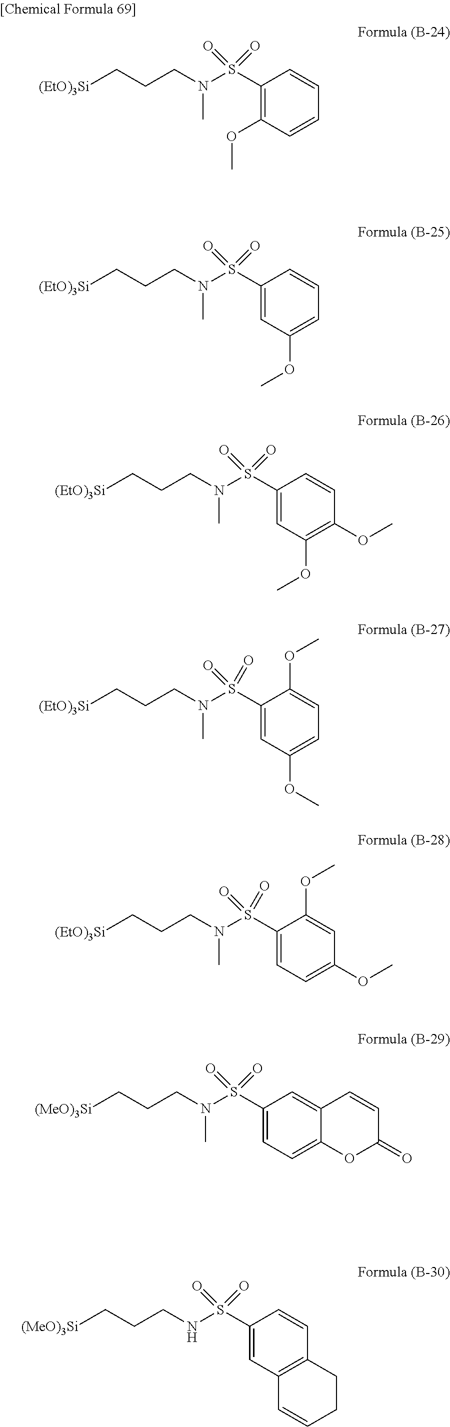

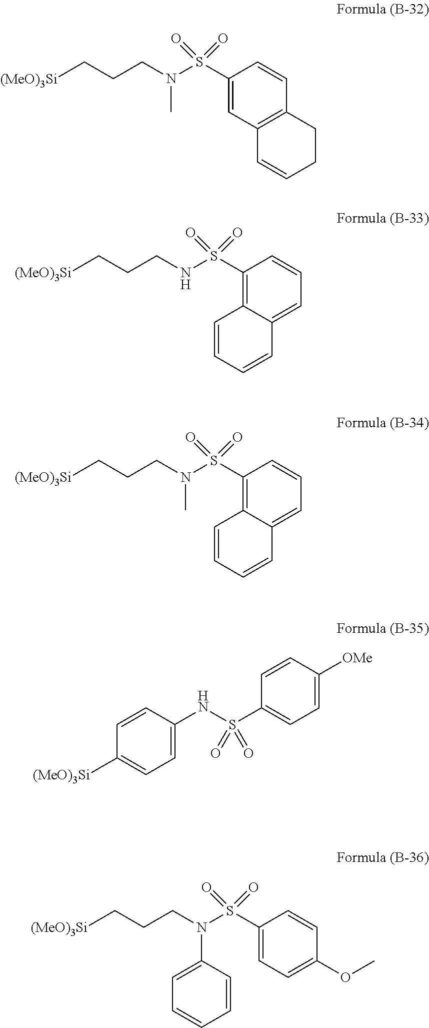

### <<Silane Compound Having Cyclic Urea Skeleton in Molecule (Hydrolyzable Organosilane)>>

Examples of the hydrolyzable organosilane having a cyclic urea skeleton in a molecule include a hydrolyzable organosilane represented by the following formula (4-1).

[Chemical Formula 70]

R⁴⁰¹ₓR⁴⁰²_{y}Si(R⁴⁰³)_{4-(x+y)} (4-1)

In formula (4-1), R⁴⁰¹ is a group bonded to a silicon atom, and R⁴⁰¹s each independently represent a group represented by the following formula (4-2).

R⁴⁰² is a group bonded to a silicon atom, and represents an alkyl group optionally having a substituent, an aryl group optionally having a substituent, an aralkyl group optionally having a substituent, an halogenated alkyl group optionally having a substituent, a halogenated aryl group optionally having a substituent, a halogenated aralkyl group optionally having a substituent, an alkoxyalkyl group optionally having a substituent, an alkoxyaryl group optionally having a substituent, an alkoxyaralkyl group optionally having a substituent, an alkenyl group optionally having a substituent, an organic group having an epoxy group, an organic group having an acryloyl group, an organic group having a methacryloyl group, an organic group having a mercapto group, an organic group having a cyano group, or a combination of two or more thereof.

R⁴⁰³ is a group or an atom bonded to a silicon atom, and R⁴⁰³s each independently represent an alkoxy group, an aralkyloxy group, an acyloxy group, or a halogen atom.

x is 1 or 2, y is 0 or 1, and x+y≤2 is satisfied.

As specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, and the organic group having a cyano group of R⁴⁰², the alkoxy group, the aralkyloxy group, the acyloxy group, and the halogen atom of R⁴⁰³, and substituents thereof, the preferred numbers of carbon atoms thereof, and the like, those described above for R¹ and R² can be exemplified.

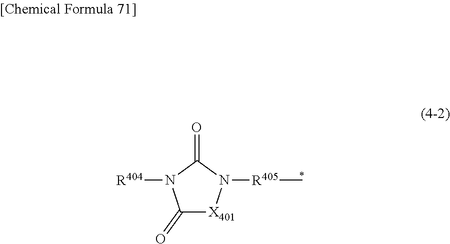

In formula (4-2), R⁴⁰⁴s each independently represent a hydrogen atom, an alkyl group optionally having a substituent, an alkenyl group optionally having a substituent, an organic group having an epoxy group, or an organic group having a sulfonyl group, and R⁴⁰⁵s each independently represent an alkylene group, a hydroxyalkylene group, a sulfide bond (—S—), an ether bond (—O—), or an ester bond (—CO—O— or —O—CO—). * represents a bond.

Note that as specific examples of the alkyl group optionally having a substituent, the alkenyl group optionally having a substituent, and the organic group having an epoxy group of R⁴⁰⁴, the preferred numbers of carbon atoms thereof, and the like, those described above for R¹ can be exemplified. In addition to these, the alkyl group optionally having a substituent of R⁴⁰⁴ is preferably an alkyl group in which a terminal hydrogen atom is replaced with a vinyl group, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an alkylsulfonyl group optionally having a substituent, an arylsulfonyl group optionally having a substituent, an aralkylsulfonyl group optionally having a substituent, a halogenated alkylsulfonyl group optionally having a substituent, a halogenated arylsulfonyl group optionally having a substituent, a halogenated aralkylsulfonyl group optionally having a substituent, an alkoxyalkylsulfonyl group optionally having a substituent, an alkoxyarylsulfonyl group optionally having a substituent, an alkoxyaralkylsulfonyl group optionally having a substituent, and an alkenylsulfonyl group optionally having a substituent.

As specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group in these groups and the substituents thereof, the preferred numbers of carbon atoms thereof, and the like, those described above for R¹ can be exemplified.

The alkylene group is a divalent group derived by further removing one hydrogen atom of an alkyl group, and may be linear, branched, or cyclic, and as specific examples of such an alkylene group, those described above can be exemplified. The number of carbon atoms of the alkylene group is not particularly limited, but is preferably 40 or less, more preferably 30 or less, still more preferably 20 or less, and further still more preferably 10 or less.

The alkylene group of R⁴⁰⁵ may have one or more selected from a sulfide bond, an ether bond, and an ester bond at a terminal thereof or in a middle thereof, preferably in a middle thereof.

Specific examples of the alkylene group include: a linear alkylene group such as a methylene group, an ethylene group, a trimethylene group, a tetramethylene group, a pentamethylene group, a hexamethylene group, a heptamethylene group, an octamethylene group, a nonamethylene group, or a decamethylene group; a branched alkylene group such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, or a 1-ethyltrimethylene group; a cyclic alkylene group such as a 1,2-cyclopropanediyl group, a 1,2-cyclobutanediyl group, a 1,3-cyclobutanediyl group, a 1,2-cyclohexanediyl group, or a 1,3-cyclohexanediyl group; and an alkylene group including an ether group or the like, such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, or —CH₂OCH₂CH₂SCH₂—, but are not limited thereto.

The hydroxyalkylene group is a group in which at least one of hydrogen atoms of the above-described alkylene group is replaced with a hydroxy group, and specific examples thereof include a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group, but are not limited thereto.

In formula (4-2), X₄₀₁s each independently represent any of groups represented by the following formulas (4-3) to (4-5), and a carbon atom of a ketone group in the following formulas (4-4) and (4-5) is bonded to a nitrogen atom to which R⁴⁰⁵ in formula (4-2) is bonded.

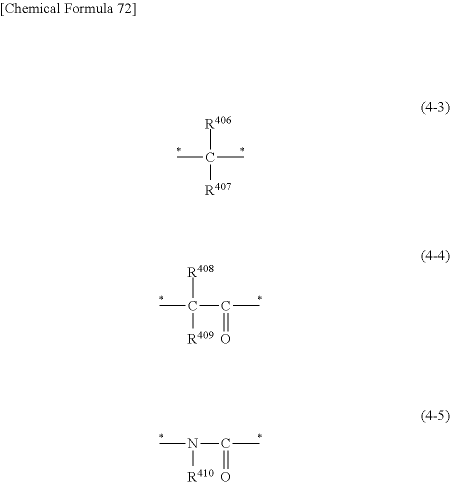

In formulas (4-3) to (4-5), R⁴⁰⁶ to R⁴¹⁰ each independently represent a hydrogen atom, an alkyl group optionally having a substituent, an alkenyl group optionally having a substituent, or an organic group having an epoxy group or a sulfonyl group. As specific examples of the alkyl group optionally having a substituent, the alkenyl group optionally having a substituent, and the organic group having an epoxy group or a sulfonyl group, the preferred numbers of carbon atoms thereof, and the like, those described above for R¹ can be exemplified. As specific examples of the organic group having a sulfonyl group, the preferred numbers of carbon atoms thereof, and the like, those described above for R⁴⁰⁴ can be exemplified. * represents a bond.

Among the groups, X₄₀₁ is preferably a group represented by formula (4-5) from a viewpoint of achieving excellent lithography characteristics with good reproducibility.

At least one of R⁴⁰⁴ and R⁴⁰⁶ to R⁴¹⁰ is preferably an alkyl group in which a terminal hydrogen atom is replaced with a vinyl group from a viewpoint of achieving excellent lithography characteristics with good reproducibility.

As the hydrolyzable organosilane represented by formula (4-1), a commercially available product may be used, and the hydrolyzable organosilane can also be synthesized by a known method described in WO 2011/102470 A or the like. Hereinafter, specific examples of the hydrolyzable organosilane represented by formula (4-1) include silanes represented by the following formulas (4-1-1) to (Apr. 1, 2029), but are not limited thereto.

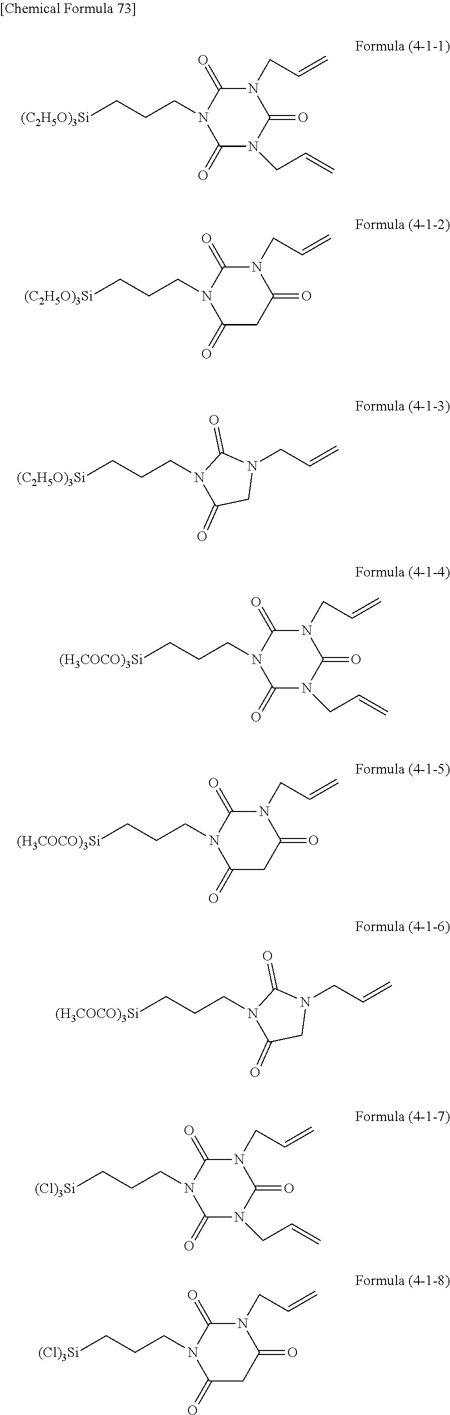

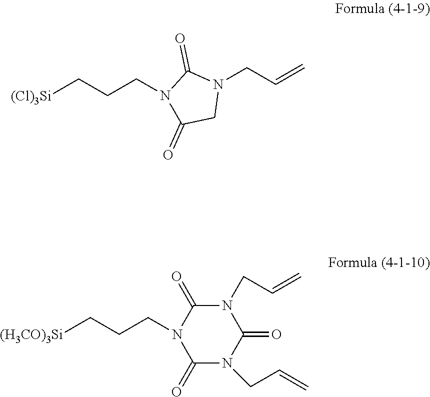

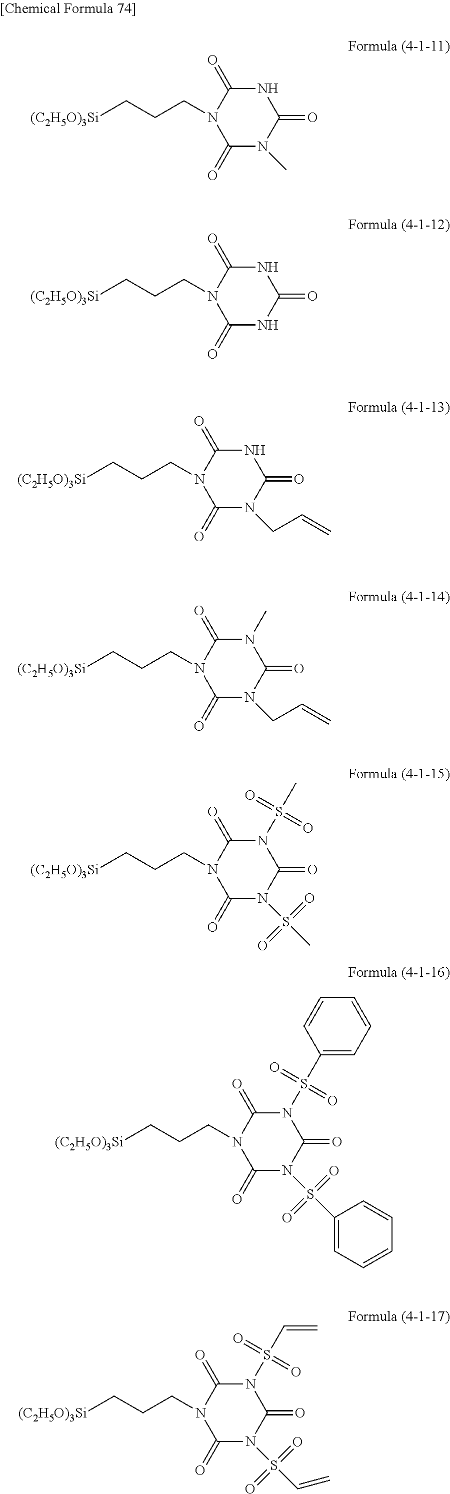

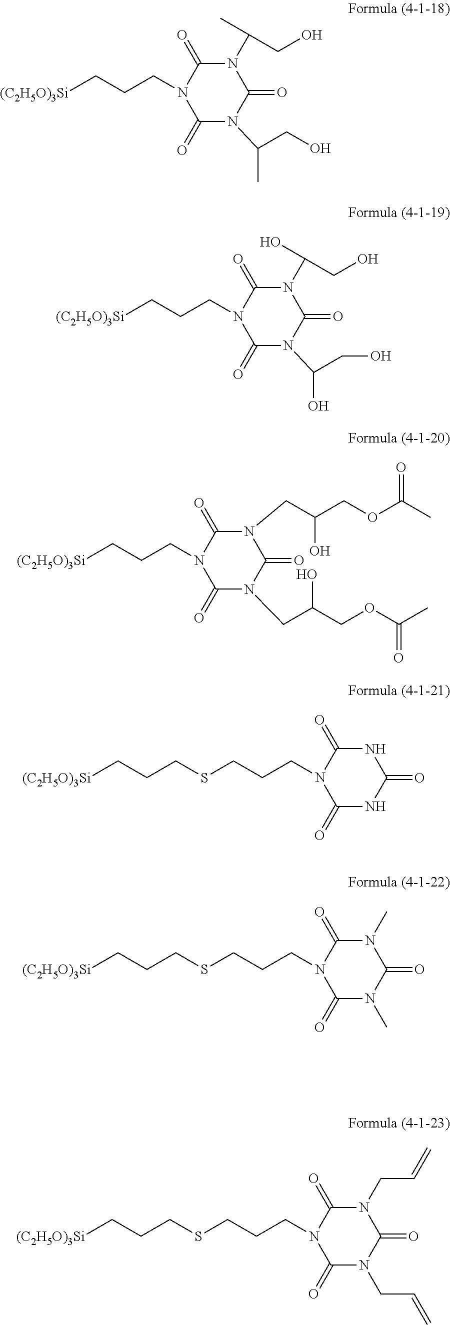

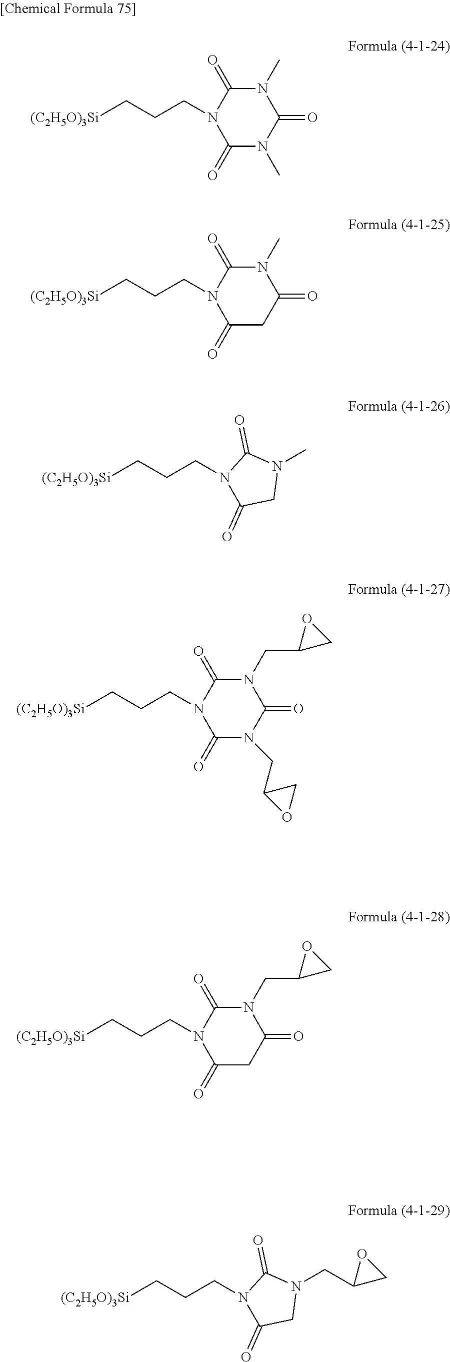

[A] Polysiloxane can be a hydrolysis condensate of a hydrolycable silane containing a silane compound other than those exemplified above as long as an effect of the present invention is not impaired.

As described above, as [A] polysiloxane, a modified polysiloxane in which at least some of silanol groups are modified can be used. For example, a polysiloxane modified product in which some of silanol groups are alcohol-modified or acetal-protected can be used.

Examples of the polysiloxane as the modified product include: a reaction product obtained by a reaction between at least some of silanol groups of a hydrolysis condensate of the above-described hydrolyzable silane and a hydroxy group of an alcohol; a dehydration reaction product of the condensate and an alcohol; and a modified product obtained by protecting at least some of silanol groups of the condensate with an acetal group.

As the alcohol, a monohydric alcohol can be used, and examples thereof include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3 pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

For example, an alkoxy group-containing alcohol such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), or propylene glycol monobutyl ether (1-butoxy-2-propanol) can be used.

Regarding the reaction between a silanol group of a condensate and a hydroxy group of an alcohol, the polysiloxane and the alcohol are brought into contact with each other and caused to reacted with each other at a temperature of 40 to 160° C., for example, 60° C., for 0.1 to 48 hours, for example, 24 hours, whereby a modified polysiloxane capped with the silanol group is obtained. At this time, the alcohol as a capping agent can be used as a solvent in a composition containing the polysiloxane.

The dehydration reaction product of a polysiloxane formed of a hydrolysis condensate of a hydrolyzable silane and an alcohol can be manufactured by causing the polysiloxane with the alcohol in the presence of an acid as a catalyst, capping a silanol group with the alcohol, and removing water generated by dehydration to the outside of the reaction system.

As the acid, an organic acid having an acid dissociation constant (pka) of −1-to 5, preferably 4 to 5 can be used. Examples of the acid include trifluoroacetic acid, maleic acid, benzoic acid, isobutyric acid, and acetic acid, and among these acids, benzoic acid, isobutyric acid, and acetic acid can be exemplified.

As the acid, an acid having a boiling point of 70 to 160° C. can be used, and examples thereof include trifluoroacetic acid, isobutyric acid, acetic acid, and nitric acid.

As described above, the acid preferably has a physical property of having an acid dissociation constant (pka) of 4 to 5 or a boiling point of 70 to 160° C. That is, an acid having a weak acidity or an acid having a low boiling point even when having a strong acidity can be used.

As the acid, either the property of the acid dissociation constant or the property of the boiling point can be used.

For acetal protection of the silanol group of the condensate, a vinyl ether, for example, a vinyl ether represented by the following formula (5) can be used, and a partial structure represented by the following formula (6) can be introduced into the polysiloxane by these reactions.

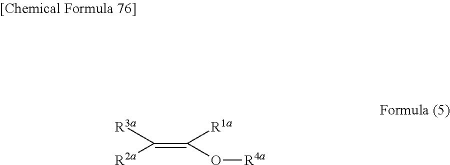

In formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded to each other to form a ring. As the alkyl group, those described above can be exemplified.

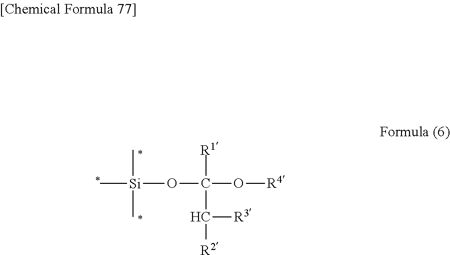

In formula (6), R¹′, R²′, and R³′ each represent a hydrogen atom or an alkyl group having 1 to 10 carbon atoms, R⁴′ represents an alkyl group having 1 to 10 carbon atoms, and R²′ and R⁴′ may be bonded to each other to form a ring. In formula (6), * represents a bond to an adjacent atom. Examples of the adjacent atom include an oxygen atom of a siloxane bond, an oxygen atom of a silanol group, and a carbon atom derived from R¹ of formula (1). As the alkyl group, those described above can be exemplified.

Examples of the vinyl ether represented by formula (5) include: an aliphatic vinyl ether compound such as methyl vinyl ether, ethyl vinyl ether, isopropyl vinyl ether, normal butyl vinyl ether, 2-ethylhexyl vinyl ether, tert-butyl vinyl ether, or cyclohexyl vinyl ether; and a cyclic vinyl ether compound such as 2,3-dihydrofuran, 4-methyl-2,3-dihydrofuran, or 3,4-dihydro-2H-pyran. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran can be preferably used.

The acetal protection of the silanol group can be performed using polysiloxane, vinyl ether, and an aprotic solvent such as propylene glycol monomethyl ether acetate, ethyl acetate, dimethylformamide, tetrahydrofuran, or 1,4-dioxane as a solvent, and using a catalyst such as pyridium p-toluenesulfonic acid, trifluoromethanesulfonic acid, p-toluenesulfonic acid, methanesulfonic acid, hydrochloric acid, or sulfuric acid.

Note that capping and acetal protection of the silanol group with an alcohol may be performed simultaneously with hydrolysis and condensation of a hydrolyzable silane described later.

In a preferred aspect of the present invention, [A] polysiloxane includes at least one of a hydrolysis condensate of a hydrolyzable silane, including a hydrolyzable silane represented by formula (1), a hydrolyzable silane represented by formula (2) if desired, and other hydrolyzable silanes, and a modified product thereof.

In a preferred aspect, [A] polysiloxane contains a dehydration reaction product of a hydrolysis condensate and an alcohol.

The hydrolysis condensate (which may also include a modified product) of the hydrolyzable silane can have a weight average molecular weight of, for example, 500 to 1,000,000. The weight average molecular weight can be preferably 500,000 or less, more preferably 250,000 or less, and still more preferably 100,000 or less from a viewpoint of, for example, suppressing precipitation of the hydrolysis condensate in a composition, or the like, and the weight average molecular weight can be preferably 700 or more, and more preferably 1,000 or more from a viewpoint of, for example, achieving both storage stability and applicability.

Note that the weight average molecular weight is a molecular weight obtained in terms of polystyrene by GPC analysis. The GPC analysis can be performed using, for example, a GPC apparatus (trade name: HLC-8220GPC, manufactured by Tosoh Corporation), a GPC column (trade name: Shodex (registered trademark) KF803L, KF802, or KF801, manufactured by Showa Denko K.K.), a column temperature of 40° C., tetrahydrofuran as an eluent (elution solvent), a flow rate of 1.0 mL/min, and polystyrene (Shodex (registered trademark) manufactured by Showa Denko K.K.) as a standard sample.

The hydrolysis condensate of the hydrolyzable silane is obtained by hydrolyzing and condensing the above-described silane compound (hydrolyzable silane).

The above-described silane compound (hydrolyzable silane) contains an alkoxy group, an aralkyloxy group, an acyloxy group, or a halogen atom that is directly bonded to a silicon atom, that is, an alkoxysilyl group, an aralkyloxysilyl group, an acyloxysilyl group, or a halogenated silyl group (hereinafter, referred to as a hydrolyzable group).

For hydrolysis of these hydrolyzable groups, usually 0.1 to 100 mol, for example, 0.5 to 100 mol, preferably 1 to 10 mol of water is used per mol of the hydrolyzable groups.

At the time of hydrolysis and condensation, a hydrolysis catalyst may be used for the purpose of, for example, accelerating a reaction, or hydrolysis and condensation may be performed without using a hydrolysis catalyst. When a hydrolysis catalyst is used, usually 0.0001 to 10 mol, preferably 0.001 to 1 mol, of a hydrolysis catalyst can be used per mol of the hydrolyzable groups.

A reaction temperature at the time of performing hydrolysis and condensation is usually in a range of room temperature or higher and a reflux temperature at normal pressure of an organic solvent that can be used for hydrolysis or lower, and can be, for example, 20 to 110° C. or 20 to 80° C.

The hydrolysis may be completely performed, that is, all hydrolyzable groups may be changed to silanol groups, or partially performed, that is, unreacted hydrolyzable groups may remain.

Examples of the hydrolysis catalyst that can be used in hydrolysis and condensation include a metal chelate compound, an organic acid, an inorganic acid, an organic base, and an inorganic base.

Examples of the metal chelate compound as the hydrolysis catalyst include: a titanium chelate compound such as triethoxy⋅mono(acetylacetonate) titanium, tri-n-propoxy⋅mono(acetylacetonate) titanium, tri-i-propoxy⋅mono(acetylacetonate) titanium, tri-n-butoxy⋅mono(acetylacetonate) titanium, tri-sec-butoxy⋅mono(acetylacetonate) titanium, tri-t-butoxy⋅mono(acetylacetonate) titanium, diethoxy⋅bis(acetylacetonate) titanium, di-n-propoxy⋅bis(acetylacetonate) titanium, di-i-propoxy⋅bis(acetylacetonate) titanium, di-n-butoxy⋅bis(acetylacetonate) titanium, di-sec-butoxy⋅bis(acetylacetonate) titanium, di-t-butoxy⋅bis(acetylacetonate) titanium, monoethoxy⋅tris(acetylacetonate) titanium, mono-n-propoxy⋅tris(acetylacetonate) titanium, mono-i-propoxy⋅tris(acetylacetonate) titanium, mono-n-butoxy⋅tris(acetylacetonate) titanium, mono-sec-butoxy⋅tris(acetylacetonate) titanium, mono-t-butoxy⋅tris(acetylacetonate) titanium, tetrakis(acetylacetonate) titanium, triethoxy⋅mono(ethylacetoacetate) titanium, tri-n-propoxy⋅mono(ethylacetoacetate) titanium, tri-i-propoxy⋅mono(ethylacetoacetate) titanium, tri-n-butoxy⋅mono(ethylacetoacetate) titanium, tri-sec-butoxy⋅mono(ethylacetoacetate) titanium, tri-t-butoxy⋅mono(ethylacetoacetate) titanium, diethoxy⋅bis(ethylacetoacetate) titanium, di-n-propoxy⋅bis(ethylacetoacetate) titanium, di-i-propoxy⋅bis(ethylacetoacetate) titanium, di-n-butoxy⋅bis(ethylacetoacetate) titanium, di-sec-butoxy⋅bis(ethylacetoacetate) titanium, di-t-butoxy⋅bis(ethylacetoacetate) titanium, monoethoxy⋅tris(ethylacetoacetate) titanium, mono-n-propoxy⋅tris(ethylacetoacetate) titanium, mono-i-propoxy⋅tris(ethylacetoacetate) titanium, mono-n-butoxy⋅tris(ethylacetoacetate) titanium, mono-sec-butoxy⋅tris(ethylacetoacetate) titanium, mono-t-butoxy⋅tris(ethylacetoacetate) titanium, tetrakis(ethylacetoacetate) titanium, mono(acetylacetonate)tris(ethylacetoacetate) titanium, bis(acetylacetonate)bis(ethylacetoacetate) titanium, or tris(acetylacetonate) mono(ethylacetoacetate) titanium; a zirconium chelate compound such as triethoxy⋅mono(acetylacetonate) zirconium, tri-n-propoxy⋅mono(acetylacetonate) zirconium, tri-i-propoxy⋅mono(acetylacetonate) zirconium, tri-n-butoxy⋅mono(acetylacetonate) zirconium, tri-sec-butoxy⋅mono(acetylacetonate) zirconium, tri-t-butoxy⋅mono(acetylacetonate) zirconium, diethoxy⋅bis(acetylacetonate) zirconium, di-n-propoxy⋅bis(acetylacetonate) zirconium, di-i-propoxy⋅bis(acetylacetonate) zirconium, di-n-butoxy⋅bis(acetylacetonate) zirconium, di-sec-butoxy⋅bis(acetylacetonate) zirconium, di-t-butoxy⋅bis(acetylacetonate) zirconium, monoethoxy⋅tris(acetylacetonate) zirconium, mono-n-propoxy⋅tris(acetylacetonate) zirconium, mono-i-propoxy⋅tris(acetylacetonate) zirconium, mono-n-butoxy⋅tris(acetylacetonate) zirconium, mono-sec-butoxy⋅tris(acetylacetonate) zirconium, mono-t-butoxy⋅tris(acetylacetonate) zirconium, tetrakis(acetylacetonate) zirconium, triethoxy⋅mono(ethylacetoacetate) zirconium, tri-n-propoxy⋅mono(ethylacetoacetate) zirconium, tri-i-propoxy⋅mono(ethylacetoacetate) zirconium, tri-n-butoxy⋅mono(ethylacetoacetate) zirconium, tri-sec-butoxy⋅mono(ethylacetoacetate) zirconium, tri-t-butoxy⋅mono(ethylacetoacetate) zirconium, diethoxy⋅bis(ethylacetoacetate) zirconium, di-n-propoxy⋅bis(ethylacetoacetate) zirconium, di-i-propoxy⋅bis(ethylacetoacetate) zirconium, di-n-butoxy⋅bis(ethylacetoacetate) zirconium, di-sec-butoxy⋅bis(ethylacetoacetate) zirconium, di-t-butoxy⋅bis(ethylacetoacetate) zirconium, monoethoxy⋅tris(ethylacetoacetate) zirconium, mono-n-propoxy⋅tris(ethylacetoacetate) zirconium, mono-i-propoxy⋅tris(ethylacetoacetate) zirconium, mono-n-butoxy⋅tris(ethylacetoacetate) zirconium, mono-sec-butoxy⋅tris(ethylacetoacetate) zirconium, mono-t-butoxy⋅tris(ethylacetoacetate) zirconium, tetrakis(ethylacetoacetate) zirconium, mono(acetylacetonate) tris(ethylacetoacetate) zirconium, bis(acetylacetonate) bis(ethylacetoacetate) zirconium, or tris(acetylacetonate) mono(ethylacetoacetate) zirconium; and an aluminum chelate compound such as tris(acetylacetonate) aluminum or tris(ethylacetoacetate)aluminum, but are not limited thereto.

Examples of the organic acid as the hydrolysis catalyst include acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linolic acid, linoleic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid, but are not limited thereto.

Examples of the inorganic acid as the hydrolysis catalyst include hydrochloric acid, nitric acid, sulfuric acid, hydrofluoric acid, and phosphoric acid, but are not limited thereto.

Examples of the organic base as the hydrolysis catalyst include pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide, but are not limited thereto.

Examples of the inorganic base as the hydrolysis catalyst include ammonia, sodium hydroxide, potassium hydroxide, barium hydroxide, and calcium hydroxide, but are not limited thereto.

Among these catalysts, a metal chelate compound, an organic acid, and an inorganic acid are preferable, and these may be used singly or in combination of two or more types thereof.

Among these catalysts, in the present invention, nitric acid can be preferably used as the hydrolysis catalyst. By using nitric acid, storage stability of a reaction solution after hydrolysis and condensation can be improved, and in particular, a change in the molecular weight of a hydrolysis condensate can be suppressed. It is known that stability of the hydrolysis condensate in liquid depends on the pH of a solution. As a result of intensive studies, it has been found that the pH of the solution is in a stable region by using an appropriate amount of nitric acid.

In addition, as described above, nitric acid can also be used in obtaining a modified product of a hydrolysis condensate, for example, capping of a silanol group with an alcohol, and thus is also preferable from a viewpoint of being able to contribute to both reactions of hydrolysis and condensation of a hydrolyzable silane and alcohol capping of a hydrolysis condensate.

When hydrolysis and condensation are performed, an organic solvent may be used as a solvent, and specific examples thereof include: an aliphatic hydrocarbon-based solvent such as n-pentane, i-pentane, n-hexane, i-hexane, n-heptane, i-heptane, 2,2,4-trimethylpentane, n-octane, i-octane, cyclohexane, or methylcyclohexane; an aromatic hydrocarbon-based solvent such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, or n-amylnaphthalene; a monoalcohol-based solvent such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, or cresol; a polyhydric alcohol-based solvent such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, or glycerin; a ketone-based solvent such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, or fenchon; an ether-based solvent such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol di-n-butyl ether, diethylene glycol mono-n-hexyl ether, ethoxy triglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, or 2-methyltetrahydrofuran; an ester-based solvent such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, or diethyl phthalate; a nitrogen-containing solvent such as N-methylformamide, N, N-dimethylformamide, N, N-diethylformamide, acetamide, N-methylacetamide, N, N-dimethylacetamide, N-methylpropionamide, or N-methyl-2-pyrrolidone; and a sulfur-containing solvent such as dimethyl sulfide, diethyl sulfide, thiophene, tetrahydrothiophene, dimethyl sulfoxide, sulfolane, or 1,3-propane sultone, but are not limited thereto. These solvents can be used singly or in combination of two or more types thereof.

After completion of the hydrolysis and condensation reaction, the reaction solution is left as it is, or diluted or concentrated, then neutralized, and treated using an ion exchange resin, whereby the hydrolysis catalyst such as an acid or a base used for the hydrolysis and condensation can be removed. In addition, before or after such treatment, an alcohol and water as by-products, the hydrolysis catalyst used, and the like can be removed from the reaction solution by distillation under reduced pressure or the like.

The hydrolysis condensate (hereinafter, also referred to as polysiloxane) thus obtained is obtained in a form of a polysiloxane varnish dissolved in an organic solvent, and can be used as it is for preparation of a silicon-containing resist underlayer film forming composition. That is, the reaction solution can be used as it is (or by being diluted) for preparation of the silicon-containing resist underlayer film forming composition, and at this time, the hydrolysis catalyst used for hydrolysis and condensation, by-products, and the like may remain in the reaction solution as long as an effect of the present invention is not impaired. For example, the hydrolysis catalyst or nitric acid used at the time of alcohol capping of the silanol group may remain in a polymer varnish solution in an amount of about 100 ppm to 5,000 ppm.

The obtained polysiloxane varnish may be subjected to solvent substitution or may be appropriately diluted with a solvent. Note that when storage stability of the obtained polysiloxane varnish is not poor, the organic solvent can be distilled off to set the concentration of a film forming component to 100%. Note that the film forming component refers to a component obtained by removing a solvent component from all components of the composition.

The organic solvent used for solvent substitution, dilution, or the like of the polysiloxane varnish may be the same as or different from the organic solvent used for the hydrolysis and condensation reaction of the hydrolyzable silane. The diluting solvent is not particularly limited, and one or more types can be arbitrarily selected and used.

### <Component [B]: Solvent>

A solvent as a the component [B] can be used without particular limitation as long as it is a solvent capable of dissolving and mixing the component [A] and, as necessary, other components contained in the silicon-containing resist underlayer film forming composition.

[B] Solvent is preferably an alcohol-based solvent, more preferably an alkylene glycol monoalkyl ether which is an alcohol-based solvent, and still more preferably a propylene glycol monoalkyl ether. Since these solvents are also capping agents for a silanol group of a polysiloxane, the silicon-containing resist underlayer film forming composition can be prepared from a solution obtained by preparing [A] polysiloxane without requiring solvent substitution or the like.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Specific other examples of [B] solvent include methyl cellosolve acetate, ethyl cellosolve acetate, propylene glycol propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3 methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methyl propionate, methyl 3-methoxy-2-methyl propionate, methyl 2-hydroxy-3-methyl butyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N, N-dimethylformamide, N-methylacetamide, N, N-dimethylacetamide, N-methyl-2-pyrrolidone, 4-methyl-2-pentanol, and γ-butyrolactone, and these solvents can be used singly or in combination of two or more type thereof.

The silicon-containing resist underlayer film forming composition of the present invention may contain water as a solvent. When the silicon-containing resist underlayer film forming composition contains water as a solvent, the content thereof can be, for example, 30% by mass or less, preferably 20% by mass or less, and still more preferably 15% by mass or less with respect to the total mass of the solvents contained in the composition.

### <Component [C]: Nitric Acid or Acetic Acid>

The silicon-containing resist underlayer film forming composition preferably contains [C] nitric acid or acetic acid in order to, for example, adjust the pH of a solution containing the composition.

[C] Nitric acid or acetic acid may be added at the time of preparation of the silicon-containing resist underlayer film forming composition, but in manufacture of the polysiloxane described above, nitric acid or acetic acid may be used as a hydrolysis catalyst or at the time of alcohol capping of a silanol group, and the nitric acid or acetic acid remaining in a polysiloxane varnish can be used as [C] nitric acid or acetic acid.

The blending amount (residual nitric acid amount) of [C] nitric acid or acetic acid can be, for example, 0.0001% by mass to 1% by mass, 0.001% by mass to 0.1% by mass, or 0.005% by mass to 0.05% by mass on the basis of the total mass of the silicon-containing resist underlayer film forming composition.

### <Component [D]: Curing Catalyst>

The silicon-containing resist underlayer film forming composition can be a composition not containing a curing catalyst, but preferably contains a curing catalyst (component [D]).

As the curing catalyst, an ammonium salt, a phosphine, a phosphonium salt, a sulfonium salt, or the like can be used. Note that the following salts described as an example of the curing catalyst may be added in a form of a salt or may form a salt in the composition (one that is added as a separate compound at the time of addition and forms a salt in the system).

### Examples of the Ammonium Salt Include:

a quaternary ammonium salt having a structure represented by formula (D-1):

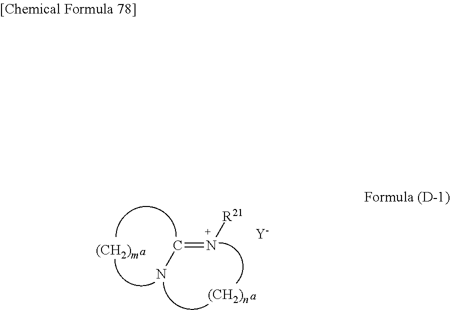

(In the formula, m^{a} represents an integer of 2 to 11, n^{a} represents an integer of 2 or 3, R²¹ represents an alkyl group, an aryl group, or an aralkyl group, and γ-represents an anion);
a quaternary ammonium salt having a structure represented by formula (D-2):

[Chemical Formula 79]

R²²R²³R²⁴R²⁵N⁺Y⁻ Formula (D-2)

(In the formula, R²², R²³, R²⁴, and R²⁵ each independently represent an alkyl group, an aryl group, or an aralkyl group, Y-represents an anion, and R²², R²³, R²⁴, and R²⁵ are each bonded to a nitrogen atom);
a quaternary ammonium salt having a structure represented by formula (D-3):

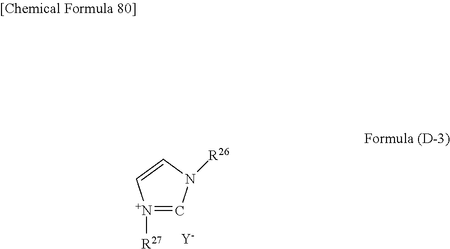

(In the formula, R²⁶ and R²⁷ each independently represent an alkyl group, an aryl group, or an aralkyl group, and Y-represents an anion);
a quaternary ammonium salt having a structure represented by formula (D-4):

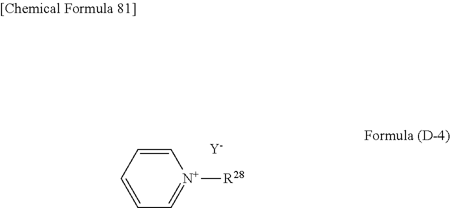

(In the formula, R²⁸ represents an alkyl group, an aryl group, or an aralkyl group, and Y-represents an anion);
a quaternary ammonium salt having a structure represented by formula (D-5):

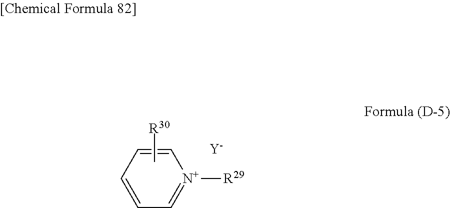

(In the formula, R²⁹ and R³⁰ each independently represent an alkyl group, an aryl group, or an aralkyl group, and Y-represents an anion); and
a tertiary ammonium salt having a structure represented by formula (D-6):

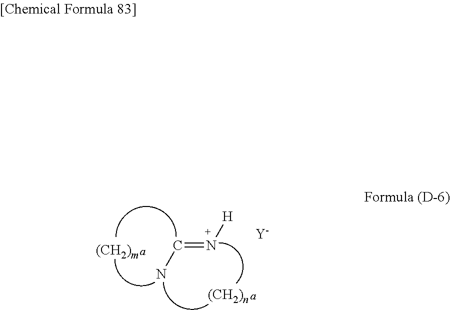

(In the formula, m^{a} represents an integer of 2 to 11, n^{a} represents an integer of 2 or 3, and Y-represents an anion).

Examples of the phosphonium salt include a quaternary phosphonium salt represented by formula (D-7):

[Chemical Formula 84]

R³¹R³²R³³R³⁴P⁺Y⁻ Formula(D-7)

(In the formula, R³¹, R³², R³³, and R³⁴ each independently represent an alkyl group, an aryl group, or an aralkyl group, Y-represents an anion, and R³¹, R³², R³³, and R³⁴ are each bonded to a phosphorus atom).

Examples of the sulfonium salt include a tertiary sulfonium salt represented by formula (D-8):

[Chemical Formula 85]

R³⁵R³⁶R³⁷S⁺Y⁻ Formula(D-8)

(In the formula, R³⁵, R³⁶, and R³⁷ each independently represent an alkyl group, an aryl group, or an aralkyl group, Y⁻ represents an anion, and R³⁵, R³⁶, and R³⁷ are each bonded to a sulfur atom).

The compound of formula (D-1) is a quaternary ammonium salt derived from an amine, m^{a} represents an integer of 2 to 11, and n^{a} represents an integer of 2 or 3. R²¹ of this quaternary ammonium salt represents, for example, an alkyl group having 1 to 18 carbon atoms, preferably 2 to 10 carbon atoms, an aryl group having 6 to 18 carbon atoms, or an aralkyl group having 7 to 18 carbon atoms, and examples thereof include a linear alkyl group such as an ethyl group, a propyl group, or a butyl group, a benzyl group, a cyclohexyl group, a cyclohexylmethyl group, and a dicyclopentadienyl group. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), or alcoholate (—O⁻).

The compound of formula (D-2) is a quaternary ammonium salt represented by R²²R²³R²⁴R²⁵N⁺Y⁻. Each of R²², R²³, R²⁴, and R²⁵ of this quaternary ammonium salt represents, for example, an alkyl group having 1 to 18 carbon atoms, such as an ethyl group, a propyl group, a butyl group, a cyclohexyl group, or a cyclohexylmethyl group, an aryl group having 6 to 18 carbon atoms, such as a phenyl group, or an aralkyl group having 7 to 18 carbon atoms, such as a benzyl group. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), or alcoholate (—O⁻). This quaternary ammonium salt can be obtained as a commercially available product, and examples thereof include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of formula (D-3) is a quaternary ammonium salt derived from a 1-substituted imidazole, the number of carbon atoms of each of R²⁶ and R²⁷ is, for example, 1 to 18, and the total number of carbon atoms of R²⁶ and R²⁷ is preferably 7 or more. Examples of R²⁶ include an alkyl group such as a methyl group, an ethyl group, or a propyl group, an aryl group such as a phenyl group, and an aralkyl group such as a benzyl group, and examples of R²⁷ include an aralkyl group such as a benzyl group, and an alkyl group such as an octyl group or an octadecyl group. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), or alcoholate (—O⁻). This compound can also be obtained as a commercially available product, and can be manufactured, for example, by causing an imidazole-based compound such as 1-methylimidazole or 1-benzylimidazole to react with an aralkyl halide, an alkyl halide, or an aryl halide such as benzyl bromide, methyl bromide, or benzene bromide.

The compound of formula (D-4) is a quaternary ammonium salt derived from pyridine, and R²⁸ represents, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof include a butyl group, an octyl group, a benzyl group, and a lauryl group. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), or alcoholate (—O⁻). This compound can also be obtained as a commercially available product, and can be manufactured, for example, by causing pyridine to react with an alkyl halide such as lauryl chloride, benzyl chloride, benzyl bromide, methyl bromide, or octyl bromide, or an aryl halide. Examples of this compound include N-laurylpyridinium chloride and N-benzylpyridinium bromide.

The compound of formula (D-5) is a quaternary ammonium salt derived from a substituted pyridine typified by picoline or the like, and R²⁹ represents, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof include a methyl group, an octyl group, a lauryl group, and a benzyl group. R³⁰ represents, for example, an alkyl group having 1 to 18 carbon atoms, an aryl group having 6 to 18 carbon atoms, or an aralkyl group having 7 to 18 carbon atoms, and for example, when the compound represented by formula (D-5) is a quaternary ammonium derived from picoline, R³⁰ is a methyl group. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), or alcoholate (—O⁻). This compound can also be obtained as a commercially available product, and can be manufactured, for example, by causing a substituted pyridine such as picoline with an alkyl halide or an aryl halide such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of formula (D-6) is a tertiary ammonium salt derived from an amine, m^{a} represents an integer of 2 to 11, and n^{a} represents 2 or 3. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃−), or alcoholate (—O⁻). The present compound can be manufactured by a reaction of an amine with a weak acid such as a carboxylic acid or phenol. Examples of the carboxylic acid include formic acid and acetic acid, and when formic acid is used, the anion (Y⁻) is (HCOO⁻), and when acetic acid is used, the anion (Y⁻) is (CH₃COO⁻). When phenol is used, the anion (Y⁻) is (C₆H₅O⁻).

The compound of formula (D-7) is a quaternary phosphonium salt having a structure of R³¹R³²R³³R³⁴P⁺Y⁻. Each of R³¹, R³², R³³, and R³⁴ represents, for example, an alkyl group having 1 to 18 carbon atoms, such as an ethyl group, a propyl group, a butyl group, or cyclohexylmethyl, an aryl group having 6 to 18 carbon atoms, such as a phenyl group, or an aralkyl group having 7 to 18 carbon atoms, such as a benzyl group. Preferably, three of four substituents of R³¹ to R³⁴ are unsubstituted phenyl groups or substituted phenyl groups, and examples thereof include a phenyl group and a tolyl group. The remaining one group is an alkyl group having 1 to 18 carbon atoms, an aryl group having 6 to 18 carbon atoms, or an aralkyl group having 7 to 18 carbon atoms. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), or alcoholate (—O⁻). This compound can be obtained as a commercial product, and examples thereof include a tetraalkylphosphonium halide such as a tetra n-butylphosphonium halide or a tetra n-propylphosphonium halide, a trialkylbenzylphosphonium halide such as a triethylbenzylphosphonium halide, a triphenylmonoalkylphosphoniums halide such as a triphenylmethylphosphonium halide or a triphenylethylphosphonium halide, a triphenylbenzylphosphonium halide, a tetraphenylphosphonium halide, a tritolylmonoarylphosphonium halide, and a tritolylmonoalkylphosphonium halide (the halogen atom is a chlorine atom or a bromine atom). In particular, a triphenylmonoalkylphosphonium halide such as a triphenylmethylphosphonium halide or a triphenylethylphosphonium halide, a triphenylmonoarylphosphonium halide such as a triphenylbenzylphosphonium halide, a tritolylmonoarylphosphonium halide such as a tritolylmonophenylphosphonium halide, and a tritolylmonoalkylphosphonium halide such as a tritolylmonomethylphosphonium halide (the halogen atom is a chlorine atom or a bromine atom) are preferable.

Examples of the phosphine include: a first phosphine such as methylphosphine, ethylphosphine, propylphosphine, isopropylphosphine, isobutylphosphine, or phenylphosphine; a second phosphine such as dimethylphosphine, diethylphosphine, diisopropylphosphine, diisoamylphosphine, or diphenylphosphine; and a third phosphine such as trimethylphosphine, triethylphosphine, triphenylphosphine, methyldiphenylphosphine, or dimethylphenylphosphine.

The compound of formula (D-8) is a tertiary sulfonium salt having a structure of R³⁵R³⁶R³⁷S⁺Y⁻. Each of R³⁵, R³⁶, and R³⁷ represents, for example, an alkyl group having 1 to 18 carbon atoms, such as an ethyl group, a propyl group, a butyl group, or cyclohexylmethyl, an aryl group having 6 to 18 carbon atoms, such as a phenyl group, or an aralkyl group having 7 to 18 carbon atoms, such as a benzyl group. Preferably, two of the three substituents of R³⁵ to R³⁷ are unsubstituted phenyl groups or substituted phenyl groups, and examples thereof include a phenyl group and a tolyl group. The remaining one group is an alkyl group having 1 to 18 carbon atoms, an aryl group having 6 to 18 carbon atoms, or an aralkyl group having 7 to 18 carbon atoms. Examples of the anion (Y⁻) include a halide ion such as a chlorine ion (Cl⁻), a bromine ion (Br⁻), or an iodine ion (I⁻), and an acid group such as carboxylate (—COO⁻), sulfonate (—SO₃⁻), alcoholate (—O⁻), a maleate anion, or a nitrate anion. This compound can be obtained as a commercially available product, and examples thereof include: a trialkylsulfonium halide such as a tri n-butylsulfonium halide or a tri n-propylsulfonium halide; a dialkylbenzylsulfonium halide such as a diethylbenzylsulfonium halide; a diphenylmonoalkylsulfonium halide such as a diphenylmethylsulfonium halide or a diphenylethylsulfonium halide; a trialkylsulfonium carboxylate such as a triphenylsulfonium halide (the halogen atom is a chlorine atom or a bromine atom), tri n-butylsulfonium carboxylate, or tri n-propylsulfonium carboxylate; a dialkylbenzylsulfonium carboxylate such as diethylbenzylsulfonium carboxylate; a diphenylmonoalkylsulfonium carboxylate such as diphenylmethylsulfonium carboxylate or diphenylethylsulfonium carboxylate; and triphenylsulfonium carboxylate. A triphenylsulfonium halide and triphenylsulfonium carboxylate can be preferably used.

A nitrogen-containing silane compound can be added as a curing catalyst. Examples of the nitrogen-containing silane compound include an imidazole ring-containing silane compound such as N-(3-triethoxysilypropyl)-4,5-dihydroimidazole.

The content of [D] curing catalyst in the silicon-containing resist underlayer film forming composition is preferably 0.1 to 30 parts by mass, more preferably 0.5 to 25 parts by mass, and still more preferably 1 to 20 parts by mass with respect to 100 parts by mass of [A] polysiloxane from a viewpoint of more sufficiently obtaining an effect of the present invention.

### <Component [E]: Amine and Hydroxide>

The silicon-containing resist underlayer film forming composition preferably contains at least one selected from [E] an amine and a hydroxide from a viewpoint of more sufficiently obtaining an effect of the present invention.

Examples of the amine include ammonia; a primary amine such as monomethanolamine, monoethanolamine, monopropanolamine, methylamine, ethylamine, propylamine, or butylamine; a secondary amine such as dimethylamine, ethylmethylamine, or diethylamine; a tertiary amine such as trimethylamine, triethylamine, tripropylamine, dimethylethylamine, methyldiisopropylamine, diisopropylethylamine, diethylethanolamine, or triethanolamine; an amine such as ethylenediamine or tetramethylethylenediamine; and a cyclic amine such as pyridine or morpholine.

Examples of the hydroxide include an inorganic alkali hydroxide and an organic alkali hydroxide.

Examples of the inorganic alkali hydroxide include sodium hydroxide and potassium hydroxide.

Examples of the organic alkali hydroxide include a tetraalkylammonium hydroxide, a triarylsulfonium hydroxide, and a diaryliodonium hydroxide. Examples of the tetraalkylammonium hydroxide include tetramethylammonium hydroxide, tetraethylammonium hydroxide, and tetrabutylammonium hydroxide. Examples of the triarylsulfonium hydroxide include triphenylsulfonium hydroxide and tris(t-butylphenyl) sulfonium hydroxide. Examples of the diaryliodonium hydroxide include diphenyliodonium hydroxide and bis(t-butylphenyl) iodonium hydroxide.

The content of the component [E] in the silicon-containing resist underlayer film forming composition can be preferably 0.05 to 20 parts by mass, more preferably 0.1 to 15 parts by mass, and still more preferably 0.5 to 10 parts by mass with respect to 100 parts by mass of [A] polysiloxane.

### <Other Additives>

In the silicon-containing resist underlayer film forming composition, various additives can be blended depending on use of the composition.

Examples of the additive include known additives blended in a material (composition) forming various films that can be used for manufacturing a semiconductor device, such as a resist underlayer film, an antireflection film, and a pattern inversion film. Examples of the known additives include a crosslinking agent, a crosslinking catalyst, a stabilizer (an organic acid, water, an alcohols, or the like), an organic polymer, an acid generator, a surfactant (a nonionic surfactant, an anionic surfactant, a cationic surfactant, a silicon-based surfactant, a fluorine-based surfactant, a UV-curable surfactant, or the like), a pH adjusting agent, a metal oxide, a rheology modifier, and an adhesive auxiliary agent.

Note that various additives will be exemplified below, but examples of the additive are not limited thereto.

### <<Stabilizer>>

The stabilizer can be added for the purpose of, for example, stabilizing a hydrolysis condensate of a hydrolyzable silane mixture, and as a specific example thereof, an organic acid, water, an alcohol, or a combination thereof can be added.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these acids, oxalic acid and maleic acid are preferable. When the organic acid is added, the addition amount thereof is 0.1 to 5.0% by mass with respect to the mass of a hydrolysis condensate of a hydrolyzable silane mixture. These organic acids can also act as pH adjusting agents.

As the water, pure water, ultrapure water, deionized water, or the like can be used. When the water is used, the addition amount thereof can be 1 to 20 parts by mass with respect to 100 parts by mass of the silicon-containing resist underlayer film forming composition.

The alcohol is preferably an alcohol that easily scatters by heating after application, and examples thereof include methanol, ethanol, propanol, i-propanol, and butanol. When the alcohol is added, the addition amount thereof can be 1 to 20 parts by mass with respect to 100 parts by mass of the silicon-containing resist underlayer film forming composition.

### <<Organic Polymer>>

By adding an organic polymer to the silicon-containing resist underlayer film forming composition, a dry etching rate (amount of reduction in film thickness per unit time), an attenuation coefficient, a refractive index, and the like of a film (resist underlayer film) formed of the composition can be adjusted. The organic polymer is not particularly limited, and is appropriately selected from various organic polymers (polycondensation polymer and addition polymerization polymer) according to a purpose of addition thereof.

Specific examples thereof include an addition polymerization polymer and a polycondensation polymer such as polyester, polystyrene, polyimide, an acrylic polymer, a methacrylic polymer, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, which functions as an absorption site, can also be preferably used when such a function is required. Specific examples of such an organic polymer include: an addition polymerization polymer containing, as a structural unit thereof, an addition polymerizable monomer such as benzyl acrylate, benzyl methacrylate, phenyl acrylate, naphthyl acrylate, anthryl methacrylate, anthryl methyl methacrylate, styrene, hydroxystyrene, benzyl vinyl ether, or N-phenyl maleimide; and a polycondensation polymer such as phenol novolac or naphthol novolac, but are not limited thereto.

When an addition polymerization polymer is used as the organic polymer, the polymer may be either a homopolymer or a copolymer.

An addition polymerizable monomer is used in manufacture of the addition polymerization polymer, and specific examples of such an addition polymerizable monomer include acrylic acid, methacrylic acid, an acrylic acid ester compound, a methacrylic acid ester compound, an acrylamide compound, a methacrylamide compound, a vinyl compound, a styrene compound, a maleimide compound, maleic anhydride, and acrylonitrile, but are not limited thereto.

Specific examples of the acrylic acid ester compound include methyl acrylate, ethyl acrylate, normal hexyl acrylate, i-propyl acrylate, cyclohexyl acrylate, benzyl acrylate, phenyl acrylate, anthryl methyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyl triethoxysilane, and glycidyl acrylate, but are not limited thereto.

Specific examples of the methacrylic acid ester compound include methyl methacrylate, ethyl methacrylate, normal hexyl methacrylate, i-propyl methacrylate, cyclohexyl methacrylate, benzyl methacrylate, phenyl methacrylate, anthryl methyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyl triethoxysilane, glycidyl methacrylate, 2-phenylethyl methacrylate, hydroxyphenyl methacrylate, and bromophenyl methacrylate, but are not limited thereto.

Specific examples of the acrylamide compound include acrylamide, N-methylacrylamide, N-ethylacrylamide, N-benzylacrylamide, N-phenylacrylamide, N, N-dimethylacrylamide, and N-anthrylacrylamide, but are not limited thereto.

Specific examples of the methacrylamide compound include methacrylamide, N-methylmethacrylamide, N-ethylmethacrylamide, N-benzylmethacrylamide, N-phenylmethacrylamide, N, N-dimethylmethacrylamide, and N-anthrylmethacrylamide, but are not limited thereto.

Specific examples of the vinyl compound include vinyl alcohol, 2-hydroxyethyl vinyl ether, methyl vinyl ether, ethyl vinyl ether, benzyl vinyl ether, vinyl acetic acid, vinyl trimethoxysilane, 2-chloroethyl vinyl ether, 2-methoxyethyl vinyl ether, vinyl naphthalene, and vinyl anthracene, but are not limited thereto.

Specific examples of the styrene compound include styrene, hydroxystyrene, chlorostyrene, bromostyrene, methoxystyrene, cyanostyrene, and acetylstyrene, but are not limited thereto.

Examples of the maleimide compound include maleimide, N-methylmaleimide, N-phenylmaleimide, N-cyclohexylmaleimide, N-benzylmaleimide, and N-hydroxyethylmaleimide, but are not limited thereto.

When a polycondensation polymer is used as the polymer, examples of such a polymer include a polycondensation polymer of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. In addition, examples thereof include a polyester, a polyamide, and a polyimide such as polypyrromellitimide, poly(p-phenylene terephthalamide), polybutylene terephthalate, and polyethylene terephthalate, but are not limited thereto.

When the organic polymer contains a hydroxy group, the hydroxy group can undergo a crosslinking reaction with a hydrolysis condensate or the like.

The organic polymer can have a weight average molecular weight of usually 1,000 to 1,000,000. When the organic polymer is blended, the weight average molecular weight thereof can be, for example, 3,000 to 300,000, 5,000 to 300,000, or 10,000 to 200,000 from a viewpoint of sufficiently obtaining an effect of a function as a polymer and suppressing precipitation in the composition.

Such an organic polymer can be used singly or in combination of two or more types thereof.

When the silicon-containing resist underlayer film forming composition contains an organic polymer, the content thereof is appropriately determined in consideration of a function of the organic polymer and the like, and thus cannot be generally defined. However, usually, the content can be in a range of 1 to 200% by mass with respect to the mass of [A] polysiloxane, can be, for example, 100% by mass or less, preferably 50% by mass or less, and more preferably 30% by mass or less from a viewpoint of, for example, suppressing precipitation in the composition, and can be, for example, 5% by mass or more, preferably 10% by mass or more, and more preferably 30% by mass or more from a viewpoint of, for example, sufficiently obtaining an effect of the organic polymer.

### <<Acid Generator>>

Examples of the acid generator include a thermal acid generator and a photoacid generator, and a photoacid generator can be preferably used.

Examples of the photoacid generator include an onium salt compound, a sulfonimide compound, and a disulfonyldiazomethane compound, but are not limited thereto. Note that the photoacid generator can also function as a curing catalyst depending on the type thereof such as a nitrate, a carboxylate such as a maleate, or a hydrochloride in an onium salt compound described later.

Examples of the thermal acid generator include tetramethylammonium nitrate, but are not limited thereto.

Specific examples of the onium salt compound include: an iodonium salt compound such as diphenyliodonium hexafluorophosphate, diphenyliodonium trifluoromethanesulfonate, diphenyliodonium nonafluoronormal butanesulfonate, diphenyliodonium perfluoronormal octanesulfonate, diphenyliodonium camphor sulfonate, bis(4-t-butylphenyl) iodonium camphor sulfonate, or bis(4-t-butylphenyl) iodonium trifluoromethanesulfonate; and a sulfonium salt compound such as triphenylsulfonium hexafluoroantimonate, triphenylsulfonium nonafluoronormal butanesulfonate, triphenylsulfonium camphor sulfonate, triphenylsulfonium trifluoromethanesulfonate, triphenylsulfonium nitrate, triphenylsulfonium trifluoroacetate, triphenylsulfonium maleate, or triphenylsulfonium chloride, but are not limited thereto.

Specific examples of the sulfonimide compound include N-(trifluoromethanesulfonyloxy) succinimide, N-(nonafluoronormalbutanesulfonyloxy) succinimide, N-(camphorsulfonyloxy) succinimide, and N-(trifluoromethanesulfonyloxy) naphthalimide, but are not limited thereto.

Specific examples of the disulfonyl diazomethane compound include bis(trifluoromethylsulfonyl) diazomethane, bis(cyclohexylsulfonyl) diazomethane, bis(phenylsulfonyl)diazomethane, bis(p-toluenesulfonyl) diazomethane, bis(2,4-dimethylbenzenesulfonyl)diazomethane, and methylsulfonyl-p-toluenesulfonyl diazomethane, but are not limited thereto.

When the silicon-containing resist underlayer film forming composition contains an acid generator, the content thereof is appropriately determined in consideration of the type of the acid generator and the like, and thus cannot be generally defined. However, usually, the content is in a range of 0.01 to 5% by mass with respect to the mass of [A] polysiloxane, can be preferably 3 by mass or less, and more preferably 1% by mass or less from a viewpoint of, for example, suppressing precipitation of the acid generator in the composition, and can be preferably 0.1% by mass or more, and more preferably 0.5% by mass or more from a viewpoint of, for example, sufficiently obtaining an effect of the acid generator.

Note that the acid generator can be used singly or in combination of two or more types thereof, and a photoacid generator and a thermal acid generator may be used in combination.

### <<<Surfactant>>>

The surfactant is effective for suppressing generation of pinholes, striations, and the like when the silicon-containing resist underlayer film forming composition is applied to a substrate. Examples of the surfactant include a nonionic surfactant, an anionic surfactant, a cationic surfactant, a silicon-based surfactant, a fluorine-based surfactant, and a UV-curable surfactant. More specific examples of the surfactant include: a polyoxyethylene alkyl ether such as polyoxyethylene lauryl ether, polyoxyethylene stearyl ether, polyoxyethylene cetyl ether, or polyoxyethylene oleyl ether; a polyoxyethylene alkyl aryl ether such as polyoxyethylene octyl phenol ether or polyoxyethylene nonyl phenol ether; a polyoxyethylene/polyoxypropylene block copolymer; a sorbitan fatty acid ester such as sorbitan monolaurate, sorbitan monopalmitate, sorbitan monostearate, sorbitan monooleate, sorbitan trioleate, or sorbitan tristearate; a nonionic surfactant such as a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate, or polyoxyethylene sorbitan tristearate; a fluorine-based surfactant such as trade name: F-top (registered trademark) EF301, EF303, and EF352 (manufactured by Mitsubishi Materials Electronic Chemicals Co., Ltd. (former TOCHEM PRODUCTS CO., LTD.)), trade name: Megafac (registered trademark)) F171, F173, R-08, R-30, R-30N, and R-40 LM (manufactured by DIC Corporation), Fluorad FC430 and FC431 (manufactured by Sumitomo 3M Limited), trade name: AsahiGuard (registered trademark) AG710 (manufactured by AGC), or Surflon (registered trademark) S-382, SC101, SC102, SC103, SC104, SC105, and SC106 (manufactured by AGC SEIMI CHEMICAL CO., LTD.); and organosiloxane polymer KP341 (manufactured by Shin-Etsu Chemical Co., Ltd.), but are not limited thereto.

The surfactant can be used singly or in combination of two or more types thereof.

When the silicon-containing resist underlayer film forming composition contains a surfactant, the content thereof can be usually 0.0001 to 5% by mass, preferably 0.001 to 4% by mass, and more preferably 0.01 to 3% by mass with respect to the mass of [A] polysiloxane.

### <<Rheology Modifier>>

The rheology modifier is added mainly for the purpose of improving fluidity of the silicon-containing resist underlayer film forming composition, and particularly in a baking step, for the purpose of improving film thickness uniformity of a film to be formed and improving a filling property of the composition into a hole. Specific examples thereof include: a phthalic acid derivative such as dimethyl phthalate, diethyl phthalate, di-i-butyl phthalate, dihexyl phthalate, or butyl i-decyl phthalate; an adipic acid derivative such as di-n-butyl adipate, di-i-butyl adipate, di-i-octyl adipate, or octyl decyl adipate; a maleic acid derivative such as di-n-butyl malate, diethyl malate, or dinonyl malate; an oleic acid derivative such as methyl olate, butyl olate, or tetrahydrofurfuryl olate; and a stearic acid derivative such as n-butyl stearate or glyceryl stearate.

When these rheology modifiers are used, the addition amount thereof is usually less than 30% by mass with respect to the entire film forming component of the silicon-containing resist underlayer film forming composition.

### <<Adhesive Auxiliary Agent>>

The adhesive auxiliary agent is added mainly for the purpose of improving adhesion between a substrate or a resist and a film (resist underlayer film) formed of the silicon-containing resist underlayer film forming composition, and particularly for the purpose of suppressing and preventing peeling of the resist in development. Specific examples thereof include a chlorosilane such as trimethylchlorosilane, dimethylvinylchlorosilane, methyldiphenylchlorosilane, or chloromethyldimethylchlorosilane; an alkoxysilane such as trimethylmethoxysilane, dimethyldiethoxysilane, methyldimethoxysilane, or dimethylvinylethoxysilane; a silazane such as hexamethyldisilazane, N, N′-bis(trimethylsilyl) urea, dimethyltrimethylsilylamine, or trimethylsilyl imidazole; other silanes such as γ-chloropropyltrimethoxysilane, γ-aminopropyltriethoxysilane, and γ-glycidoxypropyltrimethoxysilane; a heterocyclic compound such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, or mercaptopyrimidine; a urea such as 1,1-dimethylurea or 1,3-dimethylurea; and a thiourea compound.

When these adhesive auxiliary agents are used, the addition amount thereof is usually less than 5% by mass, and preferably less than 2% by mass with respect to a film forming component of the silicon-containing resist underlayer film forming composition.

### <<pH Adjusting Agent>>

Examples of the pH adjusting agent include other acids having one or more carboxylic acid groups of the organic acids exemplified above as the stabilizer. When the pH adjusting agent is used, the addition amount thereof can be 0.01 to 20 parts by mass, 0.01 to 10 parts by mass, or 0.01 to 5 parts by mass with respect to 100 parts by mass of [A] polysiloxane.

### <<Metal Oxide>>

Examples of the metal oxide that can be added to the silicon-containing resist underlayer film forming composition include an oxide of one selected from metals such as tin (Sn), titanium (Ti), aluminum (Al), zirconium (Zr), zinc (Zn), niobium (Nb), tantalum (Ta), and tungsten (W), and metalloids such as boron (B), silicon (Si), germanium (Ge), arsenic (As), antimony (Sb), and tellurium (Te), and a combination of two or more types thereof, but are not limited thereto.

The concentration of a film forming component in the silicon-containing resist underlayer film forming composition can be, for example, 0.1 to 50% by mass, 0.1 to 30% by mass, 0.1 to 25% by mass, or 0.5 to 20.0% by mass with respect to the total mass of the composition.

The content of [A] polysiloxane in the film forming component is usually 20% by mass to 100% by mass, but a lower limit thereof is preferably 50% by mass, more preferably 60% by mass, still more preferably 70% by mass, and further still more preferably 80% by mass, and an upper limit thereof is preferably 99% by mass from a viewpoint of, for example, obtaining an effect of the present invention with good reproducibility. The rest thereof can be used as an additive described later.

The silicon-containing resist underlayer film forming composition preferably has a pH of 2 to 5, and more preferably has a pH of 3 to 4.

The silicon-containing resist underlayer film forming composition can be manufactured by mixing [A] polysiloxane, [B] solvent, and if other components are contained as desired, the other components. At this time, a solution containing [A] polysiloxane may be prepared in advance, and this solution may be mixed with [B] solvent or other components.

A mixing order is not particularly limited. For example, [B] solvent may be added to and mixed with a solution containing [A] polysiloxane, and other components may be added to the mixture, or a solution containing [A] polysiloxane, [B] solvent, and other components may be simultaneously mixed.

If necessary, [B] solvent may be further added at the end additionally, or some components relatively soluble in [B] solvent may be prevented from being contained in the mixture, and may be added at the end. However, it is preferable to prepare a solution in which [A] polysiloxane is dissolved well in advance, and to prepare a composition using the solution from a viewpoint of suppressing aggregation and separation of the components and preparing the composition excellent in uniformity with good reproducibility. It is noted that [A] polysiloxane may be aggregated or precipitated when being mixed with [B] solvent to be mixed together depending on the type and amount of [B] solvent, the amounts and properties of other components, and the like. When the composition is prepared using a solution in which [A] polysiloxane is dissolved, it is also noted that it is necessary to determine the concentration of the solution of [A] polysiloxane and the use amount thereof such that the amount of [A] polysiloxane in the finally obtained composition is desired.

In preparation of the composition, heating may be appropriately performed as long as the components are not decomposed or altered.

In the present invention, filtration may be performed using a submicrometer-order filter or the like at a stage in the middle of manufacturing the silicon-containing resist underlayer film forming composition or after all the components are mixed. Note that although the material type of the filter used at this time is not limited, for example, a nylon filter or a fluororesin filter can be used.

The silicon-containing resist underlayer film forming composition of the present invention can be preferably used as a composition for forming a resist underlayer film used in a lithography step.

The silicon-containing resist underlayer film formed of the silicon-containing resist underlayer film forming composition of the present invention can be effectively used as a resist underlayer film for ArF lithography or as a resist underlayer film for EUV lithography using light of a very short wavelength capable of processing finer dimensions that are difficult to process by a lithography technique using ArF excimer laser light.

### (Laminate)

The laminate includes a metal film containing at least one metal selected from the group consisting of Groups 6, 7, 8, and 9 of the periodic table of elements, and a silicon-containing resist underlayer film formed on the metal film.

The silicon-containing resist underlayer film is formed using the silicon-containing resist underlayer film forming composition of the present invention described above.

The metal film is dry-etched.

By manufacturing a semiconductor element using the laminate of the present invention including a silicon-containing resist underlayer film formed using the silicon-containing resist underlayer film forming composition of the present invention, it is possible to obtain a semiconductor element that does not require a biometal layer.

### (Method for Manufacturing Semiconductor Element)

Hereinafter, as one aspect of the present invention, a method for manufacturing a semiconductor element using a silicon-containing resist underlayer film formed using the silicon-containing resist underlayer film forming composition of the present invention will be described.

First, a metal film containing a specific metal such as ruthenium (Ru) is formed on a substrate [for example, a semiconductor substrate such as a silicon wafer coated with a silicon oxide film, a silicon nitride film, or a silicon oxynitride film, a silicon nitride substrate, a quartz substrate, a glass substrate (including alkali-free glass, low-alkali glass, and crystallized glass), a glass substrate on which an indium tin oxide (ITO) film or an indium zinc oxide (IZO) film is formed, a plastic (polyimide, PET, or the like) substrate, a low dielectric constant material (low-k material)-coated substrate, or a flexible substrate] used for manufacturing a precision integrated circuit element by an appropriate forming method such as vapor deposition.

The silicon-containing resist underlayer film forming composition of the present invention is applied onto the metal film by an appropriate application method such as a spinner or a coater, and then the silicon-containing resist underlayer film forming composition is fired using a heating means such as a hot plate to form a cured product of the composition, thereby forming a resist underlayer film. Hereinafter, in the present specification, the resist underlayer film refers to a film formed of the silicon-containing resist underlayer film forming composition of the present invention.

Firing conditions are appropriately selected from a firing temperature of 40° C. to 400° C. or 80° C. to 250° C., and a firing time of 0.3 minutes to 60 minutes. Preferably, the firing temperature is 150° C. to 250° C., and the firing time is 0.5 minutes to 2 minutes.

The film thickness of the resist underlayer film formed here is not particularly limited and can be appropriately set according to a purpose. However, for example, the film thickness of the resist underlayer film is preferably set such that a value of a dry etching rate (also referred to as a dry etch rate) of the resist underlayer film is in a preferable range as compared with a value of a dry etch rate of the metal film containing a specific metal. The thickness of the resist underlayer film is, for example, 10 nm to 1,000 nm, preferably 20 nm to 500 nm, more preferably 20 nm to 300 nm, still more preferably 20 nm to 200 nm, and particularly preferably 20 to 150 nm.

Note that, as the silicon-containing resist underlayer film forming composition to be used at the time of forming the resist underlayer film, a silicon-containing resist underlayer film forming composition that has been subjected to nylon filter filtration can be used. Here, the silicon-containing resist underlayer film forming composition that has been subjected to nylon filter filtration refers to a composition that has been subjected to nylon filter filtration at a stage in the middle of manufacturing the silicon-containing resist underlayer film forming composition or after all the components are mixed.

### <Metal Film Containing Specific Metal>

The metal film according to the present invention contains at least one metal selected from the group consisting of Groups 6, 7, 8, and 9 of the periodic table of elements.

Among the above metals, ruthenium (Ru), tungsten (W), and molybdenum (Mo) are preferable, ruthenium (Ru) and molybdenum (Mo) are more preferable, and ruthenium (Ru) is still more preferable.

Here, the thickness of the metal film on the substrate is not particularly limited, and can be appropriately selected according to a purpose. The thickness of the metal film is, for example, in a range of (1 to 500 nm or 1 to 300 nm).

In the present invention, an aspect is adopted in which the metal film is formed on the substrate, and then the resist underlayer film is formed on the metal film.

By adopting an aspect in which the metal film is formed on the substrate, the resist underlayer film is formed thereon, and a resist film described later is further formed thereon, the metal film can be processed by selecting an appropriate etching gas described later. For example, the resist underlayer film can be processed using a fluorine-based gas having a sufficiently high etching rate with respect to a photoresist film as an etching gas, the metal film can be processed using an oxygen-containing chlorine-based gas having a sufficiently high etching rate with respect to the resist underlayer film as an etching gas, and a semiconductor element can be manufactured.

For example, a layer of a photoresist material (resist film) is formed on the resist underlayer film. The resist film can be formed by a known method, that is, by applying an application type resist material (resist composition for forming the resist film) on the resist underlayer film and firing the application type resist material.

The thickness of the resist film is, for example, 10 nm to 10,000 nm, 100 nm to 2,000 nm, 200 nm to 1,000 nm, or 30 nm to 200 nm.

The photoresist material used for the resist film formed on the resist underlayer film is not particularly limited as long as it is sensitive to light (for example, KrF excimer laser or ArF excimer laser) used for exposure, and either a negative photoresist material or a positive photoresist material can be used. Examples of the photoresist material include: a positive photoresist material containing a novolac resin and a 1,2-naphthoquinone diazide sulfonate; a chemically amplified photoresist material containing a binder having a group that is decomposed by an acid to increase an alkali dissolution rate and a photoacid generator; a chemically amplified photoresist material containing a low-molecular compound that is decomposed by an acid to increase an alkali dissolution rate of the photoresist material, an alkali-soluble binder, and a photoacid generator; and a chemically amplified photoresist material containing a binder having a group that is decomposed by an acid to increase an alkali dissolution rate, a low-molecular compound that is decomposed by an acid to increase an alkali dissolution rate of the photoresist material, and a photoacid generator.

Specific examples of the photoresist material that is available as a commercially available product include trade name: APEX-E manufactured by Shipley Co., Ltd., trade name: PAR710 manufactured by Sumitomo Chemical Co., Ltd., trade name: AR2772JN manufactured by JSR Corporation, and trade name: SEPR430 manufactured by Shin-Etsu Chemical Co., Ltd, but are not limited thereto. Examples thereof further include a fluorine atom-containing polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

For the resist film formed on the resist underlayer film, a resist film for electron beam lithography (also referred to as an electron beam resist film) or a resist film for EUV lithography (also referred to as an EUV resist film) can be used instead of the photoresist film. That is, the silicon-containing resist underlayer film forming composition of the present invention can be used for forming a resist underlayer film for electron beam lithography or for forming a resist underlayer film for EUV lithography. In particular, the silicon-containing resist underlayer film forming composition is preferable as a composition for forming a resist underlayer film for EUV lithography.

As an electron beam resist material for forming an electron beam resist film, either a negative type material or a positive type material can be used. Specific examples thereof include: a chemically amplified resist material containing an acid generator and a binder having a group that is decomposed by an acid to change an alkali dissolution rate; a chemically amplified resist material containing an alkali-soluble binder, an acid generator, and a low-molecular compound that is decomposed by an acid to change an alkali dissolution rate of the resist material; a chemically amplified resist material containing an acid generator, a binder having a group that is decomposed by an acid to change an alkali dissolution rate, and a low-molecular compound that is decomposed by an acid to change an alkali dissolution rate of the resist material; a non-chemically amplified resist material containing a binder having a group that is decomposed by an electron beam to change an alkali dissolution rate; and a non-chemically amplified resist material containing a binder having a site that is cut by an electron beam to change an alkali dissolution rate. Also in a case where these electron beam resist materials are used, a pattern of a resist film can be formed similarly to a case where a photoresist material is used while an electron beam is used as an irradiation source.

As the EUV resist material for forming an EUV resist film, a methacrylate resin-based resist material can be used.

Next, the resist film formed on the resist underlayer film is exposed through a predetermined mask (reticle). For the exposure, a KrF excimer laser (wavelength: 248 nm), an ArF excimer laser (wavelength: 193 nm), an F₂ excimer laser (wavelength: 157 nm), EUV (wavelength: 13.5 nm), an electron beam, or the like can be used.

After the exposure, post exposure bake can also be performed as necessary. The post exposure bake is performed under conditions appropriately selected from a heating temperature of 70° C. to 150° C. and a heating time of 0.3 minutes to 10 minutes.

Next, development is performed with a developer (for example, an alkaline developer). As a result, for example, when a positive photoresist film is used, the photoresist film of an exposed portion is removed, and a pattern of the photoresist film is formed.

Examples of the developer (alkaline developer) include an alkaline aqueous solution (alkaline developer) including an aqueous solution of an alkali metal hydroxide such as potassium hydroxide or sodium hydroxide, an aqueous solution of a quaternary ammonium hydroxide such as tetramethylammonium hydroxide, tetraethylammonium hydroxide, or choline, and an amine aqueous solution such as ethanolamine, propylamine, or ethylenediamine. Furthermore, a surfactant or the like can be added to these developers. Conditions for development are appropriately selected from a temperature of 5 to 50° C. and a time of 10 seconds to 600 seconds.

In the present invention, an organic solvent can be used as the developer, and development is performed with the developer (solvent) after exposure. As a result, for example, when a negative photoresist film is used, the photoresist film of an unexposed portion is removed, and a pattern of the photoresist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Furthermore, a surfactant or the like can be added to these developers. Conditions for development are appropriately selected from a temperature of 5 to 50° C. and a time of 10 seconds to 600 seconds.

The resist underlayer film is removed using the pattern of the photoresist film thus formed as a protective film, and then a metal film containing a specific metal is patterned using a film formed of the patterned resist underlayer film (The patterned resist film and the patterned resist underlayer film may be combined) as a protective film. Thus, a semiconductor element having the patterned metal film on the semiconductor substrate can be manufactured.

Removal (patterning) of the resist underlayer film performed using the pattern of the resist film as a protective film is performed by dry etching, and a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane can be used.

Note that a halogen-based gas is preferably used for dry etching of the resist underlayer film. In dry etching using a halogen-based gas, a resist film (photoresist film) basically made of an organic substance is hardly removed. Meanwhile, a resist underlayer film containing a large amount of silicon atoms is quickly removed with a halogen-based gas. Therefore, a decrease in the film thickness of the photoresist film due to dry etching of the resist underlayer film can be suppressed. As a result, the photoresist film can be used as a thin film. Therefore, dry etching of the resist underlayer film is preferably performed with a fluorine-based gas, and examples of the fluorine-based gas include tetrafluoromethane (CF₄), perfluorocyclobutane (C₄F₈), perfluoropropane (C₃F₈), trifluoromethane, and difluoromethane (CH₂F₂), but are not limited thereto.

The metal film containing a specific metal is formed between the substrate and the resist underlayer film.

Removal (patterning) of the metal film performed using a film formed of the patterned resist underlayer film as a protective film (removal of the metal film performed with a film formed of a patterned resist film and a patterned resist underlayer film as a protective film when the patterned resist film remains) is preferably performed by dry etching using an oxygen-containing chlorine-based gas (a mixed gas of an oxygen gas and a chlorine gas, a mixed gas further containing an argon gas in addition to an oxygen gas and a chlorine gas, or the like).

In dry etching with an oxygen-containing chlorine-based gas, a dry etch rate of the resist underlayer film according to the present invention and a dry etch rate of the metal film containing a specific metal exhibit a favorable relationship that makes practical use possible without any problem, and thus the resist underlayer film according to the present invention can be effectively used as an etching mask for the metal film containing a specific metal.

In particular, when the resist underlayer film is a resist underlayer film formed using a silicon-containing resist underlayer film forming composition in which the content of Si in a polysiloxane is 30% by mass or more, a dry etch rate of the silicon-containing resist underlayer film is a value lower than a dry etch rate of the metal film containing a specific metal. That is, since the silicon-containing resist underlayer film has high dry etch resistance to the metal film containing a specific metal, the metal film containing a specific metal can be effectively removed by using the resist underlayer film as an etching mask.

After processing (patterning) of the metal film, the resist underlayer film can be removed. The resist underlayer film can be removed by dry etching or a wet method (wet etching) using a chemical solution.

The dry etching of the resist underlayer film is preferably performed with a fluorine-based gas as exemplified in the patterning, and examples thereof include tetrafluoromethane (CF₄), perfluorocyclobutane (C₄F₈), perfluoropropane (C₃F₈), trifluoromethane, and difluoromethane (CH₂F₂), but are not limited thereto.

Examples of the chemical solution used for wet etching of the resist underlayer film include dilute hydrofluoric acid (hydrofluoric acid), buffered hydrofluoric acid (mixed solution of HF and NH₄F), an aqueous solution containing hydrochloric acid and hydrogen peroxide (SC-2 chemical solution), an aqueous solution containing sulfuric acid and hydrogen peroxide (SPM chemical solution), an aqueous solution containing hydrofluoric acid and hydrogen peroxide (FPM chemical solution), and an alkaline solution such as an aqueous solution containing ammonia and hydrogen peroxide (SC-1 chemical solution). Examples of the alkaline solution include, in addition to the ammonia hydrogen peroxide obtained by mixing ammonia, hydrogen peroxide water, and water (chemical solution of SC-1), an aqueous solution containing 1 to 99% by mass of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, diazabicycloundecene (DBU), diazabicyclononene (DBN), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine, an ethylenediamine, or guanidine. These chemical solutions can also be used in mixture.

In addition, the resist underlayer film of the present invention can prevent reflection of exposure light, for example, UV (ultraviolet) light or DUV (deep ultraviolet) light (ArF light or KrF light), which is not preferable in EUV exposure (wavelength 13.5 nm), from a substrate or an interface without intermixing with, for example, an EUV resist film, in addition to a function as a hard mask, as the underlayer film of the EUV resist film. Therefore, in order to form an underlayer antireflection film of the EUV resist film, the silicon-containing resist underlayer film forming composition of the present invention can be preferably used. That is, reflection can be efficiently prevented as an underlayer of the EUV resist film. In a case of use as the EUV resist underlayer film, a process therefor can be performed in a similar manner to that for the photoresist underlayer film.

A semiconductor element can be preferably manufactured by using a laminate including a silicon-containing resist underlayer film formed using the silicon-containing resist underlayer film forming composition of the present invention described above and a metal film containing a specific metal and dry-etching the metal film.

In addition, according to the above-described method for manufacturing a semiconductor element, including: a step of forming a metal film containing a specific metal on a semiconductor substrate; a step of forming a silicon-containing resist underlayer film on the metal film using the silicon-containing resist underlayer film forming composition of the present invention; and a step of forming a resist film on the silicon-containing resist underlayer film, a highly accurate semiconductor element can be achieved with good reproducibility. Therefore, stable manufacture of the semiconductor element can be expected.

Furthermore, according to the above-described method for manufacturing a semiconductor element, including: a step of exposing and developing a resist film to obtain a resist pattern; a step of etching a silicon-containing resist underlayer film using the patterned resist film as a mask; and a step of dry-etching a metal film using the patterned silicon-containing resist underlayer film as a mask, it is possible to manufacture a new semiconductor element using a new metal other than Cu for wiring and not requiring a barrier metal layer which has been conventionally required by a subtractive method.

### EXAMPLES

Hereinafter, the present invention will be described more specifically with reference to Synthesis Examples and Examples, but the present invention is not limited only to the following Examples.

In Examples, apparatuses and conditions used for analyzing physical properties of a sample are as follows.

### (1) Molecular Weight Measurement

The molecular weight of the polysiloxane used in the present invention is a molecular weight obtained in terms of polystyrene by GPC analysis.

The GPC measurement conditions can be performed using, for example, a GPC apparatus (trade name: HLC-8220GPC, manufactured by Tosoh Corporation), a GPC column (trade name: Shodex (registered trademark) KF803L, KF802, or KF801, manufactured by Showa Denko K.K.), a column temperature of 40° C., tetrahydrofuran as an eluent (elution solvent), a flow rate of 1.0 mL/min, and polystyrene (manufactured by Showa Denko K.K.) as a standard sample.

### (2) 1H-NMR

Evaluation was performed using a nuclear magnetic resonance apparatus 1H-NMR (400 MHZ) manufactured by JEOL, and d6-Acetone as a solvent.

### (3) Amount of Residual Nitric Acid

The amount of nitric acid remaining in the system was measured by ion chromatography evaluation.

### [1] Synthesis of Polymer (Hydrolysis Condensate)

### Synthesis Example 1

Into a 300 mL flask, 23.04 g of tetraethoxysilane, 1.57 g of phenyltrimethoxysilane, 6.76 g of methyltriethoxysilane, 0.65 g of 1,3-diallyl-5-(3-(triethoxysilyl) propyl)-1,3,5-triazinane-2,4,6-trione, and 48.04 g of propylene glycol monoethyl ether were put, and 19.93 g of a 0.1 M nitric acid aqueous solution was added dropwise to the obtained mixed solution while the mixed solution was stirrer with a magnetic stirrer.

After the dropwise addition, the flask was transferred to an oil bath adjusted to 60° C. and caused to react for 20 hours. Thereafter, ethanol, methanol, and water, which are reaction by-products, were distilled off under reduced pressure and concentrated to obtain a hydrolysis condensate (polymer) solution.

Propylene glycol monoethyl ether was further added to the obtained solution, the concentration was adjusted such that a solvent ratio of 100% propylene glycol monoethyl ether was 20% by mass in terms of solid residue at 140° C., and filtration was performed with a nylon filter (pore size: 0.1 μm).

The obtained polymer contained a polysiloxane having a structure represented by the following formula, and the weight average molecular weight thereof was Mw 3,000 in terms of polystyrene by GPC. From 1H-NMR, the amount capped with propylene glycol monoethyl ether was 2 mol % with respect to Si atoms. The amount of nitric acid remaining in the polymer solution was 0.09%. The calculated Si content was 42% by mass. Here, the Si content was determined as a weight ratio of Si atoms in the polymer when it was assumed that each silane monomer was completely condensed.

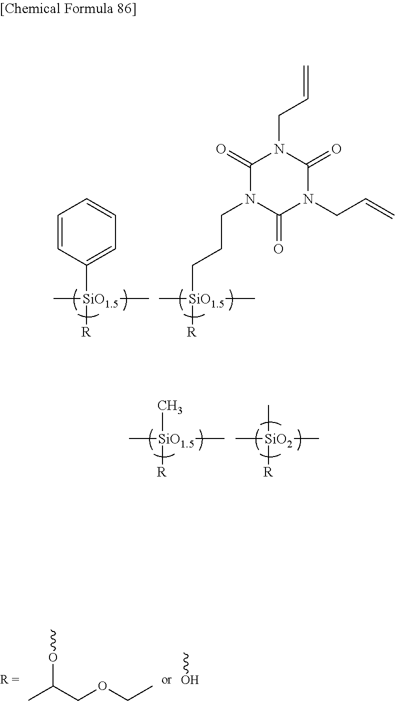

### Synthesis Example 2

Into a 300 mL flask, 22.26 g of tetraethoxysilane, 6.53 g of methyltriethoxysilane, 3.16 g of 1,3-diallyl-5-(3-(triethoxysilyl) propyl)-1,3,5-triazinane-2,4,6-trione, and 48.45 g of propylene glycol monoethyl ether were put, and a mixed aqueous solution of 19.93 g of a 0.2 M nitric acid aqueous solution and 0.35 g of N, N-dimethyl-3-(trimethoxysilyl) propan-1-amine was added dropwise to the obtained mixed solution while the mixed solution was stirred with a magnetic stirrer.

After the dropwise addition, the flask was transferred to an oil bath adjusted to 60° C. and caused to react for 20 hours. Thereafter, ethanol, methanol, and water, which are reaction by-products, were distilled off under reduced pressure and concentrated to obtain a hydrolysis condensate (polymer) solution.

Propylene glycol monoethyl ether was further added to the obtained solution, the concentration was adjusted such that a solvent ratio of 100% propylene glycol monoethyl ether was 20% by mass in terms of solid residue at 140° C., and filtration was performed with a nylon filter (pore size: 0.1 μm).

The obtained polymer contained a polysiloxane having a structure represented by the following formula, and the weight average molecular weight thereof was Mw 2, 500 in terms of polystyrene by GPC. From 1H-NMR, the amount capped with propylene glycol monoethyl ether was 3 mol % with respect to Si atoms. The remaining amount of nitric acid in the polymer solution was 0.16%. The calculated Si content was 38% by mass.

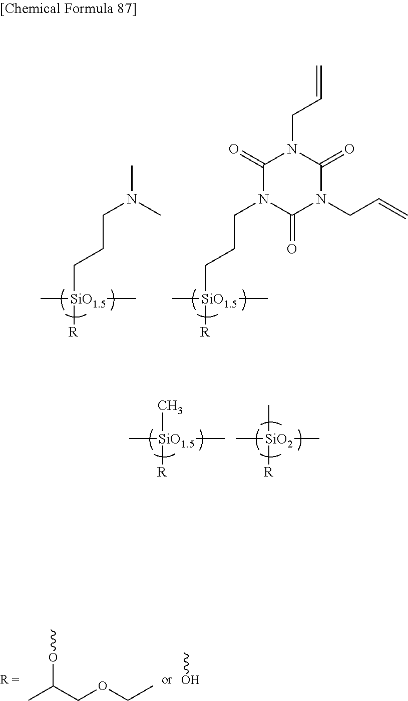

### Synthesis Example 3

Into a 500 mL flask, 22.2 g (30 mol %) of tetraethoxysilane, 44.4 g (70 mol %) of methyltriethoxysilane, and 100 g of acetone were put, and 21.2 g of 0.01 mol/L hydrochloric acid was added dropwise to the mixed solution in the flask while the mixed solution was stirred with a magnetic stirrer. After the dropwise addition, the flask was transferred to an oil bath adjusted to 85° C. and caused to react under warm reflux for four hours. Thereafter, the reaction solution was cooled to room temperature, 100 g of 4-methyl-2 pentanol was added to the reaction solution, and acetone, water, hydrochloric acid, and ethanol, which is a reaction by-product, were distilled off under reduced pressure from the reaction solution and concentrated to obtain a 4-methyl-2-pentanol solution of a co-hydrolysis condensate (polysiloxane). The solid content concentration was adjusted to 13% by mass in terms of solid residue at 140° C. To 15 g of the prepared polymer solution, 20 mg of acetic acid was added. The flask was transferred to an oil bath adjusted to 150° C. and caused to react under warm reflux for 48 hours. The weight average molecular weight Mw by GPC was 5300 in terms of polystyrene. The obtained polysiloxane was a polysiloxane in which some of silanol groups were capped with 4-methyl-2-pentanol. From 1H-NMR, the amount capped with 4-methyl-2-pentanol was 20 mol % with respect to Si atoms. The calculated Si content was 35% by mass.

### Synthesis Example 4

Into a 500 mL flask, 91.16 g of water was put, and 22.23 g of dimethylaminopropyltrimethoxysilane and 8.16 g of triethoxysilylpropylsuccinic anhydride were added dropwise to the mixed solution while the mixed solution was stirred with a magnetic stirrer. After the addition, the flask was transferred to an oil bath adjusted to 40° C. and caused to react for 240 hours. Thereafter, the reaction solution was cooled to room temperature, 91.16 g of water was added to the reaction solution, and ethanol, methanol and water, which are reaction by-products, were distilled off under reduced pressure and concentrated to obtain a hydrolysis condensate (polysiloxane) aqueous solution. Water was further added, and the concentration was adjusted such that a solvent ratio of 100% water (solvent containing only water) was 20% by mass in terms of solid residue at 140° C. The obtained polymer contained a polysiloxane having a structure represented by the following formula. The calculated Si content was 19% by mass.

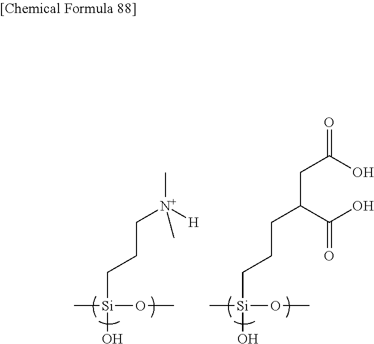

### [2] Preparation of Composition Applied to Resist Pattern

The polysiloxane (polymer) obtained in each of the above Synthesis Examples, an acid (additive 1), a photoacid generator (additive 2), and a solvent were mixed at a ratio presented in Table 1, and the mixture was filtered through a 0.1 μm fluororesin filter to prepare a composition to be applied to a resist pattern. Each addition amount in Table 1 is presented in parts by mass.

Note that, as for the hydrolysis condensate (polymer), the composition was prepared as a solution containing the condensate obtained in each of Synthesis Examples, but the addition ratio of the polymer in Table 1 indicates not the addition amount of the polymer solution but the addition amount of the polymer itself.

In Table 1, as the solvent, DIW means ultrapure water, PGEE means propylene glycol monoethyl ether, PGME means propylene glycol monomethyl ether, and MIBC means methyl isobutyl carbinol.

Furthermore, as various additives, MA means maleic acid, TPSNO3 means triphenylsulfonium nitrate, IMTEOS means triethoxysilylpropyl-4,5-dihydroimidazole, and NfA means nonafluorobutane-1-sulfonic acid (FBSA).

TABLE 1

| | | Additive | Additive | | | |
|---|---|---|---|---|---|---|
| | Polymer | 1 | 2 | Solvent | | |
| Example 1 | Synthesis | MA | IMTEOS | PGEE | PGME | DIW |
| | Example 1 | | | | | |
| (parts by | 1 | 0.01 | 0.006 | 80 | 8 | 12 |
| mass) | | | | | | |
| Example 2 | Synthesis | MA | TPSNO3 | PGEE | PGME | DIW |
| | Example 2 | | | | | |
| (parts by | 1 | 0.01 | 0.01 | 80 | 8 | 12 |
| mass) | | | | | | |
| Example 3 | Synthesis | | | MIBC | | |
| | Example 3 | | | | | |
| (parts by | 1 | | | 100 | | |
| mass) | | | | | | |
| Example 4 | Synthesis | NfA | | DIW | | |
| | Example 4 | | | | | |
| (parts by | 1 | 0.01 | | 100 | | |
| mass) | | | | | | |

*Each of Examples 1 to 4 further contains nitric acid or acetic acid contained in the polymer solution prepared in each of Synthesis Examples 1 to 4.

### [1] Dry Etching Resistance Test

The composition prepared in each of Examples 1 to 4 was applied onto a silicon wafer using a spinner. The composition was heated on a hot plate at 215° C. for one minute to form a Si-containing resist underlayer film, and the film thickness of the obtained underlayer film was measured.

Thereafter, dry etching was performed with a mixed gas of Cl₂ and O₂ for 45 seconds using a dry etcher manufactured by Samco Inc., and the film thickness of the obtained underlayer film was measured.

As Reference Example, a Ru substrate having a film thickness of 100 nm was also dry-etched under the above conditions.

Obtained etch rate measurement results are presented in Table 2.

TABLE 2

| | Dry etch rate |
|---|---|
| | (nm/min) |
| Example 1 | 38.4 |
| Example 2 | 34.9 |
| Example 3 | 59.6 |
| Example 4 | 122.4 |
| Reference Example | 85.3 |
| (Ru substrate) | |

From the above results, it has been confirmed that the dry etch rate of the silicon-containing resist underlayer film formed by the silicon-containing resist underlayer film forming composition of the present invention is within a range that makes practical use possible without any problem as an etching mask for a Ru substrate as compared with the dry etch rate of the Ru substrate. Therefore, it has been found that a silicon-containing resist underlayer film formed of the silicon-containing resist underlayer film forming composition of the present invention can be preferably used as an etching mask used when a metal film containing at least one metal selected from the group consisting of Groups 6, 7, 8, and 9 of the periodic table of elements, such as Ru is dry-etched.

In particular, it has been confirmed that the dry etch rate of the silicon-containing resist underlayer film of each of Examples 1 to 3 is lower than the dry etch rate of the Ru substrate, and has high dry etch resistance to the Ru substrate.

From this, it has been found that there is a correlation between the content of Si in the polysiloxane in the silicon-containing resist underlayer film forming composition and the dry etch resistance, and for example, as indicated in Examples 1 to 3, the silicon-containing resist underlayer film formed of the silicon-containing resist underlayer film forming composition in which the content of Si in at least the polysiloxane is 30% by mass or more can be more preferably used as an etching mask used when a metal film containing at least one metal selected from the group consisting of Groups 6, 7, 8, and 9 of the periodic table of elements is dry-etched.

1. A silicon-containing resist underlayer film forming composition for forming a silicon-containing resist underlayer film to be used as an etching mask when a metal film containing at least one metal selected from the group consisting of Groups 6, 7, 8, and 9 of the periodic table of elements is dry-etched.

2. The silicon-containing resist underlayer film forming composition according to claim 1, wherein the metal is ruthenium (Ru).

3. The silicon-containing resist underlayer film forming composition according to claim 1, comprising:
component [A]: a polysiloxane; and
component [B]: a solvent.

4. The silicon-containing resist underlayer film forming composition according to claim 1, wherein the silicon-containing resist underlayer film is a film formed by application.

5. The silicon-containing resist underlayer film forming composition according to claim 3, wherein a content of Si in the polysiloxane as the component [A] is 30% by mass or more.

6. The silicon-containing resist underlayer film forming composition according to claim 3, wherein the polysiloxane as the component [A] is a polysiloxane using a tetrafunctional alkoxysilane as a raw material.

7. The silicon-containing resist underlayer film forming composition according to claim 3, wherein the polysiloxane as the component [A] is a polysiloxane using a trifunctional alkoxysilane as a raw material.

8. The silicon-containing resist underlayer film forming composition according to claim 3, wherein the polysiloxane as the component [A] contains a polysiloxane modified product in which at least some of silanol groups are alcohol-modified or acetal-protected.

9. The silicon-containing resist underlayer film forming composition according to claim 8, wherein the polysiloxane modified product contains a dehydration reaction product of a hydrolysis condensate of a hydrolyzable silane compound and an alcohol.

10. The silicon-containing resist underlayer film forming composition according to claim 3, wherein the solvent as the component [B] contains an alcohol-based solvent.

11. The silicon-containing resist underlayer film forming composition according to claim 10, wherein the solvent as the component [B] contains at least one of a propylene glycol monoalkyl ether and methyl isobutyl carbinol.

12. The silicon-containing resist underlayer film forming composition according to claim 3, further comprising nitric acid or acetic acid.

13. The silicon-containing resist underlayer film forming composition according to claim 3, wherein the solvent as the component [B] contains water.

14. The silicon-containing resist underlayer film forming composition according to claim 1, wherein the silicon-containing resist underlayer film is a resist underlayer film for ArF or EUV lithography.

15. A laminate comprising: a metal film containing at least one metal selected from the group consisting of Groups 6, 7, 8, and 9 of the periodic table of elements; and a silicon-containing resist underlayer film formed on the metal film, wherein
the silicon-containing resist underlayer film is formed using the silicon-containing resist underlayer film forming composition according to claim 1, and
the metal film is dry-etched.

16. A method for manufacturing a semiconductor element, comprising:
forming a metal film containing at least one metal selected from the group consisting of Groups 6, 7, 8, and 9 of the periodic table of elements on a semiconductor substrate;
forming a silicon-containing resist underlayer film on the metal film using the silicon-containing resist underlayer film forming composition according to claim 1; and
forming a resist film on the silicon-containing resist underlayer film.

17. The method for manufacturing a semiconductor element according to claim 16, wherein a silicon-containing resist underlayer film forming composition that has been subjected to nylon filter filtration is used in forming the silicon-containing resist underlayer film.

18. The method for manufacturing a semiconductor element according to claim 16, comprising:
applying the silicon-containing resist underlayer film forming composition according to claim 1 on the metal film and firing the composition to form a silicon-containing resist underlayer film; and
applying a resist composition onto the silicon-containing resist underlayer film to form a resist film.

19. The method for manufacturing a semiconductor element according to claim 16, comprising:
exposing and developing the resist film to obtain a resist pattern;
etching the silicon-containing resist underlayer film using the patterned resist film as a mask; and
dry-etching the metal film using the patterned silicon-containing resist underlayer film as a mask.

20. The method for manufacturing a semiconductor element according to claim 19, wherein an etching rate (etch rate) of the silicon-containing resist underlayer film in the step of dry-etching is lower than an etching rate (etch rate) of the metal film.

21. The method for manufacturing a semiconductor element according to claim 19, further comprising removing the silicon-containing resist underlayer film by a wet method using a chemical solution after dry-etching the metal film.
